(19) United States
(12) Patent Application Publication
(10) Pub. No.: US 2024/0341109 A1
(43) Pub. Date: Oct. 10, 2024

(54) DISPLAY APPARATUS AND MANUFACTURING METHOD OF DISPLAY APPARATUS

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Shingo EGUCHI, Atsugi, Kanagawa (JP); Koji KUSUNOKI, Isehara, Kanagawa (JP)

(21) Appl. No.: 18/292,122

(22) PCT Filed: Aug. 2, 2022
(86) PCT No.: PCT/IB2022/057141

§ 371 Date: Jan. 25, 2024

(30) Foreign Application Priority Data
Aug. 12, 2021 (JP) 2021-131633

(51) Int. Cl. H10K 50/11; H10K 50/15; H10K 50/16; H10K 50/19; H10K 59/35; H10K 71/13; H10K 85/10

(52) U.S. Cl. CPC H10K 50/11; H10K 50/15; H10K 50/16; H10K 59/35; H10K 71/135; H10K 85/10; H10K 50/19

(57) ABSTRACT

A display apparatus with high display quality is provided. A highly reliable display apparatus is provided. A display apparatus that can easily achieve a higher resolution is provided. The display apparatus includes a first light-emitting device in which a first pixel electrode, a first layer including a first light-emitting layer, and a common electrode are stacked in order, a second light-emitting device in which a second pixel electrode, a second layer including a second light-emitting layer, and the common electrode are stacked in order, and a third light-emitting device in which a third pixel electrode, a third layer including a third light-emitting layer, and the common electrode are stacked in order. The second layer includes a first region overlapping with the first layer and a second region overlapping with the third layer. The first region is positioned over the first layer. The second region is positioned under the third layer. The first region is positioned between the first pixel electrode and the second pixel electrode in a top view. The second region is positioned between the second pixel electrode and the third pixel electrode in a top view.

### TECHNICAL FIELD

One embodiment of the present invention relates to a display apparatus and a manufacturing method of the display apparatus.

Examples of the technical field of one embodiment of the present invention include, in addition to the above, a semiconductor device, a light-emitting apparatus, an electronic device, an input device (e.g., a touch sensor), a driving method thereof, and a manufacturing method thereof.

### BACKGROUND ART

As a manufacturing method of a display apparatus containing organic EL, there is a method in which an EL layer is formed by an inkjet method (see Patent Document 1).

### REFERENCE

### Patent Document

[Patent Document 1] Japanese Published Patent Application No. 2001-185354

### SUMMARY OF THE INVENTION

### Problems to be Solved by the Invention

An object of one embodiment of the present invention is to provide a display apparatus with high display quality. An object of one embodiment of the present invention is to provide a highly reliable display apparatus. An object of one embodiment of the present invention is to provide a display apparatus that can easily achieve a higher resolution. An object of one embodiment of the present invention is to provide a display apparatus having both high display quality and a high resolution. An object of one embodiment of the present invention is to provide a display apparatus with low power consumption.

An object of one embodiment of the present invention is to increase the resolution of a display apparatus in which at least one organic compound layer is formed by a wet process. An object of one embodiment of the present invention is to provide the above-described display apparatus and a manufacturing method thereof.

An object of one embodiment of the present invention is to provide a display apparatus having a novel structure or a manufacturing method of the display apparatus. An object of one embodiment of the present invention is to provide a method for manufacturing the above-described display apparatus with high yield. An object of one embodiment of the present invention is to at least reduce at least one of problems of conventional art.

Note that the description of these objects does not preclude the existence of other objects. Note that one embodiment of the present invention does not have to achieve all the objects. Note that other objects will be apparent from the description of the specification, the drawings, the claims, and the like, and other objects can be derived from the description of the specification, the drawings, the claims, and the like.

### Means for Solving the Problems

One embodiment of the present invention is a display apparatus including a first light-emitting device, a second light-emitting device, and a third light-emitting device. The first light-emitting device includes a first pixel electrode, a first layer over the first pixel electrode, and a common electrode over the first layer; the second light-emitting device includes a second pixel electrode, a second layer over the second pixel electrode, and the common electrode over the second layer; the third light-emitting device includes a third pixel electrode, a third layer over the third pixel electrode, and the common electrode over the third layer; the first layer includes a first light-emitting layer; the second layer includes a second light-emitting layer; the third layer includes a third light-emitting layer; the second layer includes a first region overlapping with the first layer and a second region overlapping with the third layer; the first region is positioned over the first layer; the second region is positioned under the third layer; the first light-emitting device and the second light-emitting device are adjacent to each other; the first region is positioned between the first pixel electrode and the second pixel electrode in a top view; the second light-emitting device and the third light-emitting device are adjacent to each other; and the second region is positioned between the second pixel electrode and the third pixel electrode in a top view.

In the above-described structure, the first layer preferably includes one or two of a hole-injection layer and a hole-transport layer.

In the above-described structure, the first layer preferably includes an electron-transport layer.

Another embodiment of the present invention is a display apparatus including a first light-emitting device, a second light-emitting device, and an insulating layer. The first light-emitting device includes a first pixel electrode, a first layer over the first pixel electrode, and a common electrode over the first layer; the second light-emitting device includes a second pixel electrode, a second layer over the second pixel electrode, and the common electrode over the second layer; the first layer includes a first light-emitting layer; the second layer includes a second light-emitting layer; the insulating layer is in contact with a side surface of the first layer and a side surface of the second layer; the insulating layer includes a region overlapping with a top surface of the first layer; the first layer covers an end portion of the first pixel electrode; and the insulating layer covers an end portion of the second pixel electrode.

In the above-described structure, it is preferable that the second layer not overlap with a top surface of the insulating layer.

In the above-described structure, the first layer preferably includes one or two of a hole-injection layer and a hole-transport layer.

In the above-described structure, the first layer preferably includes an electron-transport layer.

Another embodiment of the present invention is a manufacturing method of a display apparatus, including: forming a first transistor and a second transistor over a substrate; forming a first electrode of a first light-emitting device so that the first electrode is electrically connected to the first transistor; forming a second electrode of a second light-emitting device so that the second electrode is electrically connected to the second transistor; forming a first layer that contains a light-emitting material and is included in the first light-emitting device over the first electrode by an evaporation method; forming a mask layer over the first layer; removing part of the first layer with use of the mask layer to form a second layer; forming an insulating layer being in contact with a side surface of the second layer and overlapping with part of a top surface of the second layer; forming a third layer that contains a light-emitting material and is included in the second light-emitting device over the second electrode by a wet process so that the third layer is in contact with a side surface of the insulating layer; and forming a common electrode over the second layer, the third layer, and the insulating layer.

In the above-described structure, the first light-emitting device preferably exhibits blue light emission, and the second light-emitting device preferably exhibits red or green light emission.

In the above-described structure, an inkjet method is preferably used as the wet process.

In the above-described structure, it is preferable that the third layer be formed after the insulating layer is subjected to liquid-repellent treatment.

Another embodiment of the present invention is a display apparatus including a display portion. The display portion includes a plurality of first light-emitting devices, a plurality of second light-emitting devices, and a plurality of third light-emitting devices; each of the plurality of first light-emitting devices exhibits light emission of a first color; each of the plurality of second light-emitting devices exhibits light emission of a second color; each of the plurality of third light-emitting devices exhibits light emission of a third color; the display portion includes a first column where the first light-emitting devices and the third light-emitting devices are alternately arranged and a second column where the second light-emitting devices and the third light-emitting devices are alternately arranged; in the display portion, the first light-emitting device is adjacent to four of the third light-emitting devices and the second light-emitting device is adjacent to four of the third light-emitting devices; a first layer containing a light-emitting material included in each of the third light-emitting devices includes a low molecular weight compound; and a second layer containing a light-emitting material included in each of the second light-emitting devices includes a high molecular weight compound.

In the above-described structure, each of the plurality of third light-emitting devices preferably exhibits blue light emission, each of the plurality of second light-emitting devices preferably exhibits red light emission, and each of the plurality of first light-emitting devices preferably exhibits green light emission.

In the above-described structure, a second layer containing a light-emitting material included in the first light-emitting devices preferably includes a high molecular weight compound.

### Effect of the Invention

With one embodiment of the present invention, a display apparatus with high display quality can be provided. A highly reliable display apparatus can be provided. A display apparatus that can easily achieve a higher resolution can be provided. A display apparatus having both high display quality and a high resolution can be provided. A display apparatus with low power consumption can be provided.

With one embodiment of the present invention, a high-resolution display apparatus and a manufacturing method thereof can be provided. With one embodiment of the present invention, the display apparatus can be manufactured by a wet process, and thus, the cost can be reduced.

With one embodiment of the present invention, a display apparatus having a novel structure or a manufacturing method of the display device can be provided. A method for manufacturing the above-described display apparatus with high yield can be provided. With one embodiment of the present invention, at least one of problems of conventional art can be at least reduced.

Note that the description of these effects does not preclude the existence of other effects. Note that one embodiment of the present invention does not need to have all the effects. Note that other effects can be derived from the description of the specification, the drawings, the claims, and the like.

### BRIEF DESCRIPTION OF THE DRAWINGS

FIG. 1A is a top view illustrating an example of a display apparatus. FIG. 1B and FIG. 1C are cross-sectional views illustrating the example of the display apparatus.

FIG. 2A to FIG. 2C are cross-sectional views illustrating examples of a display apparatus.

FIG. 3A to FIG. 3C are cross-sectional views illustrating examples of a display apparatus.

FIG. 4 is a cross-sectional view illustrating an example of a display apparatus.

FIG. 5A is a top view illustrating an example of a display apparatus. FIG. 5B and FIG. 5C are cross-sectional views illustrating the example of the display apparatus.

FIG. 6A to FIG. 6C are cross-sectional views illustrating an example of a manufacturing method of the display apparatus.

FIG. 7A to FIG. 7C are cross-sectional views illustrating the example of the manufacturing method of the display apparatus.

FIG. 8A to FIG. 8D are cross-sectional views illustrating an example of a manufacturing method of the display apparatus.

FIG. 9A and FIG. 9B are cross-sectional views illustrating the example of the manufacturing method of the display apparatus.

FIG. 10A to FIG. 10D are cross-sectional views illustrating an example of a manufacturing method of the display apparatus.

FIG. 11A to FIG. 11C are cross-sectional views illustrating an example of a manufacturing method of the display apparatus.

FIG. 12A and FIG. 12B are cross-sectional views illustrating the example of the manufacturing method of the display apparatus.

FIG. 13A and FIG. 13B are cross-sectional views illustrating the example of the manufacturing method of the display apparatus.

FIG. 14A and FIG. 14B are cross-sectional views illustrating the example of the manufacturing method of the display apparatus.

FIG. 15A and FIG. 15B are cross-sectional views illustrating the example of the manufacturing method of the display apparatus.

FIG. 16A to FIG. 16F are top views illustrating examples of a pixel.

FIG. 17A to FIG. 17H are top views illustrating examples of a pixel.

FIG. 18A to FIG. 18J are top views illustrating examples of a pixel.

FIG. 19A to FIG. 19D are top views illustrating examples of a pixel. FIG. 19E to FIG. 19G are cross-sectional views illustrating examples of a display apparatus.

FIG. 20A and FIG. 20B are perspective views illustrating an example of a display apparatus.

FIG. 21A and FIG. 21B are cross-sectional views illustrating examples of a display apparatus.

FIG. 22 is a cross-sectional view illustrating an example of a display apparatus.

FIG. 23 is a cross-sectional view illustrating an example of a display apparatus.

FIG. 24 is a cross-sectional view illustrating an example of a display apparatus.

FIG. 25 is a cross-sectional view illustrating an example of a display apparatus.

FIG. 26 is a cross-sectional view illustrating an example of a display apparatus.

FIG. 27 is a perspective view illustrating an example of a display apparatus.

FIG. 28A is a cross-sectional view illustrating an example of a display apparatus. FIG. 28B and FIG. 28C are cross-sectional views illustrating examples of transistors.

FIG. 29A is a block diagram illustrating an example of a display apparatus. FIG. 29B to FIG. 29D are diagrams illustrating examples of a pixel circuit.

FIG. 30A to FIG. 30D are cross-sectional views illustrating examples of a transistor.

FIG. 31A to FIG. 31F are diagrams illustrating structure examples of light-emitting devices.

FIG. 32A to FIG. 32D are diagrams illustrating examples of electronic devices.

FIG. 33A to FIG. 33F are diagrams illustrating examples of electronic devices.

FIG. 34A to FIG. 34G are diagrams illustrating examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of embodiments below.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Thus, they are not limited to the illustrated scale.

Note that in this specification and the like, ordinal numbers such as “first” and “second” are used in order to avoid confusion among components and do not limit the number.

In this specification and the like, a display apparatus may be rephrased as an electronic device.

In this specification and the like, a display apparatus that is one embodiment of a display apparatus has a function of displaying (outputting) an image or the like on (to) a display surface. Therefore, the display apparatus is one embodiment of an output device.

In this specification and the like, a substrate of a display apparatus to which a connector such as an FPC (Flexible Printed Circuit) or a TCP (Tape Carrier Package) is attached, or a substrate on which an IC is mounted by a COG (Chip On Glass) method or the like is referred to as a display module in some cases. In this specification and the like, a display apparatus is referred to as a display panel in some cases.

In this specification and the like, the term “film” and the term “layer” can be interchanged with each other. For example, in some cases, the term “conductive layer” and the term “insulating layer” can be interchanged with the term “conductive film” and the term “insulating film”, respectively.

Note that in this specification and the like, an EL layer means a layer containing at least a light-emitting substance (also referred to as a light-emitting layer) or a stacked-layer body including the light-emitting layer provided between a pair of electrodes of a light-emitting device (also referred to as a light-emitting element).

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

### Embodiment 1

In this embodiment, a display apparatus of one embodiment of the present invention is described.

One embodiment of the present invention is a display apparatus including a display portion capable of full-color display. The display portion includes a first subpixel and a second subpixel that exhibit light of different colors. The first subpixel includes a first light-emitting device that emits light of a first color and the second subpixel includes a second light-emitting device that emits light of a color different from the color of light emitted from the first light-emitting device. At least one kind of material is different between the first light-emitting device and the second light-emitting device; for example, the light-emitting devices include different light-emitting materials from each other. That is, light-emitting devices for different emission colors are separately formed in the display apparatus of one embodiment of the present invention.

A structure in which light-emitting layers in light-emitting devices of different colors (for example, blue (B), green (G), and red (R)) are separately formed or separately patterned is sometimes referred to as an SBS (Side By Side) structure. The SBS structure can optimize materials and structures of light-emitting devices and thus can extend the freedom of choice of materials and structures, whereby the luminance and the reliability can be easily improved.

In the case of manufacturing a display apparatus including a plurality of light-emitting devices emitting light of different colors, light-emitting layers different in emission color each need to be formed in an island shape. Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

For example, an island-shaped light-emitting layer can be formed by a vacuum evaporation method using a metal mask (also referred to as a shadow mask). However, this method causes a deviation from the designed shape and position of an island-shaped light-emitting layer due to various influences such as the low accuracy of the metal mask, the positional deviation between the metal mask and a substrate, a warp of the metal mask, and the vapor-scattering-induced expansion of the outline of the formed film; accordingly, it is difficult to achieve high resolution and a high aperture ratio. In addition, the outline of the layer may blur during vapor deposition, whereby the thickness of an end portion may be small. That is, the thickness of the island-shaped light-emitting layer may vary from area to area. In the case of manufacturing a display apparatus with a large size, high definition, or high resolution, the manufacturing yield might be reduced because of low dimensional accuracy of the metal mask and deformation due to heat or the like.

The display apparatus of one embodiment of the present invention includes a first light-emitting device, and the first light-emitting device includes a first layer (also referred to as an EL layer or part of an EL layer) including a light-emitting layer emitting light of a first color. In the manufacturing method of the display apparatus of one embodiment of the present invention, the first layer is formed by a wet process. An inkjet method is preferably used as the wet process.

An inkjet method generates fewer waste materials than an evaporation method, and thus the cost can be reduced.

The display apparatus of one embodiment of the present invention includes a second light-emitting device, and the second light-emitting device includes a second layer (also referred to as an EL layer or part of an EL layer) including a light-emitting layer emitting light of a second color. In the manufacturing method of the display apparatus of one embodiment of the present invention, the second layer may be formed by a wet process or by an evaporation method. In the case of using an evaporation method, after a film to be the second layer is formed by an evaporation method, part of the film is removed by processing using a photolithography method, so that the second layer can be formed. Specifically, for example, after the film to be the second layer is formed, a second mask layer is formed over the film. Then, a second resist mask is formed over the second mask layer, and the second mask layer and the film to be the second layer are processed using the second resist mask, so that the island-shaped second layer is formed.

Note that in the case where processing is performed by a photolithography method directly above the light-emitting layer, damage to the light-emitting layer (e.g., damage by processing) might significantly degrade the reliability. In view of the above, a method in which a mask layer or the like is formed over a layer positioned above the light-emitting layer and the light-emitting layer is processed into an island shape is preferably used. By employing such a method, a highly reliable display apparatus can be provided.

By using an inkjet method for forming the first layer and using etching with a mask layer formed by an evaporation method and a photolithography method for forming the second layer in this manner, a display apparatus with a high resolution or a display apparatus with a high aperture ratio can be formed compared with a method using a metal mask having a fine pattern. Moreover, the EL layer or the island-shaped layer formed of part of the EL layer can be formed separately for each color, enabling the display apparatus to perform extremely clear display with high contrast and high display quality. Moreover, providing the mask layer over the EL layer or the island-shaped layer formed of part of the EL layer can reduce damage to the EL layer or the island-shaped layer formed of part of the EL layer in the manufacturing process of the display apparatus, resulting in an increase in reliability of the light-emitting device.

It is difficult to set the interval between adjacent light-emitting devices to be less than 10 μm with a formation method using a metal mask, for example; however, with the above method, the interval between adjacent light-emitting devices can be decreased to be less than 10 μm, less than or equal to 8 μm, less than or equal to 5 μm, less than or equal to 3 μm, less than or equal to 2 μm, or less than or equal to 1 μm. For example, with use of a light exposure tool for LSI, the interval between adjacent light-emitting devices can be decreased to be less than or equal to 500 nm, less than or equal to 200 nm, less than or equal to 100 nm, or less than or equal to 50 nm. Accordingly, the area of a non-light-emitting region that may exist between two light-emitting devices can be significantly reduced, and the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

Note that it is not necessary to form all layers included in the EL layer separately between light-emitting devices that exhibit different colors, and some of the layers in the EL layer can be formed in the same step. As examples of the layers included in the EL layer, a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer) can be given. In the method for manufacturing a display apparatus of one embodiment of the present invention, after some layers included in the EL layer are formed into an island shape separately for each color, at least part of the mask layer is removed; then, the other layers included in the EL layer (sometimes referred to as common layers) and a common electrode (also referred to as an upper electrode) are formed (as a single film) so as to be shared by the light-emitting devices of different colors. For example, a carrier-injection layer and the common electrode can be formed so as to be shared by the light-emitting devices of different colors.

Meanwhile, the carrier-injection layer is often a layer having relatively high conductivity in the EL layer. Therefore, when the carrier-injection layer is in contact with the side surface of any layer included in the EL layer formed in an island shape or the side surface of the pixel electrode, the light-emitting device might be short-circuited. Note that also in the case where the carrier-injection layer is provided in an island shape and the common electrode is formed to be shared by the light-emitting devices of different colors, the light-emitting device might be short-circuited when the common electrode is in contact with the side surface of the EL layer or the side surface of the pixel electrode.

In view of this, the display apparatus of one embodiment of the present invention includes an insulating layer covering at least the side surface of the island-shaped light-emitting layer. The insulating layer may cover part of a top surface of the island-shaped light-emitting layer. Note that the side surface of the island-shaped light-emitting layer here refers to the plane that is not parallel to the substrate (or the surface where the light-emitting layer is formed) among the interfaces between the island-shaped light-emitting layer and other layers. The side surface is not necessarily one of a planar plane and a curved plane in an exactly mathematical perspective.

Thus, at least some layers in the EL layer formed in an island shape and the pixel electrode can be inhibited from being in contact with the carrier-injection layer or the common electrode. Hence, a short circuit in the light-emitting device is inhibited, and the reliability of the light-emitting device can be improved.

In addition, the insulating layer preferably has a function of a barrier insulating layer against at least one of water and oxygen. Alternatively, the insulating layer preferably has a function of inhibiting the diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as having low permeability). Alternatively, a barrier property refers to a function of capturing or fixing (also referred to as gettering) a particular substance.

When the insulating layer having a function of the barrier insulating layer or a gettering function is used, entry of impurities (typically, at least one of water and oxygen) that would diffuse into the light-emitting devices from the outside can be inhibited. With this structure, a highly reliable light-emitting device and a highly reliable display apparatus can be provided.

The hole-injection layer or the electron-injection layer and the like often have relatively high conductivity in the EL layer. Since side surfaces of these layers are covered with the insulating layer in the display apparatus of one embodiment of the present invention, these layers can be inhibited from being in contact with the common electrode or the like. Hence, a short circuit in the light-emitting device is inhibited, and the reliability of the light-emitting device can be improved.

The insulating layer that covers a side surface of the island-shaped EL layer or the island-shaped layer formed of part of the EL layer may have a single-layer structure or a stacked-layer structure.

For example, an insulating layer having a single-layer structure using an inorganic material can be used as a protective insulating layer for the EL layer or the island-shaped layer formed of part of the EL layer. Thus, the reliability of the display apparatus can be improved. The protective insulating layer preferably covers part of the top surface of the EL layer or the island-shaped layer formed of part of the EL layer. In such a structure, the above-described mask layer may remain between the protective insulating layer and the top surface of the EL layer or the island-shaped layer formed of part of the EL layer. The mask layer is preferably an insulating layer formed using an inorganic material like the protective insulating film.

Note that in all the light-emitting devices, the protective insulating layer does not necessarily cover part of the top surface of the island-shaped EL layer or the island-shaped layer formed of part of the EL layer. For example, the protective insulating layer may cover the top surface of the island-shaped EL layer or the island-shaped layer formed of part of the EL layer in only one of two adjacent light-emitting devices.

For example, in the case where an inkjet method is used to form an island-shaped EL layer or an island-shaped layer formed of part of the EL layer (the first layer) included in the first light-emitting device and etching with a mask layer formed by an evaporation method and a photolithography method is used to form an island-shaped EL layer or an island-shaped layer formed of part of the EL layer (the second layer) included in the first light-emitting device, the second layer can be formed by an inkjet method after the second layer is formed and then the side and top surfaces of the second layer are covered by the protective insulating layer. Providing the protective insulating layer before formation of the second layer allows the first layer and the second layer to be separated by the protective insulating layer.

In the case where the insulating layer having a stacked-layer structure is used, the first layer of the insulating layer is preferably formed using an inorganic insulating material because it is formed in contact with the EL layer or the island-shaped layer formed of part of the EL layer. In particular, the first layer is preferably formed by an atomic layer deposition (ALD) method, by which damage due to deposition is small. Alternatively, an inorganic insulating layer is preferably formed by a sputtering method, a chemical vapor deposition (CVD) method, or a plasma-enhanced chemical vapor deposition (PECVD) method, which have higher deposition speed than an ALD method. In this case, a highly reliable display apparatus can be manufactured with high productivity. The second layer of the insulating layer is preferably formed using an organic material to fill a concave portion formed in the first layer of the insulating layer.

For example, an aluminum oxide film formed by an ALD method can be used as the first layer of the insulating layer, and an organic resin film can be used as the second layer of the insulating layer. For example, it is preferable to use a photosensitive acrylic resin as the organic resin.

### [Structure Example 1 of Display Apparatus]

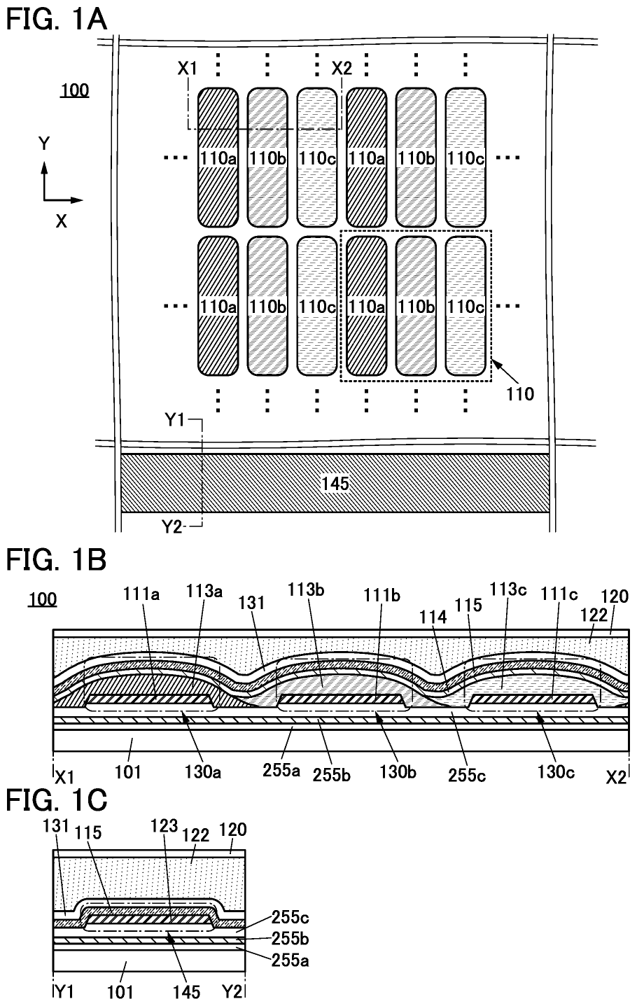

FIG. 1A to FIG. 5C illustrate a display apparatus of one embodiment of the present invention.

FIG. 1A illustrates a top view of a display apparatus 100. The display apparatus 100 includes a display portion where a plurality of pixels 110 are arranged, and a connection portion 145 outside the display portion. A plurality of subpixels are arranged in a matrix in the display portion. FIG. 1A illustrates subpixels in two rows and six columns, which form pixels in two rows and two columns. The connection portion 145 can also be referred to as a cathode contact portion.

The pixel 110 illustrated in FIG. 1A employs stripe arrangement. The pixel 110 illustrated in FIG. 1A is composed of three subpixels: the subpixels 110a, 110b, and 110c. The subpixels 110a, 110b, and 110c include light-emitting devices emitting light of different colors. The subpixels 110a, 110b, and 110c are subpixels of three colors of red (R), green (G), and blue (B) or subpixels of three colors of yellow (Y), cyan (C), and magenta (M), for example. The number of types of subpixels is not limited to three and may be four or more. The four subpixels are subpixels of four colors of R, G, B, and white (W), subpixels of four colors of R, G, B, and Y, or subpixels of four types of R, G, B, and infrared light (IR), for example.

In this specification and the like, the row direction is referred to as X direction and the column direction is referred to as Y direction, in some cases. The X direction and the Y direction intersect with each other and are, for example, orthogonal to each other (see FIG. 1A).

FIG. 1A illustrates an example in which subpixels of different colors are arranged in the X direction and subpixels of the same color are arranged in the Y direction. In FIG. 1A, the subpixels 110a, 110b, and 110c included in the pixel 110 are arranged in this order in the X direction. In the pixel 110, the subpixel 110a and the subpixel 110b are adjacent to each other in the X direction, and the subpixel 110b and the subpixel 110c are adjacent to each other in the X direction. The subpixel 110c included in a pixel 110 is adjacent in the X direction to the subpixel 110a included in another pixel 110 that is adjacent in the X direction. In FIG. 1A, the subpixels 110a, 110b, and 110c included in a pixel 110 are respectively adjacent in the Y direction to the subpixels 110a, 110b, and 110c included in another pixel 110 that is adjacent in the Y direction.

Although the top view of FIG. 1A illustrates an example in which the connection portion 145 is positioned in the lower side of the display portion, one embodiment of the present invention is not particularly limited thereto. The connection portion 145 is provided in at least one of the upper side, the right side, the left side, and the lower side of the display portion in the top view, and may be provided so as to surround the four sides of the display portion. The top surface shape of the connection portion 145 can be a belt-like shape, an L shape, a U shape, a frame-like shape, or the like. The number of the connection portions 145 can be one or more.

FIG. 1B illustrates a cross-sectional view along the dashed-dotted line X1-X2 in FIG. 1A. FIG. 1C illustrates a cross-sectional view along the dashed-dotted line Y1-Y2 in FIG. 1A.

As illustrated in FIG. 1B, in the display apparatus 100, insulating layers 255a, 255b, and 255c are provided over a layer 101 including transistors, light-emitting devices 130a, 130b, and 130c are provided over the insulating layers, and a protective layer 131 is provided to cover these light-emitting devices. The light-emitting device 130a is a light-emitting device corresponding to the subpixel 110a, the light-emitting device 130b is a light-emitting device corresponding to the subpixel 110b, and the light-emitting device 130c is a light-emitting device corresponding to the subpixel 110c, for example. A substrate 120 is bonded to the protective layer 131 with a resin layer 122.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 including transistors can employ a stacked-layer structure in which a plurality of transistors are provided over a substrate and an insulating layer is provided to cover these transistors, for example. The insulating layer over the transistors may have a single-layer structure or a stacked-layer structure. In FIG. 1B and the like, the insulating layer 255a, the insulating layer 255b over the insulating layer 255a, and the insulating layer 255c over the insulating layer 255b are illustrated as the insulating layer over the transistors. These insulating layers may have a depressed portion between adjacent light-emitting devices. In the example illustrated in FIG. 1B and the like, the insulating layer 255c is provided with a depressed portion.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and that a silicon nitride film be used as the insulating layer 255b. The insulating layer 255b preferably has a function of an etching protective film.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

Structure examples of the layer 101 including transistors will be described in Embodiment 3 and Embodiment 4.

The light-emitting devices 130a, 130b, and 130c emit light of different colors. Preferably, the light-emitting devices 130a, 130b, and 130c emit light of three colors, red (R), green (G), and blue (B), for example.

As the light-emitting devices 130a, 130b, and 130c, an EL device such as an OLED (Organic Light Emitting Diode) or a QLED (Quantum-dot Light Emitting Diode) is preferably used. Examples of a light-emitting substance contained in the EL device include a substance that exhibits fluorescence (a fluorescent material), a substance that exhibits phosphorescence (a phosphorescent material), an inorganic compound (a quantum dot material or the like), and a substance that exhibits thermally activated delayed fluorescence (a thermally activated delayed fluorescent (TADF) material). As the TADF material, a material in which the singlet and triplet excited states are in thermal equilibrium may be used. Since such a TADF material has a short emission lifetime (excitation lifetime), it can inhibit a reduction in the efficiency of a light-emitting device in a high-luminance region.

The light-emitting device includes an EL layer between a pair of electrodes. The EL layer includes at least a light-emitting layer. In this specification and the like, one of the pair of electrodes may be referred to as a pixel electrode and the other may be referred to as a common electrode.

One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130a includes a pixel electrode 111a over the insulating layer 255c, an island-shaped layer 113a over the pixel electrode 111a, a common layer 114 over the island-shaped layer 113a, and a common electrode 115 over the common layer 114. In the light-emitting device 130a, the layer 113a and the common layer 114 can be collectively referred to as an EL layer.

The light-emitting device 130b includes a pixel electrode 111b over the insulating layer 255c, an island-shaped layer 113b over the pixel electrode 111b, the common layer 114 over the island-shaped layer 113b, and the common electrode 115 over the common layer 114. In the light-emitting device 130b, the layer 113b and the common layer 114 can be collectively referred to as an EL layer.

The light-emitting device 130c includes a pixel electrode 111c over the insulating layer 255c, an island-shaped layer 113c over the pixel electrode 111c, the common layer 114 over the island-shaped layer 113c, and the common electrode 115 over the common layer 114. In the light-emitting device 130c, the layer 113c and the common layer 114 can be collectively referred to as an EL layer.

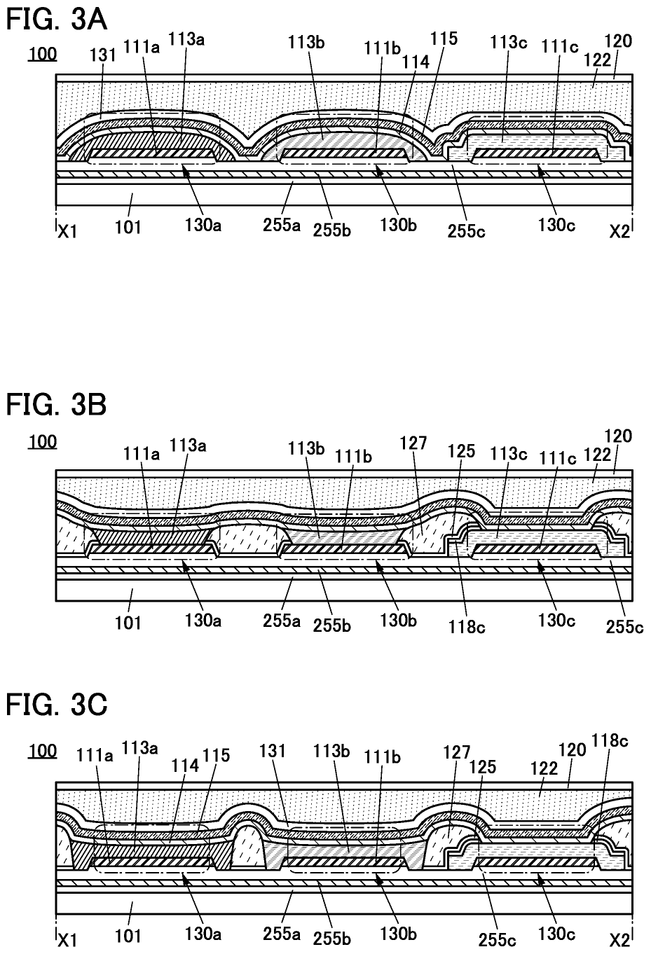

In the case where the layer 113a is formed by an inkjet method in which a droplet is dripped linearly in the Y direction, the thickness of the center region is different from the thickness of the end portion in the X direction in some cases, for example. FIG. 1B and FIG. 3A illustrate examples in which the thickness of the center region is larger than the thickness of the end portion in the X direction. FIG. 3B described later illustrates an example in which the thickness of the center region is smaller than the thickness of the end portion in the X direction.

There is no particular limitation on the structure of the light-emitting device in this embodiment, and the light-emitting device can have a single structure or a tandem structure.

Note that hereafter, in describing matters common to the light-emitting device 130a, the light-emitting device 130b, and the light-emitting device 130c, the alphabets are omitted from the reference numerals and the term “light-emitting device 130” is used in some cases. Similarly, the layer 113a, the layer 113b, and the layer 113c are described using the term “layer 113” in some cases. Similarly, the pixel electrode 111a, the pixel electrode 111b, and the pixel electrode 111c are described using the term “pixel electrode 111” in some cases.

In this embodiment, in the EL layers included in the light-emitting devices, the island-shaped layers provided in the respective light-emitting devices are referred to as the layer 113a, the layer 113b, and the layer 113c, and the layer shared by the plurality of light-emitting devices is referred to as the common layer 114. Note that in this specification and the like, in some cases, the common layer 114 is not included in the EL layers, and the layer 113a, the layer 113b, and the layer 113c are each referred to as an EL layer.

The layer 113a, the layer 113b, and the layer 113c each include at least a light-emitting layer. The layer 113a includes, for example, a light-emitting layer that emits light of a first color selected from red, green, and blue; the layer 113b includes, for example, a light-emitting layer that emits light of a second color that is different from the first color and selected from red, green, and blue; and the layer 113c includes, for example, a light-emitting layer that emits light of a third color that is different from the first color and the second color and selected from red, green, and blue. Here, as an example, the layer 113a includes a red-light-emitting layer, the layer 113b includes a green-light-emitting layer, and the layer 113c includes a blue-light-emitting layer.

The layer 113a, the layer 113b, and the layer 113c may each include one or more of a hole-injection layer, a hole-transport layer, a hole-blocking layer, a charge-generation layer, an electron-blocking layer, an electron-transport layer, and an electron-injection layer.

The layer 113a, the layer 113b, and the layer 113c may each include a hole-injection layer, a hole-transport layer, a light-emitting layer, and an electron-transport layer, for example. In addition, an electron-blocking layer may be provided between the hole-transport layer and the light-emitting layer. Furthermore, an electron-injection layer may be provided over the electron-transport layer.

The layer 113a, the layer 113b, and the layer 113c may each include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The layer 113a, the layer 113b, and the layer 113c each preferably include a light-emitting layer and a carrier-transport layer (an electron-transport layer or a hole-transport layer) over the light-emitting layer. Since surfaces of the layer 113a, the layer 113b, and the layer 113c are exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

Alternatively, the layer 113a, the layer 113b, and the layer 113c each include a first light-emitting unit, a charge-generation layer, and a second light-emitting unit, for example. It is preferable that the layer 113a include two or more light-emitting units that emit red light, the layer 113b include two or more light-emitting units that emit green light, and the layer 113c include two or more light-emitting units that emit blue light, for example.

The first light-emitting unit and the second light-emitting unit each include at least a light-emitting layer. The second light-emitting unit preferably includes a light-emitting layer and a carrier-transport layer (an electron-transport layer or a hole-transport layer) over the light-emitting layer. Since the surface of the second light-emitting unit is exposed in the manufacturing process of the display apparatus, providing the carrier-transport layer over the light-emitting layer inhibits the light-emitting layer from being exposed on the outermost surface, so that damage to the light-emitting layer can be reduced. Accordingly, the reliability of the light-emitting device can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting devices 130a, 130b, and 130c.

End portions of the pixel electrode 111a, the pixel electrode 111b, and the pixel electrode 111c each preferably have a tapered shape. When the end portions of these pixel electrodes have a tapered shape, the layer 113a, the layer 113b, and the layer 113c provided along the side surfaces of the pixel electrodes also have a tapered shape, for example. When the side surface of the pixel electrode has a tapered shape, coverage with at least part of the EL layer provided along the side surface of the pixel electrode can be improved. Furthermore, when the side surface of the pixel electrode has a tapered shape, foreign matter (also referred to as dust or particles, for example) in the manufacturing process is easily removed by treatment such as cleaning, which is preferable. Note that in this specification and the like, a tapered shape indicates a shape in which at least part of a side surface of a structure is inclined to a substrate surface. For example, a region where the angle formed between the inclined side surface and the substrate surface (also referred to as a taper angle) is less than 90° is preferably included.

The common electrode 115 is shared by the light-emitting devices 130a, 130b, and 130c. The common electrode 115 shared by the plurality of light-emitting devices is electrically connected to a conductive layer 123 provided in the connection portion 145 (see FIG. 1C). For the conductive layer 123, it is preferable to use a conductive layer at least part of which is formed using the same material through the same step as at least one of the pixel electrode 111a to the pixel electrode 111c.

Note that the common layer 114 may be provided in the connection portion 145.

The protective layer 131 is preferably provided over the light-emitting devices 130a, 130b, and 130c. Providing the protective layer 131 can improve the reliability of the light-emitting devices. The protective layer 131 may have a single-layer structure or a stacked-layer structure of two or more layers.

There is no limitation on the conductivity of the protective layer 131. As the protective layer 131, at least one type of insulating films, semiconductor films, and conductive films can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

In the display apparatus of this embodiment, the distance between the light-emitting devices can be narrowed. Specifically, the distance between the light-emitting devices, the distance between the layers 113, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where an interval between two adjacent island-shaped layers 113 is less than or equal to 1 μm, preferably less than or equal to 0.5 μm (500 nm), further preferably less than or equal to 100 nm.

A light-blocking layer may be provided on the surface of the substrate 120 on the resin layer 122 side. Moreover, a variety of optical members can be provided on the outer surface of the substrate 120. Examples of optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. For the surface protective layer, a material having a high visible-light-transmittance is preferably used. For the surface protective layer, a material with high hardness is preferably used. In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

In the case of using a film as the substrate 120, examples of a highly optically isotropic film include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

In the display apparatus of one embodiment of the present invention, the thicknesses of the layer 113a to the layer 113c may different from one another. The thicknesses may be set in accordance with optical path lengths that intensify light emitted from the layer 113a to the layer 113c. A microcavity structure can be achieved in this manner, and the color purity of each light-emitting device can be increased.

The thickness of the layer 113 or the like may be set so that the optical path length is mλ/2 (m is a positive integer) or the vicinity thereof when the wavelength of light obtained from the light-emitting layer of the light-emitting device is 2.

Note that in the case where three light-emitting devices exhibit red, green, and blue and have the same m of mλ/2, the layer 113a emitting light whose wavelength is the longest may be the thickest, and the layer 113c emitting light whose wavelength is the shortest may be the thinnest, for example.

The same does not apply to the case where the value of m is different among the light-emitting devices. For example, there is a case where the layer 113c has the largest thickness.

Without limitation to this, the thicknesses of the layers 113 can be adjusted in consideration of the wavelengths of light emitted from the light-emitting devices, the optical characteristics of the layers included in the light-emitting devices, the electrical characteristics of the light-emitting devices, and the like. The thickness of the layer 113 may be a thickness of a center region of the layer 113, for example. Alternatively, the thickness of the layer 113 may be, for example, a thickness of the layer 113 in a portion where the layer 113 is the thickest in a region where the layer 113 and the pixel electrode 111 overlap with each other. Alternatively, the thickness of the layer 113 may be a thickness of the layer 113 in the barycenter of a region where the layer 113 and the pixel electrode 111 overlap with each other.

Note that the optical path length of the light-emitting device can be adjusted not only by making the thicknesses of the layer 113a to the layer 113c different from one another but also by making the thicknesses of the pixel electrode 111a to the pixel electrode 111c different from one another. Specifically, when the pixel electrode 111 is a reflective electrode having a stacked-layer structure of a conductive material having a reflective property (a reflective conductive film) and a conductive material having a light-transmitting property (a transparent conductive film), for example, making the thickness of the transparent conductive film different between the light-emitting devices that exhibit different colors enables the optical path lengths suitable for each color.

For simplicity, figures or the like in this specification do not clearly show the difference in the thicknesses of the layer 113 and the pixel electrode 111 between the light-emitting devices; however, the thicknesses are preferably adjusted as appropriate in each light-emitting device to intensify light with a wavelength corresponding to each light-emitting device.

In addition to the light-emitting layer, the layer 113a, the layer 113b, and the layer 113c may each further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular weight compound or a high molecular weight compound can be used for the light-emitting device, and an inorganic compound may also be included. Examples of the high molecular weight compound include an oligomer, a dendrimer, and a polymer. Each layer included in the light-emitting device can be formed by a wet process. Each layer included in the light-emitting device can be formed by an evaporation method (including a vacuum evaporation method).

A wet process is the method in which a liquid composition is obtained by a process of dissolution or dispersion of a material having a predetermined function into a solvent for liquefaction and the liquid composition is applied. Examples of the material having a predetermined function include layers including a material having a hole-injection property, a material having a hole-transport property, a light-emitting material, a material having an electron-transport property, and a material having an electron-injection property. The liquid composition is referred to as a droplet or an ink material in some cases. After being applied, the liquid composition is solidified or made to be a thin film through a drying step or a curing step, whereby the above-described organic compound layer can be obtained. A high molecular weight compound is preferable as a material used in a wet process because it is easily mixed with a solvent. Alternatively, a monomer that can form a high molecular weight compound can be mixed in a solvent and used in a wet process. The monomer forms a high molecular weight compound through a step after the application. Among layers included in the light-emitting device, a layer formed by a wet process includes a high molecular weight compound, for example. For example, a layer formed by a wet process includes a high molecular weight compound, and a layer formed by an evaporation method includes a low molecular weight compound.

Note that a material used in a wet process is not limited to a high molecular weight compound. As a material used in a wet process, a low molecular weight compound may be used. As a material used in a wet process, a mixture of a high molecular weight compound and a low molecular weight compound may be used.

The high molecular weight compound is a polymer having molecular weight distribution, for example. The average molecular weight of the high molecular weight compound is, for example, higher than or equal to 1000 and lower than or equal to 1×10⁸. The low molecular weight compound is a compound that does not have molecular weight distribution and has a molecular weight of lower than or equal to 1×10⁴, for example. Note that the molecular weight of the low molecular weight compound is preferably lower than or equal to 2000, further preferably lower than 1000. When having a molecular weight within the above-described range, the low molecular weight compound can be formed with an evaporation apparatus, for example.

Examples of a wet process include a printing method such as an inkjet method, a screen (stencil printing) method, an offset (planography) method, a flexography (relief printing) method, a gravure method, or a micro-contact printing method and an application method such as a dip coating method, a die coating method, a bar coating method, a spin coating method, or a spray coating method. A wet process generates fewer waste materials than an evaporation method, and thus the cost can be reduced.

For example, the layer 113a, the layer 113b, and the layer 113c may each include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting device does not necessarily include the common layer 114.

The layer 113a, the layer 113b, and the layer 113c each preferably include a light-emitting layer and a carrier-transport layer over the light-emitting layer. Accordingly, the light-emitting layer is inhibited from being exposed on the outermost surface in the manufacturing process of the display apparatus 100, so that damage to the light-emitting layers can be reduced. Accordingly, the reliability of the light-emitting devices can be improved.

In FIG. 1B, the layers 113 included in the adjacent light-emitting devices overlap each other in a region. The overlapping layers 113 include light-emitting layers of different colors from each other. In the overlap region, the chromaticity might be decreased due to light emission corresponding to two different colors. Thus, it is preferable that the overlap region overlap with neither of the pixel electrodes included in the adjacent light-emitting devices.

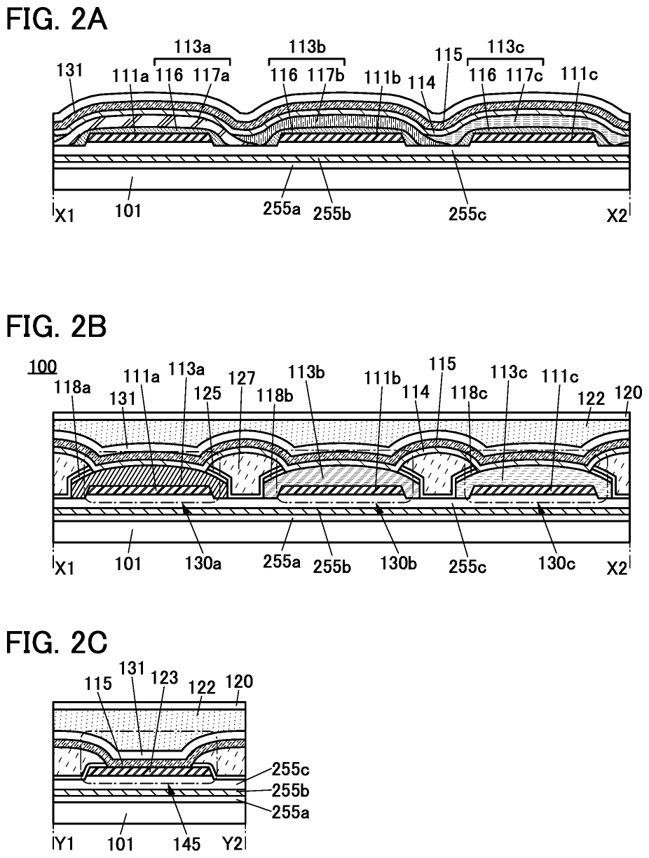

As illustrated in FIG. 2A, the layer 113a can have a stacked-layer structure of a layer 116 and a layer 117a over the layer 116. The layer 113b can have a stacked-layer structure of the layer 116 and a layer 117b over the layer 116. The layer 113c can have a stacked-layer structure of the layer 116 and a layer 117c over the layer 116. The layer 116 preferably includes one or two or more layers selected from a hole-injection layer and a hole-transport layer. The layer 117a preferably includes a light-emitting layer containing a red-light-emitting material. The layer 117b preferably includes a light-emitting layer containing a green-light-emitting material. The layer 117c preferably includes a light-emitting layer containing a blue-light-emitting material.

Next, materials that can be used for the light-emitting device will be described.

### <Light-Emitting Layer>

The light-emitting layer contains a light-emitting material (also referred to as a light-emitting substance). The light-emitting layer can contain one or more kinds of light-emitting substances. As the light-emitting substance, a substance exhibiting light emission of a color such as blue, violet, bluish violet, green, yellowish green, yellow, orange, or red is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a hole-transport material and an electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (a phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

### <Hole-Injection Layer>

The hole-injection layer is a layer injecting holes from an anode to the hole-transport layer, and a layer containing a material with a high hole-injection property. Examples of a material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used. As the material with a high hole-injection property, a mixed material in which the above-described oxide of a metal belonging to any of Groups 4 to 8 of the periodic table (typically, molybdenum oxide) and an organic material are mixed may be used.

### <Hole-Transport Layer>

The hole-transport layer is a layer transporting holes, which are injected from the anode by the hole-injection layer, to the light-emitting layer. The hole-transport layer is a layer that contains a hole-transport material. As the hole-transport material, a substance having a hole mobility of 1×10⁻⁶ cm²/Vs or higher is preferable. Note that other substances can also be used as long as the substances have a hole-transport property higher than an electron-transport property. As the hole-transport material, a material with a high hole-transport property such as a π-electron rich heteroaromatic compound (e.g., a carbazole derivative, a thiophene derivative, or a furan derivative) or an aromatic amine (a compound having an aromatic amine skeleton) is preferable.

### <Electron-Transport Layer>

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility of 1×10⁻⁶ cm²/Vs or higher is preferable. Note that other substances can also be used as long as the substances have an electron-transport property higher than a hole-transport property. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

### <Electron-Injection Layer>

The electron-injection layer is a layer injecting electrons from the cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used. Note that it is preferable that a material with a high electron-injection property be a material whose lowest unoccupied molecular orbital (LUMO) level value has a small difference from the work function value of a material used for the common electrode; for example, the difference of value is preferably lower than or equal to 0.5 eV.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. In addition, the electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino [2,3-a: 2′,3′-c]phenazine (abbreviation: HATNA), 2,4,6-tris [3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

### <Charge-Generation Layer>

In the case of manufacturing a light-emitting device having a tandem structure, a charge-generation layer (also referred to as an intermediate layer) is provided between two light-emitting units. The intermediate layer has a function of injecting electrons into one of the two light-emitting units and injecting holes to the other when a voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. For the charge-generation layer, a layer containing a hole-transport material and an acceptor material (an electron-accepting material) can be used. For the charge-generation layer, a layer containing an electron-transport material and a donor material can be used. Forming such a charge-generation layer can inhibit an increase in driving voltage that would be caused by stacking light-emitting units.

### <Pixel Electrode and Common Electrode>

A conductive film transmitting visible light is used as the electrode through which light is extracted, which is either the pixel electrode or the common electrode. A conductive film reflecting visible light is preferably used as the electrode through which light is not extracted. In the case where a display apparatus includes a light-emitting device emitting infrared light, a conductive film transmitting visible light and infrared light is used as the electrode through which light is extracted, and a conductive film reflecting visible light and infrared light is preferably used as the electrode through which light is not extracted.

A conductive film transmitting visible light may be used also for an electrode through which no light is extracted. In that case, this electrode is preferably provided between a reflective layer and the EL layer. In other words, light emitted by the EL layer may be reflected by the reflective layer to be extracted from the display apparatus.

As a material that forms the pair of electrodes (the pixel electrode and the common electrode) of the light-emitting device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not exemplified above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting device preferably employs a microcavity structure. Therefore, one of the pair of electrodes included in the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with a wavelength longer than or equal to 400 nm and shorter than 750 nm) transmittance higher than or equal to 40% is preferably used in the light-emitting device. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity of 1×10⁻² Ωcm or lower.

For the pixel electrode 111, for example, a metal material such as aluminum, gold, platinum, silver, nickel, tungsten, chromium, molybdenum, iron, cobalt, copper, or palladium or an alloy containing any of these metal materials can be used. Copper is preferably used because of its high reflectance with respect to visible light. Aluminum is preferable because an aluminum electrode is easily etched and thus is easily processed, and aluminum has high reflectance with respect to visible light and near-infrared light. Lanthanum, neodymium, germanium, or the like may be added to the above-described metal material or alloy. An alloy (an aluminum alloy) containing aluminum and titanium, nickel, or neodymium may be used. An alloy containing silver and copper, palladium, or magnesium may be used. An alloy containing silver and copper is preferable because of its high heat resistance.

Alternatively, for the pixel electrode 111, for example, indium oxide, indium tin oxide, indium zinc oxide, zinc oxide, or zinc oxide to which gallium is added can be used. Alternatively, a metal material such as gold, silver, platinum, magnesium, nickel, tungsten, chromium, molybdenum, iron, cobalt, copper, palladium, or titanium; an alloy containing any of these metal materials; a nitride of any of these metal materials (e.g., titanium nitride), or the like formed thin enough to have a light-transmitting property can be used. Furthermore, a stacked-layer film of the above materials can be used as a conductive layer. For example, a stacked-layer film of indium tin oxide and an alloy of silver and magnesium is preferably used, in which case conductivity can be increased. Further alternatively, graphene or the like may be used.

For the pixel electrode 111, a single-layer structure or a stacked-layer structure using a film containing the material exemplified above can be employed.

The pixel electrode 111 may have a structure in which a conductive metal oxide film is stacked over a conductive film that reflects visible light. With such a structure, oxidization and corrosion of the conductive film reflecting visible light can be inhibited. When a metal film or a metal oxide film is stacked in contact with an aluminum film or an aluminum alloy film, for example, oxidization can be inhibited. Examples of a material for the metal film or the metal oxide film include titanium and titanium oxide. Alternatively, the above conductive film that transmits visible light and a film containing a metal material may be stacked. For example, a stacked-layer film of silver and indium tin oxide or a stacked-layer film of an alloy of silver and magnesium and indium tin oxide can be used.

### <Protective Layer 131>

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer side.

Furthermore, the protective layer 131 may include an organic film. For example, the protective layer 131 may include both an organic film and an inorganic film. Examples of an organic material that can be used for the protective layer 131 include organic insulating materials or the like that can be used for an insulating layer 127 described later.

The protective layer 131 may have a two-layer structure formed by different film formation methods. Specifically, the first layer of the protective layer 131 may be formed by an ALD method, and the second layer of the protective layer 131 may be formed by a sputtering method.

### <Substrate 120>

For the substrate 120, glass, quartz, ceramic, sapphire, a resin, a metal, an alloy, a semiconductor, or the like can be used. For the substrate through which light from the light-emitting device is extracted, a material that transmits the light is used. When the substrate 120 is formed using a flexible material, the flexibility of the display apparatus can be increased. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

### <Resin Layer 122>

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

### <Light-Receiving Device>

The display apparatus of one embodiment of the present invention may include a light-receiving device in the pixel. For example, one or more of a plurality of subpixels included in the pixel may include a light-emitting device(s) and one or more of a plurality of subpixels included in the pixel may include a light-receiving device(s).

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode including a layer containing an organic compound as the light-receiving device. An organic photodiode, which is easily made thin, lightweight, and large in area and has a high degree of freedom in shape and design, can be used for a variety of display apparatuses.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

The light-receiving device includes at least an active layer that functions as a photoelectric conversion layer between a pair of electrodes. In this specification and the like, one of the pair of electrodes may be referred to as a pixel electrode and the other may be referred to as a common electrode.

One of the pair of electrodes of the light-receiving device functions as an anode, and the other electrode functions as a cathode. The case where the pixel electrode functions as an anode and the common electrode functions as a cathode is described below as an example. The light-receiving device is driven by application of reverse bias between the pixel electrode and the common electrode, whereby light entering the light-receiving device can be detected and electric charge can be generated and extracted as a current. Alternatively, the pixel electrode may function as a cathode and the common electrode may function as an anode.

By replacing the layer 113 with an active layer (also referred to as a photoelectric conversion layer) of a photoelectric conversion device, the light-emitting device 130 can function as a light-receiving device. Furthermore, layers other than the layer 113 can be formed using the same materials, which can increase productivity. Since the common layer 114 and the common electrode 115 can be shared by the light-emitting device and the light-receiving device, productivity can be increased.

A manufacturing method similar to that for the light-emitting device can be employed for the light-receiving device. The island-shaped active layer included in the light-receiving device may be provided by application of a droplet only in the active layer region by an inkjet method. Alternatively, an application method or an evaporation method may be used to form a film to be the active layer over the entire surface, and then the film may be processed into the island-shaped active layer. Moreover, providing the mask layer over the active layer can reduce damage to the active layer in the manufacturing process of the display apparatus, resulting in an improvement in reliability of the light-receiving device.

Here, a layer used in common to the light-receiving device and the light-emitting device may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer used in common to the light-receiving device and the light-emitting device may have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

In the display apparatus including the light-emitting device and the light-receiving device in each pixel, the pixel has a light-receiving function; thus, the display apparatus can detect a contact or approach of an object while displaying an image. For example, an image can be displayed by all the subpixels included in the display apparatus; or light can be emitted by some of the subpixels as a light source and an image can be displayed by the other subpixels.

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of an object (e.g., a finger, a hand, or a pen) can be detected. Furthermore, in the display apparatus of one embodiment of the present invention, the light-emitting device can be used as a light source of the sensor. Accordingly, a light-receiving portion and a light source do not need to be provided separately from the display apparatus; hence, the number of components in an electronic device can be reduced. For example, a fingerprint authentication device, a capacitive touch panel for scroll operation, or the like is not necessarily provided separately from the electronic device. Thus, with the use of the display apparatus of one embodiment of the present invention, the electronic device can be provided with reduced manufacturing cost.

In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

In the case where the light-receiving device is used as an image sensor, the display apparatus can capture an image with the use of the light-receiving device. For example, the display apparatus of this embodiment can be used as a scanner.

For example, data on biological information such as a fingerprint or a palm print can be obtained with use of the image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus; thus, the size and weight of the electronic device can be reduced.

In the case where the light-receiving device is used as the touch sensor, the display apparatus can detect the approach or contact of an object with the use of the light-receiving device.

The display apparatus of one embodiment of the present invention can have one or both of an image capturing function and a sensing function in addition to an image displaying function. Thus, the display apparatus of one embodiment of the present invention can be regarded as highly compatible with the function other than the display function.

### [Structure Example 2 of Display Apparatus]

FIG. 2B and FIG. 2C illustrate an example of a display apparatus having a structure different from that illustrated in FIG. 1B and FIG. 1C.

FIG. 2B illustrates a structure in which part of each of the layer 113a, the layer 113b, and the layer 113c included in the light-emitting devices in FIG. 1B is removed. The region removed in the layer 113 includes a region overlapping with the layer 113 included in the adjacent light-emitting device.

In FIG. 2B, an insulating layer 125 and the insulating layer 127 over the insulating layer 125 are provided in a region between the adjacent light-emitting devices. In FIG. 2C, the insulating layer 125 and the insulating layer 127 over the insulating layer 125 are provided on both sides of the conductive layer 123.

In FIG. 2B and FIG. 2C, the layer 113a, the layer 113b, and the layer 113c are separated from each other. The layers 113 included in the adjacent light-emitting devices are separated by the insulating layer 125 and the insulating layer 127. Thus, leakage of a current between the layers 113 included in the adjacent light-emitting devices can be reduced, for example.

The insulating layer 127 is provided over the insulating layer 125 to fill a depressed portion formed in the insulating layer 125. The insulating layer 127 can overlap with the side surface and part of the top surface of each of the layer 113a, the layer 113b, and the layer 113c, with the insulating layer 125 therebetween.

The insulating layer 125 and the insulating layer 127 can fill a gap between adjacent island-shaped layers, whereby the formation surfaces of layers (e.g., the carrier-injection layer and the common electrode) provided over the island-shaped layers can have reduced extreme unevenness and can be flatter. Thus, the coverage with the carrier-injection layer, the common electrode, and the like can be increased and disconnection of the common electrode can be prevented.

Although FIG. 2B or the like illustrates a plurality of cross sections of the insulating layer 125 and the insulating layer 127, the insulating layer 125 and the insulating layer 127 are each one continuous layer when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other, and may include a plurality of insulating layers 127 that are separated from each other.

### <Insulating Layer 125>

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure.

Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the layer 113 in etching and has a function of protecting the layer 113 when the later-described insulating layer 127 is formed. When an inorganic insulating film such as an aluminum oxide film, a hafnium oxide film, or a silicon oxide film is formed by an ALD method as the insulating layer 125, the insulating layer 125 can have few pinholes and an excellent function of protecting the layer 113. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, degradation of the layer 113, which is caused by entry of impurities into the layer 113 from the insulating layer 125, can be inhibited. In addition, when the impurity concentration is reduced in the insulating layer 125, a barrier property against at least one of water and oxygen can be increased. For example, it is desirable that one or both of the hydrogen concentration and the carbon concentration in the insulating layer 125 be sufficiently low.

The insulating layer 125 can be formed by a sputtering method, a CVD method, a pulsed laser deposition (PLD) method, an ALD method, or the like. The insulating layer 125 is preferably formed by an ALD method achieving good coverage.

When the substrate temperature at the time when the insulating layer 125 is formed is increased, the formed insulating layer 125, even with a small thickness, can have a low impurity concentration and a high barrier property against at least one of water and oxygen. Thus, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of an island-shaped layer 113, it is preferable that the insulating layer 125 be formed at a temperature lower than the heat resistance temperature of the layer 113. Thus, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the heat resistance temperature include the glass transition point, the softening point, the melting point, the thermal decomposition temperature, and the 5% weight loss temperature. The heat resistance temperature of the layer 113 can be, for example, any of the above-mentioned temperatures, preferably the lowest temperature of the above-mentioned temperatures.

As the insulating layer 125, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

### <Insulating Layer 127>

The insulating layer 127 provided over the insulating layer 125 has a planarization function for extreme unevenness on the insulating layer 125 formed between adjacent light-emitting devices. In other words, the insulating layer 127 brings an effect of improving the flatness of the formation surface of the common electrode 115.

As the insulating layer 127, an insulating layer containing an organic material can be favorably used. As the organic material, a photosensitive organic resin is preferably used; for example, a photosensitive acrylic resin may be used. The viscosity of the material of the insulating layer 127 is greater than or equal to 1 cP and less than or equal to 1500 cP, and is preferably greater than or equal to 1 cP and less than or equal to 12 cP. By setting the viscosity of the material of the insulating layer 127 in the above-described range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material that can be used for the insulating layer 127 is not limited to the above as long as the insulating layer 127 has a tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used in some cases, for example. Alternatively, an organic material such as polyvinyl alcohol (PVA), polyvinylbutyral, polyvinylpyrrolidone, polyethylene glycol, polyglycerin, pullulan, water-soluble cellulose, an alcohol-soluble polyamide resin, or the like can be employed for the insulating layer 127 in some cases. As the photosensitive resin, a photoresist can be used in some cases. As the photosensitive resin, a positive material or a negative material can be used in some cases.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 127 is preferably formed by spin coating.

The insulating layer 127 is formed at a temperature lower than the heat resistance temperature of the layer 113. The typical substrate temperature in formation of the layer 127 is lower than or equal to 200° C., preferably lower than or equal to 180° C., further preferably lower than or equal to 160° C., still further preferably lower than or equal to 150° C., yet still further preferably lower than or equal to 140° C.

### [Structure Example 3 of Display Apparatus]

As described later, in the display apparatus 100 illustrated in FIG. 3A, the layer 113a and the layer 113b can be formed by an inkjet method and the layer 113c can be formed by an evaporation method. The use of an evaporation method makes the thickness of the layer 113c formed over the pixel electrode 111c highly uniform. The use of an inkjet method makes the top surfaces of the layer 113a and the layer 113b have smoothly curved surfaces.

### [Structure Example 4 of Display Apparatus]

The display apparatus 100 illustrated in FIG. 3B is an example in which the structure where the top surface of the layer 113 included in the light-emitting device is covered with the insulating layer 125 and the structure where the top surface of the layer 113 included in the light-emitting device is not covered with the insulating layer 125 are mixed.

In FIG. 3B, the insulating layer 125 covers the side surface of the layer 113c. The insulating layer 125 includes a region overlapping with the top surface of the layer 113c with a mask layer 118 therebetween.

Meanwhile, in FIG. 3B, the insulating layer 125 overlaps with neither the top surface of the layer 113a nor the top surface of the layer 113b.

A mask layer 118c is a remnant of a mask layer provided in contact with the top surface of the layer 113c at the time of forming the layer 113c in the manufacturing process of the display apparatus 100 described later. In FIG. 3B or the like, one end portion of the mask layer 118c is aligned or substantially aligned with the end portion of the layer 113c, and the other end portion of the mask layer 118c is positioned over the layer 113c. Here, the other end portion of the mask layer 118c preferably overlaps with the layer 113c and the pixel electrode 111c. In that case, the other end portion of the mask layer 118c is likely to be formed on a substantially flat surface of the layer 113c.

In FIG. 3B, an insulating layer covering an end portion of the top surface of the pixel electrode 111c is not provided between the pixel electrode 111c and the layer 113c. Thus, the distance between adjacent light-emitting devices can be extremely shortened. Accordingly, the display apparatus can have a high resolution or a high definition.

The layer 113a and the layer 113b can be formed by any of various methods, but in particular is preferably formed by an inkjet method. The layer 113c can be formed by, for example, a vacuum evaporation method.

In the case where the layer 113a and the layer 113b are formed by an inkjet method, the layer 113a and the layer 113b can be formed in a self-aligned manner using the opening portion of the insulating layer 127 covering the side surface of the layer 113c. Thus, the distance between the light-emitting device 130c and the light-emitting device 130a and the distance between the light-emitting device 130c and the light-emitting device 130b can be extremely shortened. Accordingly, the display apparatus can have a high resolution or a high definition.

Although FIG. 1B illustrates an example in which the thickness of the end portion in the X direction is smaller than the thickness of the center region, the thickness of the end portion in the X direction is larger than the thickness of the center region in FIG. 3B where diffusion in the X direction is limited by the insulating layer 125 provided adjacent to the layer 113a. Depending on the liquid amount of the dripped droplet, the thickness of the center region may be larger than the thickness of the end portion in the X direction. The thickness distribution of the layer 113a and the shape of the layer 113a change depending on the droplet and wettability of a formation surface.

Although FIG. 3B illustrates an example in which the layer 113a and the layer 113b each do not overlap with the top surface of the insulating layer 127, part of the layer 113a may be formed over the insulating layer 127 in the case where the liquid amount of the dripped droplet is large.

An end portion of the top surface of the pixel electrode 111a and an end portion of the top surface of the pixel electrode 111b may be covered with the insulating layer 125 as illustrated in FIG. 3B or not covered with the insulating layer 125 as illustrated in FIG. 3C.

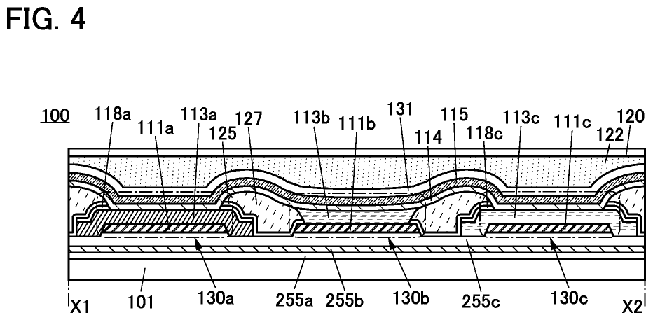

In the display apparatus 100 illustrated in FIG. 4, the insulating layer 125 covers the side surfaces of the layer 113a and the layer 113c. In FIG. 4, the insulating layer 125 includes a region overlapping with the top surface of the layer 113a with a mask layer 118a therebetween and a region overlapping with the top surface of the layer 113c with the mask layer 118c therebetween.

In FIG. 4, the insulating layer 125 does not overlap with the top surface of the layer 113b.

### [Structure Example 5 of Display Apparatus]

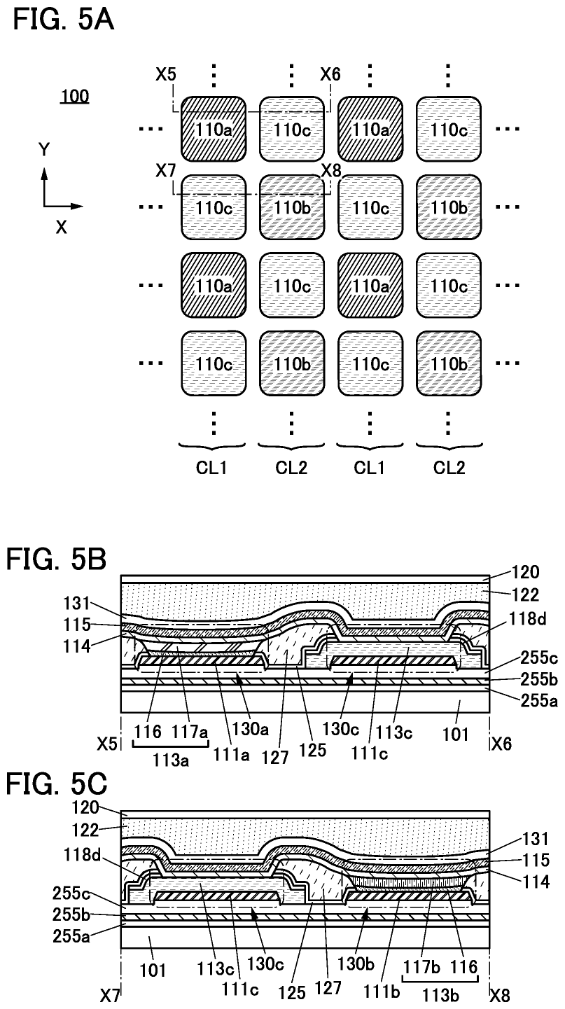

FIG. 5A to FIG. 5C illustrate an example of the display apparatus 100. FIG. 5B and FIG. 5C illustrate an example in which the subpixels 110a, 110b, and 110c illustrated in FIG. 5A correspond respectively to the light-emitting devices 130a, 130b, and 130c illustrated in FIG. 3B. FIG. 5B is a cross-sectional view along the dashed-dotted line X5-X6 in FIG. 5A. FIG. 5C is a cross-sectional view along the dashed-dotted line X7-X8 in FIG. 5A.

In FIG. 5A, columns CL1 and columns CL2 are alternately arranged in a display region of the display apparatus 100. The subpixels 110a and the subpixels 110c are alternately arranged in the Y direction in the column CL1, and the subpixels 110c and the subpixels 110b are alternately arranged in the Y direction in the column CL2.

The subpixel 110a is sandwiched between two subpixels 110c in the X direction and is sandwiched between two subpixels 110c in the Y direction. The subpixel 110a can be expressed as being surrounded on four sides by the subpixels 110c.

The subpixel 110b is sandwiched between two subpixels 110c in the X direction and is sandwiched between two subpixels 110c in the Y direction. The subpixel 110b can be expressed as being surrounded on four sides by the subpixels 110c.

Note that FIG. 5A omits part of the structure illustrated in FIG. 1A, e.g., the connection portion 145 or the like, for simplicity.

In the structure illustrated in FIG. 5A, the total area of the subpixels 110c included in the display portion can be easily set larger than the total area of the subpixels 110a and larger than the total area of the subpixels 110b. Since the total area of the subpixels 110c can be relatively large, the current density of the light-emitting device 130c corresponding to the subpixel 110c can be lowered in the structure illustrated in FIG. 5A. Thus, for example, this structure can be suitably used when the lifetime of the light-emitting device 130c corresponding to the subpixel 110c is shorter than those of the light-emitting device 130a corresponding to the subpixel 110a and the light-emitting device 130b corresponding to the subpixel 110b.

For example, in the case where the lifetime of the light-emitting device exhibiting blue light emission is shorter than those of the light-emitting device exhibiting red light emission and the light-emitting device exhibiting green light emission, the layer 113c is made to have a structure including a light-emitting layer exhibiting blue light emission, one of the layer 113a and the layer 113b is made to have a structure including a light-emitting layer exhibiting red light emission, and the other thereof is made to have a structure including a light-emitting layer exhibiting green light emission.

In the structure illustrated in FIG. 5A, for example, the layer 113a and the layer 113b are formed by an inkjet method, and the layer 113c is formed by a vacuum evaporation method.

For example, in the case where the lifetime of the device including the light-emitting layer exhibiting blue light emission is shorter than those of the device including the light-emitting layer exhibiting red light emission and the device including the light-emitting layer exhibiting green light emission, the light-emitting layer exhibiting blue light emission is formed by a vacuum evaporation method, whereby the lifetime of the light-emitting device can be lengthened in some cases.

That is, with the structure illustrated in FIG. 5A, the current density of the light-emitting device 130c is lowered; in addition, forming the layer 113c by a vacuum evaporation method is suitable for a longer lifetime.

### [Example 1 of Display Apparatus Manufacturing Method]

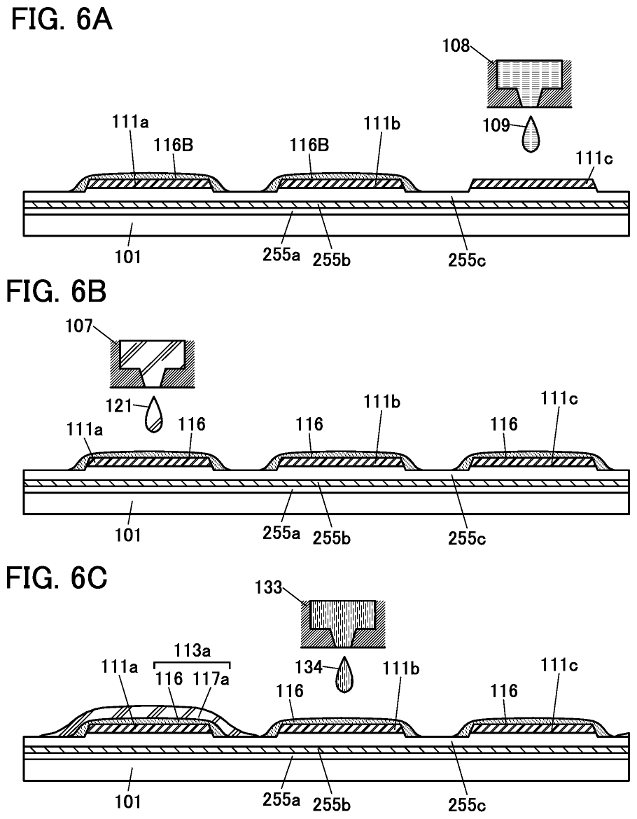

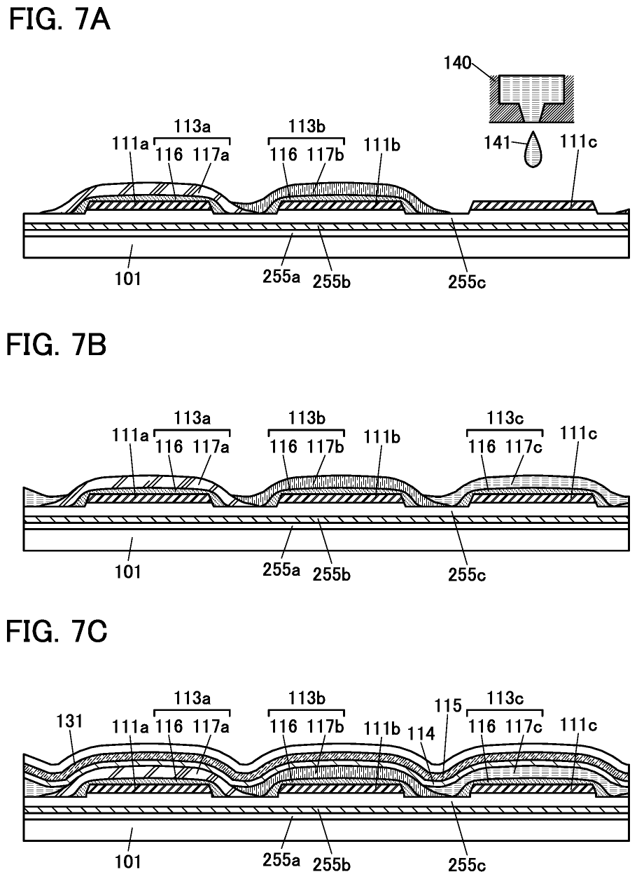

Next, an example of a manufacturing method of the display apparatus 100 illustrated in FIG. 1B or the like is described with reference to FIG. 6A to FIG. 7C.

The thin films that form the display apparatus (e.g., insulating films, semiconductor films, and conductive films) can be formed by a method such as spin coating, dipping, spray coating, ink-jetting, dispensing, screen printing, offset printing, doctor blade coating, slit coating, roll coating, curtain coating, or knife coating.

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic chemical vapor deposition (MOCVD) method.

In particular, for manufacture of light-emitting devices, a solution process such as an inkjet method or a spin coating method and a vacuum process such as an evaporation method can be used. Specifically, functional layers (e.g., a hole-injection layer, a hole-transport layer, a light-emitting layer, an electron-transport layer, and an electron-injection layer) included in the EL layers can be formed by a method such as a printing method (e.g., an inkjet method, a screen (stencil printing) method, an offset (planography) method, a flexography (relief printing) method, a gravure method, or a micro-contact printing method), an application method (e.g., a dip coating method, a die coating method, a bar coating method, a spin coating method, or a spray coating method), or an evaporation method (e.g., a vacuum evaporation method). Examples of an evaporation method include physical evaporation methods (PVD methods) such as a sputtering method, an ion plating method, an ion beam evaporation method, a molecular beam evaporation method, and a vacuum evaporation method, and a chemical evaporation method (CVD method).

When the thin films that form the display apparatus are processed, a photolithography method or the like can be used for the processing. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for light exposure in a photolithography method, it is possible to use light with the i-line (wavelength: 365 nm), light with the g-line (wavelength: 436 nm), light with the h-line (wavelength: 405 nm), or combined light of any of them, for example. Alternatively, ultraviolet rays, KrF laser light, ArF laser light, or the like can be used. Light exposure may be performed by liquid immersion light exposure technique. As the light used for the light exposure, extreme ultra-violet (EUV) light or X-rays may be used. Furthermore, instead of the light used for light exposure, an electron beam can be used. It is preferable to use extreme ultraviolet light,

X-rays, or an electron beam in order to enable extremely minute processing. Note that a photomask is not needed when light exposure is performed by scanning with a beam such as an electron beam.

For etching of thin films, a dry etching method, a wet etching method, a sandblast method, or the like can be used.

First, the insulating layer 255a, the insulating layer 255b, and the insulating layer 255c are formed in this order over the layer 101 including transistors. The above-described structure applicable to the insulating layers 255a, 255b, and 255c can be employed for the insulating layers 255a, 255b, and 255c.

Next, the pixel electrode 111a, the pixel electrode 111b, and the pixel electrode 111c are formed over the insulating layer 255c. A conductive film to be the pixel electrode 111a, the pixel electrode 111b, and the pixel electrode 111c can be formed by a sputtering method or a vacuum evaporation method, for example.

The pixel electrodes 111a, 111b, and 111c each preferably have a tapered shape. This can improve the coverage with the layers formed over the pixel electrodes 111a, 111b, and 111c and improve the manufacturing yield of the light-emitting devices.

Next, a layer 116B is formed over the pixel electrode 111a, the pixel electrode 111b, and the pixel electrode 111c (FIG. 6A). FIG. 6A illustrates a state where one or two or more selected from a hole-transport layer and a hole-injection layer included in the light-emitting devices are dripped by an inkjet method. In the dripping, a nozzle 108 included in an inkjet device and a substrate included in the layer 101 are relatively moved. A droplet 109 is dripped from the nozzle 108 onto the pixel electrode 111a, the pixel electrode 111b, and the pixel electrode 111c. The droplet 109 includes one or two or more selected from a hole-transport layer and a hole-injection layer.

The layer 116B is formed from the dripped droplet 109 over the pixel electrodes. The layer 116 can be formed through removal of a solvent or the like from the layer 116B.

The hole-injection layer can be formed from a droplet containing a hole-injection material. Furthermore, the hole-injection layer can be formed from a droplet containing a hole-transport material. Thus, the hole-injection layer can be formed by a wet process, and the hole-transport layer can be formed by a method other than a wet process. Alternatively, the hole-injection layer can be formed by a method other than a wet process, and the hole-transport layer can be formed by a wet process. Moreover, both the hole-injection layer and the hole-transport layer can be formed by a wet process. Needless to say, both the hole-injection layer and the hole-transport layer may be formed by a method other than a wet process.

The layer 116 is a layer containing a material of the droplet 109 that has remained after the removal of the solvent or the like. The layer 116 contains one or two or more organic compound materials selected from a hole-transport material and a hole-injection material.

The layer 116 may be a stack of a layer formed by a method other than a wet process and a layer formed through removal of the solvent or the like from the droplet 109.

The solvent or the like is preferably removed from the droplet 109 by a drying step or the like. Heat may be applied in the drying step. Furthermore, the layer 116 is preferably subjected to a curing step. The curing step includes one or two or more selected from a light irradiation step and a heating step. As a light source of the light irradiation, an ultraviolet ray or an infrared ray is preferably used.

In the case where both the hole-injection layer and the hole-transport layer are formed by a wet process, it is preferable that one or two or more steps selected from a drying step and a curing step be performed after a droplet for the hole-injection layer is dripped and then dripping for the hole-transport layer be started. Through such steps, the end portion of the hole-injection layer is not aligned with but deviates from the end portion of the hole-transport layer. The layer 116 may include one or two or more layers selected from a hole-injection layer and a hole-transport layer.

When the layer 116 is one or two or more selected from a hole-transport layer and a hole-injection layer, the light-emitting devices can include the layer 116 in common, which means the same organic compound material can be shared by the light-emitting devices. The light-emitting devices refer to the light-emitting devices exhibiting light emission of different colors and the light-emitting devices exhibiting light emission of the same color.

The layer 116 has a layer form in many cases, and thus the shared layer is sometimes referred to as a common layer. Furthermore, when one or two or more selected from the hole-transport layer and the hole-injection layer are common layers, they are sometimes referred to as lower common layers of the light-emitting devices.

The common layer may be independently provided in each of the light-emitting devices or may be continuously provided over the light-emitting devices.

A method other than an inkjet method can be used as a formation method of the common layer; for example, a spin coating method may be used. With a spin coating method, the droplet 109 can be widely applied over the plurality of light-emitting devices.

An evaporation method may be used as a formation method of the common layer. As the evaporation method, a vacuum evaporation method is preferable. With an evaporation method, a film of an evaporation material can be widely formed over the plurality of light-emitting devices.

As the droplet 109, an ink material in which one or more kinds of monomers of a high molecular weight material that is to be obtained as the layer 116 are mixed is used; and heating, energy light irradiation, or the like may be performed after the application of the droplet 109 to form a bond such as cross-linking, condensation, polymerization, coordination, or a salt. Note that the ink material may contain an organic compound having a different function such as a surface active agent or a substance for adjusting viscosity.

The formation of the bond such as cross-linking, condensation, polymerization, coordination, or a salt can inhibit the layer 116 from dissolving in solvents contained in a droplet 121, 134, or 141 at the time of dripping the droplet 121, 134, or 141, which are described later, onto the layer 116 in some cases.

Next, layers each containing a light-emitting material are formed. FIG. 6B to FIG. 7A illustrate dripping of organic compound materials each containing a light-emitting material by an inkjet method.

FIG. 6B illustrates an example of dripping the droplet 121 onto the layer 116 with a nozzle 107. The droplet 121 is dripped onto a region overlapping with the pixel electrode 111a. The droplet 121 contains a red-light-emitting material.

The dripped droplet 121 becomes the layer 117a. The layer 117a is a light-emitting layer containing a red-light-emitting material formed through removal of the solvent or the like from the droplet 121. In FIG. 6B and the like, a stacked-layer structure of the layer 116 and the layer 117a is referred to as the layer 113a. The layer 113a is, for example, an island-shaped layer provided between a pair of electrodes in the light-emitting device 130a and forms at least part of the EL layer.

FIG. 6C illustrates an example of dripping the droplet 134 onto the layer 116 with a nozzle 133. The droplet 134 is dripped onto a region overlapping with the pixel electrode 111b. The droplet 134 contains a green-light-emitting material.

The dripped droplet 134 becomes the layer 117b (FIG. 7A). The layer 117b is a light-emitting layer containing a green-light-emitting material formed through removal of the solvent or the like from the droplet 134. In FIG. 7A and the like, a stacked-layer structure of the layer 116 and the layer 117b is referred to as the layer 113b. The layer 113b is, for example, an island-shaped layer provided between a pair of electrodes in the light-emitting device 130b and forms at least part of the EL layer.

FIG. 7A illustrates an example of dripping the droplet 141 onto the layer 116 with a nozzle 140. The droplet 141 is dripped onto a region overlapping with the pixel electrode 111c. The droplet 141 contains a blue-light-emitting material.

The dripped droplet 141 becomes the layer 117c (FIG. 7C). The layer 117c is a light-emitting layer containing a blue-light-emitting material formed through removal of the solvent or the like from the droplet 141. In FIG. 7C and the like, a stacked-layer structure of the layer 116 and the layer 117c is referred to as the layer 113c. The layer 113c is, for example, an island-shaped layer provided between a pair of electrodes in the light-emitting device 130c and forms at least part of the EL layer.

The solvent or the like is preferably removed from the droplet by a drying step or the like. Heat may be applied in the drying step. Furthermore, the layer 117a, the layer 117b, and the layer 117c are each preferably subjected to a curing step. The curing step includes one or two or more selected from a light irradiation step and a heating step. As a light source of the light irradiation, an ultraviolet ray or an infrared ray is preferably used.

As the droplet 121, an ink material in which one or more kinds of monomers of a high molecular weight material that is to be obtained as the layer 117a are mixed is used; and heating, energy light irradiation, or the like may be performed after the application of the droplet 121 to form a bond such as cross-linking, condensation, polymerization, coordination, or a salt. Note that the ink material may contain an organic compound having a different function such as a surface active agent or a substance for adjusting viscosity. The formation of the bond such as cross-linking, condensation, polymerization, coordination, or a salt in the layer 117a can inhibit the layer 117a from dissolving in the solvent contained in the droplet 134 or 141 in some cases.

As the droplet 134, an ink material in which one or more kinds of monomers of a high molecular weight material that is to be obtained as the layer 117b are mixed is used; and heating, energy light irradiation, or the like may be performed after the application of the droplet 134 to form a bond such as cross-linking, condensation, polymerization, coordination, or a salt. Note that the ink material may contain an organic compound having a different function such as a surface active agent or a substance for adjusting viscosity. The formation of the bond such as cross-linking, condensation, polymerization, coordination, or a salt in the layer 117b can inhibit the layer 117b from dissolving in the solvent contained in the droplet 141 in some cases.

As the droplet 141, an ink material in which one or more kinds of monomers of a high molecular weight material that is to be obtained as the layer 117c are mixed is used; and heating, energy light irradiation, or the like may be performed after the application of the droplet 141 to form a bond such as cross-linking, condensation, polymerization, coordination, or a salt. Note that the ink material may contain an organic compound having a different function such as a surface active agent or a substance for adjusting viscosity.

In consideration of the structure of the light-emitting devices, the light-emitting layer often has a larger thickness than a layer containing one or more selected from a hole-transport material and a hole-injection material. Therefore, the dripping amount of each of the droplet 121, the droplet 134, and the droplet 141 is larger than that of the droplet 109 in some cases.

When the droplet 121 is dripped onto the layer 116, the layer 116 may dissolve in the solvent contained in the droplet 121. When the layer 116 dissolves in the solvent, the layer 116 and the droplet 121 are mixed, which may decrease the emission efficiency of the light-emitting device. As described above, the formation of the bond such as cross-linking, condensation, polymerization, coordination, or a salt in the layer 116 can inhibit the layer 116 from dissolving in the solvent contained in the droplet 121, 134, or 141 in some cases.

Through the above-described steps, the layer 113a over the pixel electrode 111a, the layer 113b over the pixel electrode 111b, and the layer 113c over the pixel electrode 111c can be formed (FIG. 7B).

Next, the common layer 114, the common electrode 115, and the protective layer 131 are formed in order so as to cover the layer 113a, the layer 113b, and the layer 113c (FIG. 7C).

The common layer 114 is one or two or more layers selected from an electron-transport layer and an electron-injection layer.

The common layer 114 can be formed by a method such as an application method, an inkjet method, a transfer method, a printing method, or an evaporation method (including a vacuum evaporation method). The common layer 114 may be formed using a premix material.

Here, the common layer 114 is formed by a spin coating method, for example.

A mask for defining a film formation area (also referred to as an area mask, a rough metal mask, or the like) may be used in the formation of the common electrode 115. Alternatively, the common electrode 115 may be formed without the use of the mask and may be processed with the use of a resist mask or the like after the common electrode 115 is formed.

Materials that can be used for the common electrode 115 are as described above. The common electrode 115 can be formed by a sputtering method or a vacuum evaporation method, for example. Alternatively, a film formed by an evaporation method and a film formed by a sputtering method may be stacked.

Materials and film formation methods that can be used for the protective layer 131 are as described above. Examples of methods for forming the protective layer 131 include a vacuum evaporation method, a sputtering method, a CVD method, and an ALD method. The protective layer 131 may have a single-layer structure or a stacked-layer structure.

Then, the substrate 120 is bonded to the protective layer 131 using the resin layer 122. Through the above-described steps, the display apparatus 100 can be manufactured.

### <Wet Process>

Although an inkjet method and a spin coating method are given as examples of a wet process, another kind of application method, a nozzle printing method, gravure printing, and the like are also included. In an ink-jet method, a spin coating method, or the like, a liquid composition is referred to as a droplet in many cases, but may be referred to as an ink material. Furthermore, although description “a droplet is dripped” is used, description “an ink material is applied” may be used.

Examples of a solvent that can be used in the case where the wet process is employed include: chlorine-based solvents such as dichloroethane, trichloroethane, chlorobenzene, and dichlorobenzene; ether-based solvents such as tetrahydrofuran, dioxane, anisole, and methylanisole; aromatic hydrocarbon-based solvents such as toluene, xylene, mesitylene, ethylbenzene, hexylbenzene, and cyclohexylbenzene; aliphatic hydrocarbon-based solvents such as cyclohexane, methylcyclohexane, pentane, hexane, heptane, octane, nonane, decane, dodecane, and bicyclohexyl; ketone-based solvents such as acetone, methyl ethyl ketone, benzophenone, and acetophenone; ester-based solvents such as ethyl acetate, butyl acetate, ethyl cellosolve acetate, methyl benzoate, and phenyl acetate; polyalcohol-based solvents such as ethylene glycol, glycerin, and hexanediol; alcohol-based solvents such as isopropyl alcohol and cyclohexanol; a sulfoxide-based solvent such as dimethylsulfoxide; and amide-based solvents such as methylpyrrolidone and dimethylformamide. One or more solvents can be used.

### <Inkjet Device>

The inkjet device includes a nozzle. A droplet is applied from an opening provided on the nozzle. The diameter of the opening (also referred to as a nozzle diameter) is several micrometers to several tens of micrometers. A portion with the nozzle is sometimes referred to as a head of the inkjet device. To apply a droplet, the inkjet device is provided with a control portion for droplet injection. The control portion includes a piezoelectric element or the like, and the capacity of an ink tank connected to the nozzle through the piezoelectric element can be varied so that a droplet can be applied. The volume of droplets can be determined according to the nozzle diameter and, for example, can be several picoliters to several tens of picoliters per droplet. Although depending on the material included in the droplet, one picoliter droplets can be considered to form an approximately 10 μm cube.

As the resolution of a display panel is increased, miniaturization of the opening portion is desired. On the other hand, the nozzle diameter of the inkjet device has a limitation in miniaturization because of mechanical processing. Therefore, the opening portion is more miniaturized than the nozzle diameter. As a result, a droplet is applied while overflowing the opening portion in some cases. In such a case, processing using resist masks enables a high-resolution display panel to be provided.

### <Ink Material>

As a material of the droplet to be applied in a wet process (referred to as an ink material), a polymer material, a low molecular weight material, a dendrimer, or the like can be used as it is. As the ink material, a material in which a polymer material, a low molecular weight material, a dendrimer, or the like is dispersed in a solvent or a material in which a polymer material, a low molecular weight material, a dendrimer, or the like is dissolved in a solvent may be used. A polymer material may be obtained by mixing one or more of monomers. For mixing of one or more of monomers, the ink material in the mixed state may be applied and then subjected to heating, energy light irradiation, or the like to form a bond such as cross-linking, condensation, polymerization, coordination, or a salt.

Note that the above-described ink material may contain a material having a different function, such as a surface active agent or a material for adjusting viscosity.

As an amine compound used as the ink material, any of a primary amine, a secondary amine, and a tertiary amine can be used, and in particular, a secondary amine is preferred. In the case where the ink material in which a plurality of monomers are mixed is applied and polymerization is formed after the application, a secondary amine and arylsulfonic acid are preferably used as the monomers.

The secondary amine preferably has a substituted or unsubstituted aryl group having 6 to 14 carbon atoms or a substituted or unsubstituted π-electron rich heteroaryl group having 6 to 12 carbon atoms. Examples of the aryl group include a phenyl group, a biphenyl group, a naphthyl group, a fluorenyl group, a phenanthrenyl group, and an anthryl group. The above-described phenyl group is preferred because it improves solubility and reduces the raw material cost. Examples of the heteroaryl group include a carbazole skeleton, a pyrrole skeleton, a thiophene skeleton, a furan skeleton, and an imidazole skeleton.

The secondary amine preferably includes a plurality of bonds with an arylamine or a heteroaryl amine in terms of improvement in film quality after the application, heating, or curing. When the secondary amine includes many such bonds, an oligomer or a polymer is preferably formed.

The secondary amine may have a plurality of amine skeletons. In this case, some of the amine skeletons may be a primary amine or a tertiary amine. Note that the proportion of the secondary amine is preferably higher than the proportion of the primary amine or the tertiary amine. The number of the plurality of amine skeletons is preferably less than or equal to 1000, further preferably less than or equal to 10, and the molecular weight of the secondary amine is preferably less than or equal to 100000. An amine skeleton substituted by fluorine is preferably used because it improves compatibility with a compound in which fluorine is substituted.

The secondary amine is preferably an organic compound represented by General Formula (G1) below, for example.

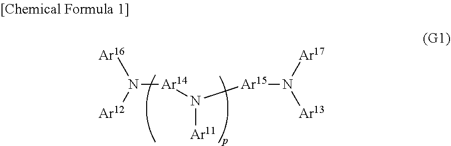

In General Formula (G1) above, one or more of Ar¹¹ to Ar¹³ represent hydrogen, and Ar¹⁴ to Ar¹⁷ represent substituted or unsubstituted aromatic rings each having 6 to 14 carbon atoms. As the aromatic ring having 6 to 14 carbon atoms, a benzene ring, a bisbenzene ring, a naphthalene ring, a fluorene ring, a phenanthrene ring, or an anthracene ring can be used. Note that Ar¹² and Ar¹⁶ may be bonded to each other to form a ring, Ar¹⁴ and Ar¹⁶ may be bonded to each other to form a ring, Ar¹¹ and Ar¹⁴ may be bonded to each other to form a ring, Ar¹⁴ and Ar¹⁵ may be bonded to each other to form a ring, Ar¹⁵ and Ar¹⁷ may be bonded to each other to form a ring, and Ar¹³ and Ar¹⁷ may be bonded to each other to form a ring. Furthermore, p represents an integer of 0 to 1000, and preferably represents 0 to 3. Note that the molecular weight of the organic compound represented by General Formula (G1) above is preferably less than or equal to 100000.

The tertiary amine is preferably an organic compound represented by General Formula (G2) below, for example.

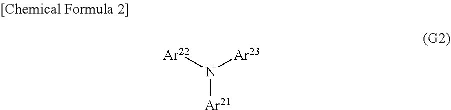

In General Formula (G2) above, Ar²¹ to Ar²³ each represent a substituted or unsubstituted aryl group having 6 to 14 carbon atoms and may be bonded to each other to form a ring. In the case where Ar²¹ to Ar²³ each have a substituent, the substituent may be a group in which a plurality of diarylamino groups or carbazolyl groups are bonded. An ether bond, a sulfide bond, or a bond via an amine may be included; any of these bonds preferably exists between a plurality of aryl groups to improve the solubility in a solvent. Also when an alkyl group is included as a substituent, the alkyl group may be bonded through an ether bond, a sulfide bond, or a bond via an amine.

As specific examples of the secondary amine, organic compounds represented by Structural Formula (Am2-1) to Structural Formula (Am2-32) below are preferably used. The organic compounds represented by Structural Formula (Am2-1) to Structural Formula (Am2-32) below each have an NH group.

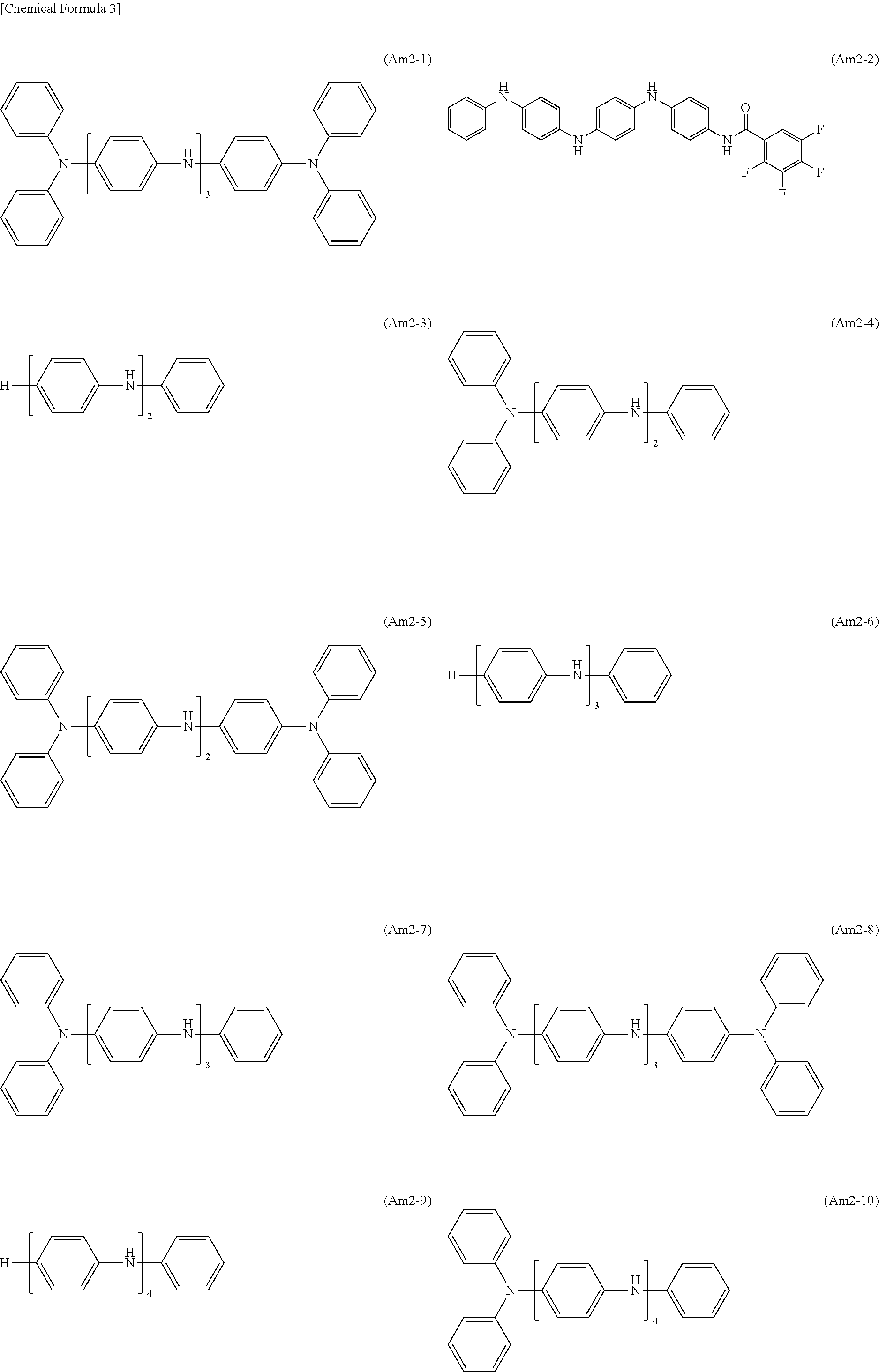

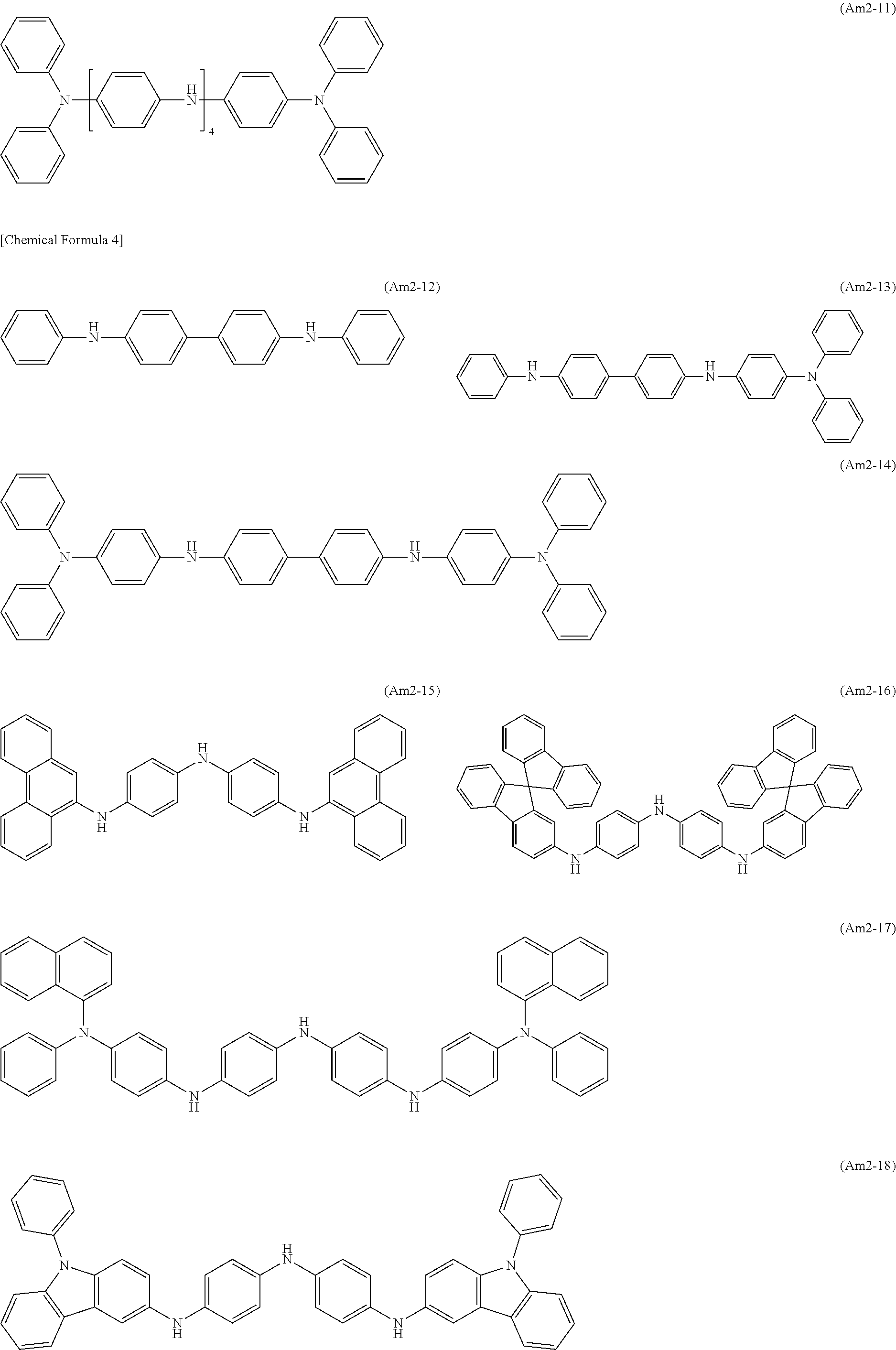

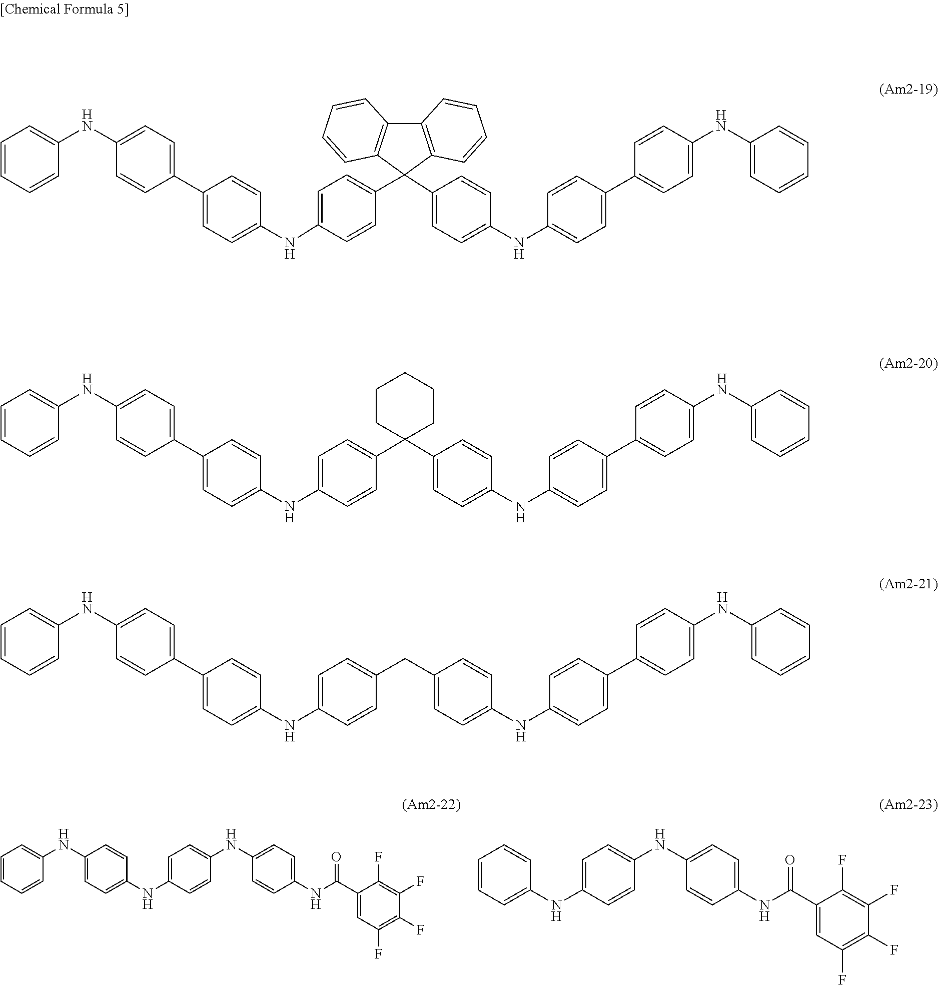 [SMILES: c1ccc(Nc2ccc(-c3ccc(Nc4ccc(C5(c6ccc(Nc7ccc(-c8ccc(Nc9ccccc9)cc8)cc7)cc6)c6ccccc6-c6ccccc65)cc4)cc3)cc2)cc1 ; c1ccc(Nc2ccc(-c3ccc(Nc4ccc(C5(c6ccc(Nc7ccc(-c8ccc(Nc9ccccc9)cc8)cc7)cc6)CCCCC5)cc4)cc3)cc2)cc1 ; c1ccc(Nc2ccc(-c3ccc(Nc4ccc(Cc5ccc(Nc6ccc(-c7ccc(Nc8ccccc8)cc7)cc6)cc5)cc4)cc3)cc2)cc1 ; O=C(Nc1ccc(Nc2ccc(Nc3ccc(Nc4ccccc4)cc3)cc2)cc1)c1cc(F)c(F)c(F)c1F ; O=C(Nc1ccc(Nc2ccc(Nc3ccccc3)cc2)cc1)c1cc(F)c(F)c(F)c1F]

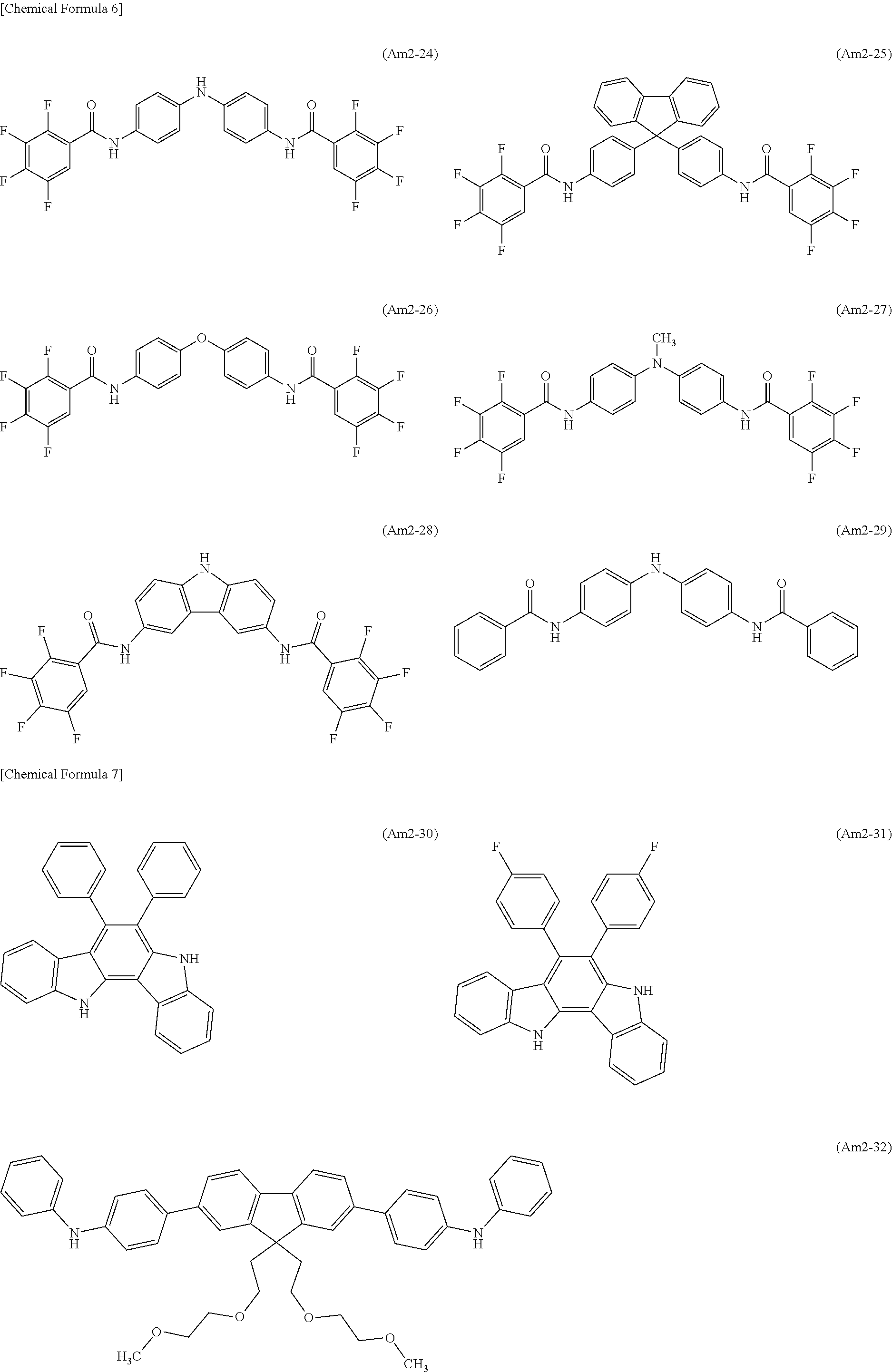

An amine compound can be used for the ink material by being mixed with a sulfonic acid compound. Mixing with a sulfonic acid compound facilitates generation of carriers and improves conductivity. Mixing with a sulfonic acid compound is referred to as p doping in some cases. In the case of using the secondary amine as the amine compound, bondings with a mixed sulfonic acid compound can be formed by a dehydration reaction, or the like, which is preferable. In the case where the compound mixed with the amine compound is a fluoride, a fluoride is preferably used as in Structural Formula (Am2-2), Structural Formulae (Am2-22) to (Am2-28), or Structural Formula (Am2-31) shown above to improve compatibility.

Note that a thiophene derivative may be used instead of the secondary amine. Specific examples of a thiophene derivative, organic compounds represented by Structural Formula (T-1) to Structural Formula (T-4) below, polythiophene, or poly (3,4-ethylenedioxythiophene) (PEDOT) is preferable. A thiophene derivative facilitates generation of carriers and improves conductivity by being mixed with a sulfonic acid compound. Mixing with a sulfonic acid compound is referred to as p doping in some cases.

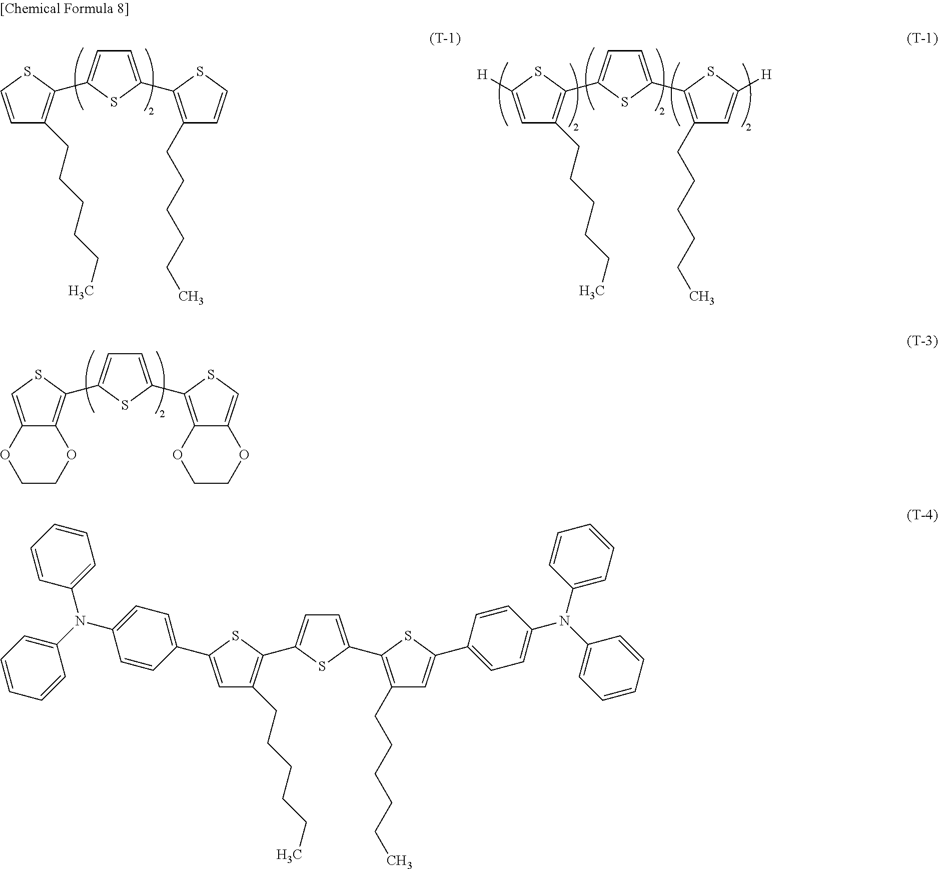

The sulfonic acid compound is a material exhibiting an acceptor property. As a sulfonic acid compound, an arylsulfonic acid can be given. It is only required that the arylsulfonic acid has a sulfo group; a sulfonic acid, a sulfonate, an alkoxysulfonic acid, a halogenated sulfonic acid, or a sulfonic acid anion can be used. Two or more of these sulfo groups may be included. As the aryl group of the arylsulfonic acid, a substituted or unsubstituted aryl group having 6 to 16 carbon atoms can be used. As the aryl group, for example, a phenyl group, a biphenyl group, a naphthyl group, a fluorenyl group, a phenanthrenyl group, an anthryl group, or a pyrenyl group can be used, and a naphthyl group is preferable because it has favorable solubility in a solvent and a favorable transport property. The arylsulfonic acid may include two or more aryl groups. The arylsulfonic acid preferably includes an aryl group substituted by fluorine because the LUMO level can be adjusted to be deep (in the negative direction widely). The arylsulfonic acid may include an ether bond, a sulfide bond, or a bond via an amine; any of these bonds preferably exists between a plurality of aryl groups, in which case the solubility in a solvent is improved. Also when the arylsulfonic acid includes an alkyl group as a substituent, the alkyl group may be bonded through an ether bond, a sulfide bond, or a bond via an amine. The arylsulfonic acid may be substituted in a polymer. Polyethylene, nylon, polystyrene, or polyfluorenylene can be used as the polymer; polystyrene or polyfluorenylene is preferred because of its favorable conductivity.

Specific and preferred examples of a compound including the arylsulfonic acid (an arylsulfonic acid compound) include organic compounds represented by Structural Formula (S-1) to Structural Formula (S-15) below. A polymer having a sulfo group such as poly (4-styrenesulfonic acid) (PSS) can also be used. Electrons from an electron donor with a shallow HOMO (such as an amine compound, a carbazole compound, or a thiophene compound) can be accepted by using an arylsulfonic acid compound, and the property of hole injection or hole transport from an electrode can be obtained by mixing with an electron donor. When the arylsulfonic acid compound is a fluorine compound, the LUMO level can be adjusted to be deeper (negatively higher energy level).

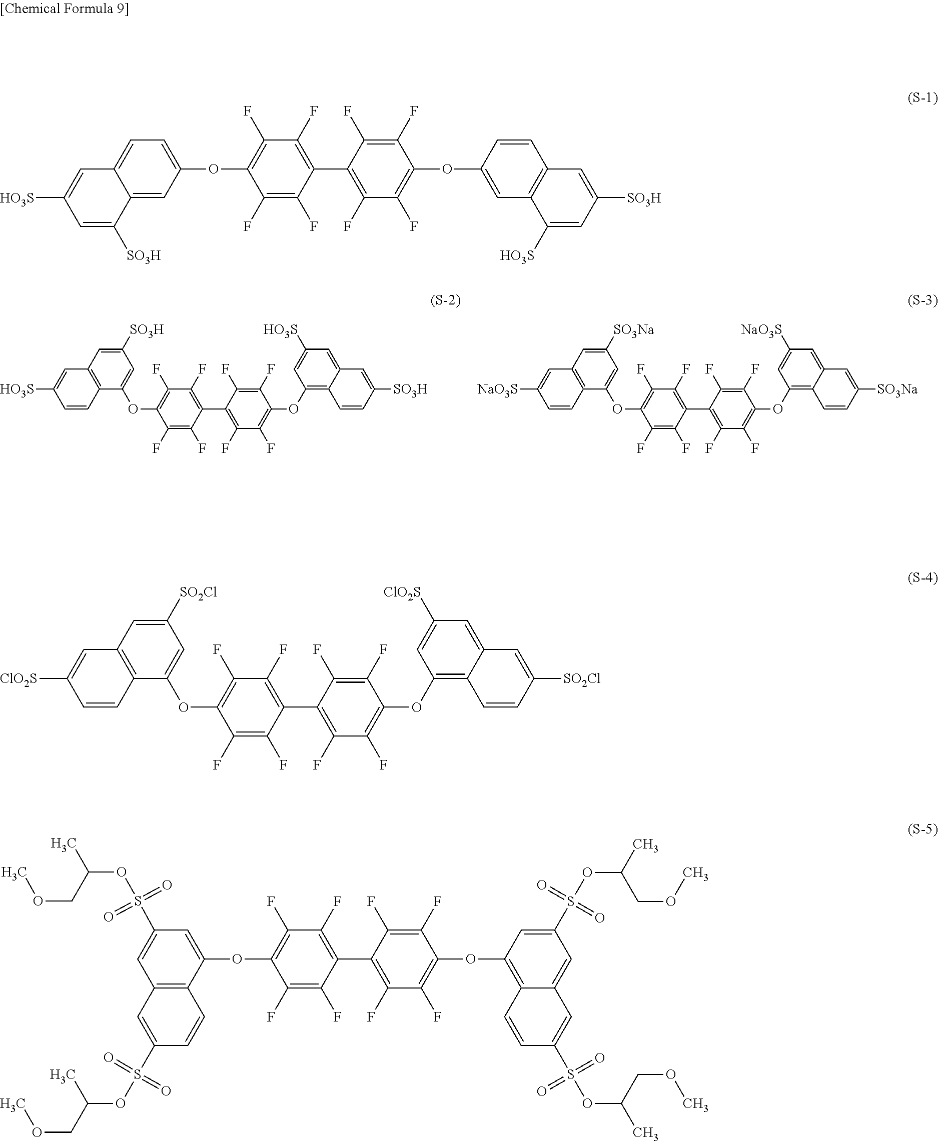

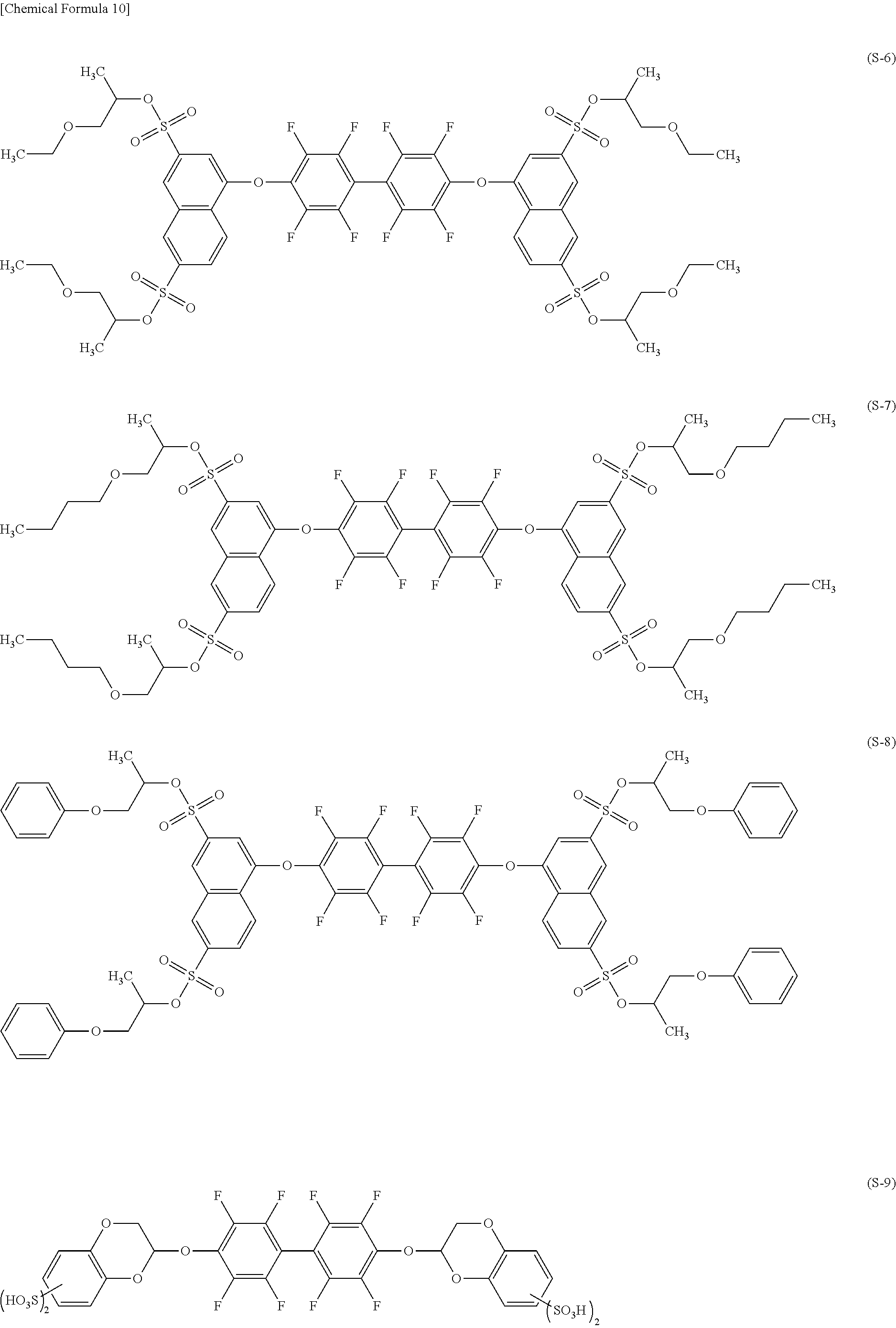

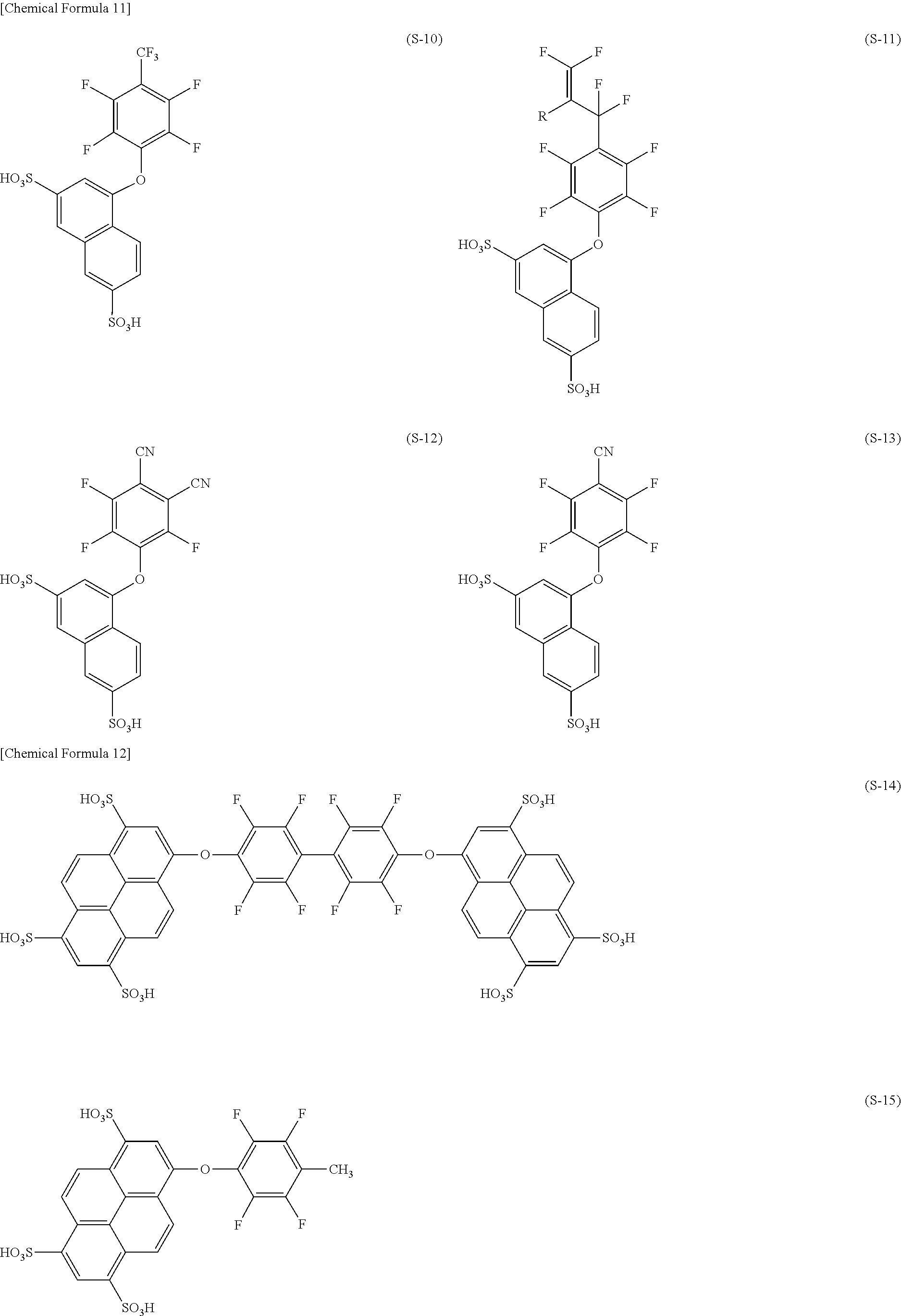

A tertiary amine may further be mixed into the above-described ink material in which a secondary amine and a sulfonic acid compound are mixed. A tertiary amine is electrochemically and photochemically stable as compared to a secondary amine and thereby enables a favorable hole-transport property when mixed. Preferable examples of the tertiary amine are organic compounds represented by Structural Formula (Am3-1) to Structural Formula (Am3-7) below. A material having a hole-transport property other than a tertiary amine may be mixed as appropriate into the ink material.

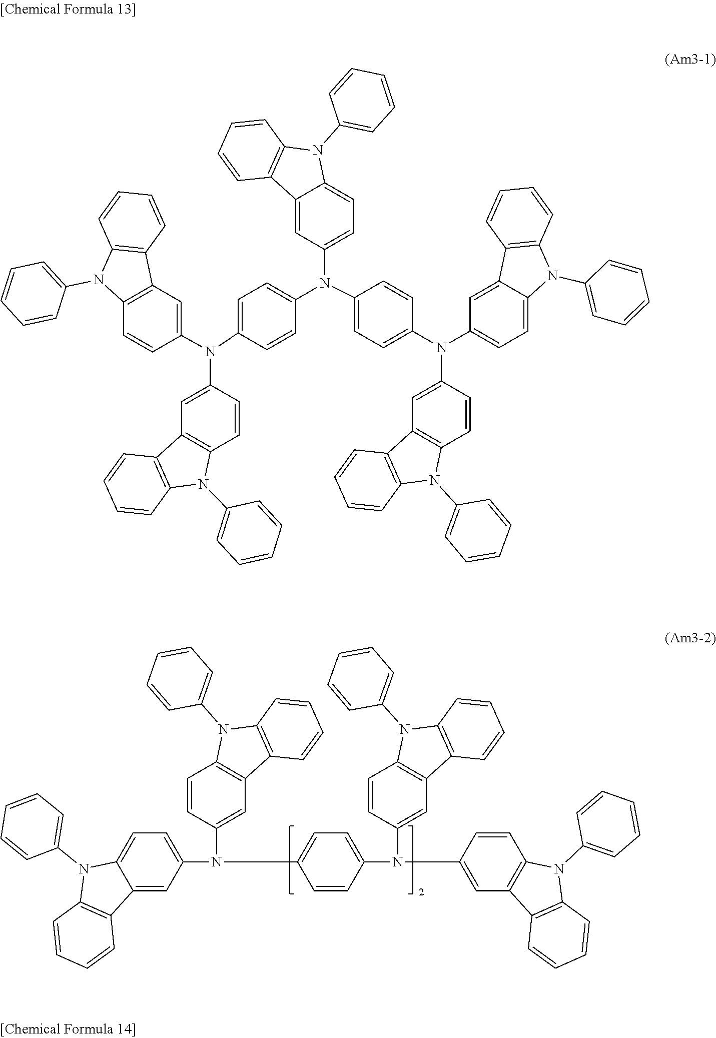

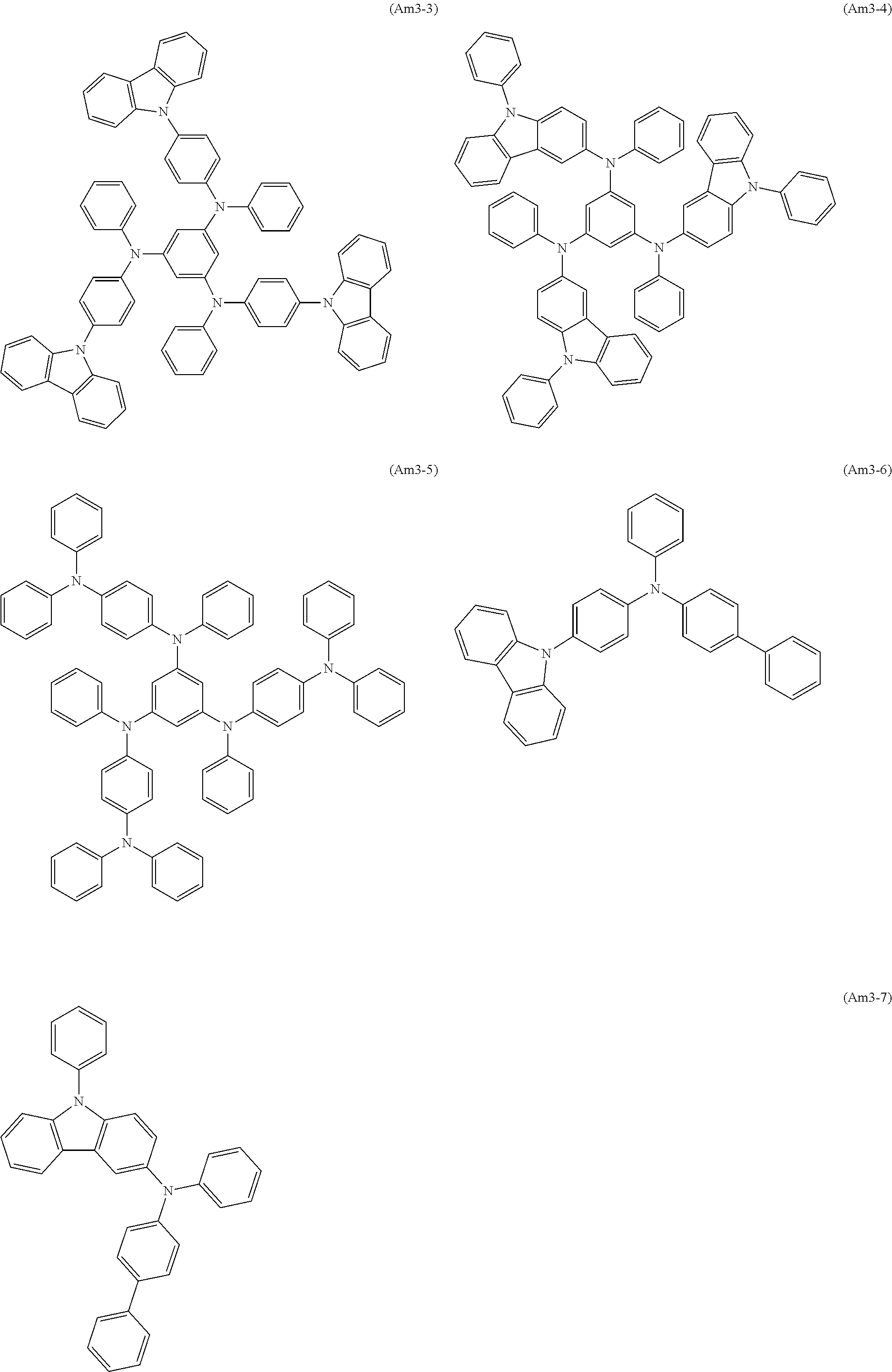

Other than the arylsulfonic acid compound, a cyano compound such as a tetracyanoquinodimethane compound can be used as an electron acceptor. Specifically, 2,3,5,6-tetrafluoro-7,7,8,8-tetracyano-quinodimethane (F4TCNQ), dipyrazino [2,3-f:2′,3′-h]quinoxaline-2,3,6,7,10,11-hexacarbonitrile (HAT-CN6), or the like can be given.

Note that the ink material in which a monomer is mixed preferably includes one or both of a 3,3,3-trifluoropropyltrimethoxysilane compound and a phenyltrimethoxysilane compound to improve wettability in the case where a film is formed by a wet process.

When a layer formed by a wet process with the ink material including at least two monomers of an electron donor such as the secondary amine or thiophene and arylsulfonic acid is measured by ToF-SIMS, a signal is observed at m/z=around 80 in a negative-mode result. The m/z=80 corresponds to a signal derived from an SO₃ anion in arylsulfonic acid. By contrast, a signal derived from an amine monomer is less likely to be observed from the layer. Meanwhile, sufficient light emission by the light-emitting element including the layer gives evidence that the layer has a sufficient hole-transport property. If a light-emitting element capable of light emission shows the analysis results including the signal or the like described above, the layer is found to have a sufficient hole-transport property, and the absence of the skeletons having a hole-transport property such as an amine suggests that the monomers are bonded to each other to form a high molecular weight compound film. These analysis results mean that the layer is formed by a wet process.

A sulfonic acid compound represented by Structural Formula (S-1) or (S-2) above is preferable because of having many sulfo groups and enabling a three-dimensional bond with an amine compound, easily stabilizing the film quality. From the layer formed using an arylsulfonic acid compound, a signal at m/z=901 can be observed in a negative mode in addition to the above-described signal at m/z=80. In addition, a signal at m/z=328 is also observed as a product ion.

Note that in the light-emitting element of one embodiment of the present invention, it is preferable that the iridium complex represented by a structural formula below be used as a light-emitting material. The iridium complex shown below is preferable because it has an alkyl group, so that it can be easily dissolved in a solvent and make it easy to adjust the ink material.

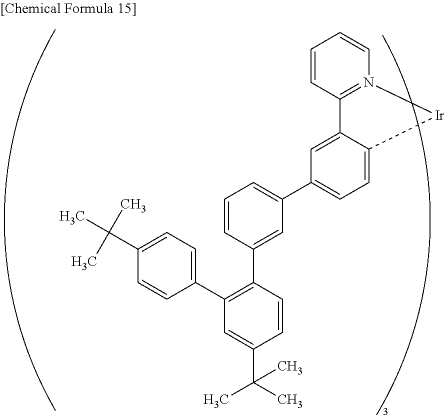

When the light-emitting layer including the iridium complex represented by the above structural formula is measured by ToF-SIMS, it has been found that a signal appears at m/z=1676, and m/z=1181 and m/z=685 each of which corresponds to a product ion, in the result of a positive mode.

Sodium fluoride is preferably used to improve the electron-transport property and water resistance of the light-emitting device. When an electron-injection layer of a light-emitting device including sodium fluoride in the electron-injection layer is analyzed by ToF-SIMS, signals are observed which are attributed to anions or cations such as Na₂F⁺, NaF₂⁻, and Na₂F₃⁻ being different in the number of bonds of sodium and fluorine.

Furthermore, as the electron-injection layer, a layer including an alkaline earth metal such as barium may be provided in contact with the cathode. This structure is preferable to make the property of electron injection from the cathode favorable.

The above layer including barium may also include a heteroaromatic compound. As the heteroaromatic compound, an organic compound having a phenanthroline skeleton is preferable and 2-phenyl-9-[3-(9-phenyl-1,10-phenanthrolin-2-yl)phenyl]-1,10-phenanthroline, which is represented by a structural formula below, or the like is particularly preferable.

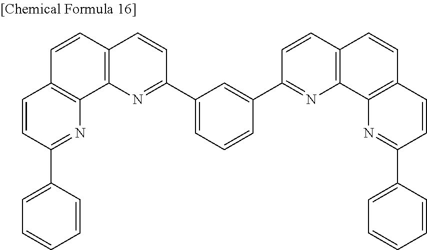 [SMILES: c1ccc(-c2ccc3ccc4ccc(-c5cccc(-c6ccc7ccc8ccc(-c9ccccc9)nc8c7n6)c5)nc4c3n2)cc1]

When a layer including 2-phenyl-9-[3-(9-phenyl-1,10-phenanthrolin-2-yl)phenyl]-1,10-phenanthroline is analyzed by ToF-SIMS, a signal is observed at m/z=587 in both a positive mode and a negative mode. In the case where a film of the same material is formed and the same layer or a layer in contact with the layer includes an alkali metal, an alkaline earth metal, or a compound thereof, an ion of an alkali metal complex (e.g., m/z=609 in the case of a Na complex), an alkaline earth metal complex (e.g., m/z=724 in the case of a Ba complex), or the like is sometimes detected.

### [Example 2 of Display Apparatus Manufacturing Method]

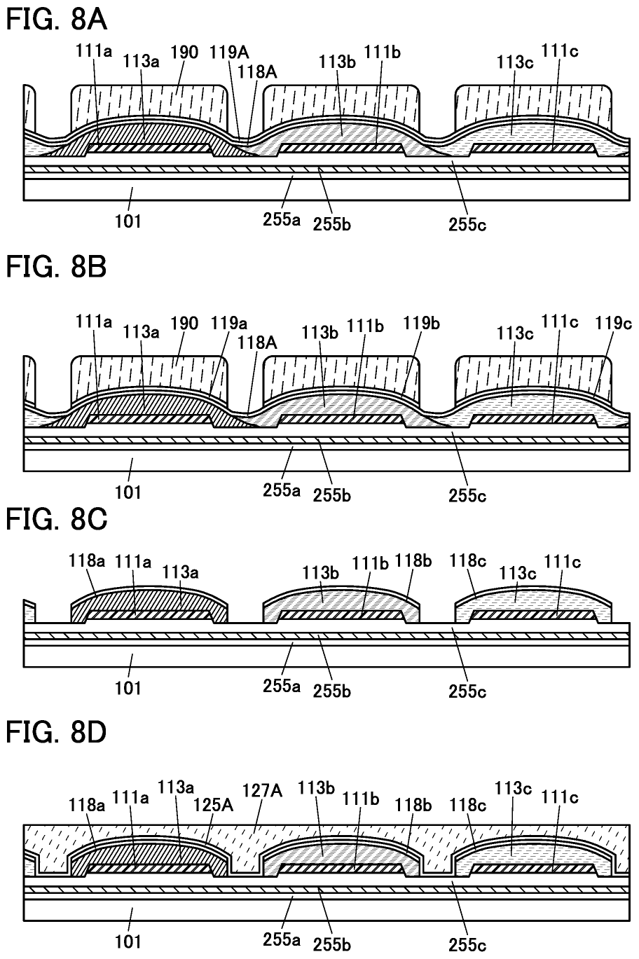

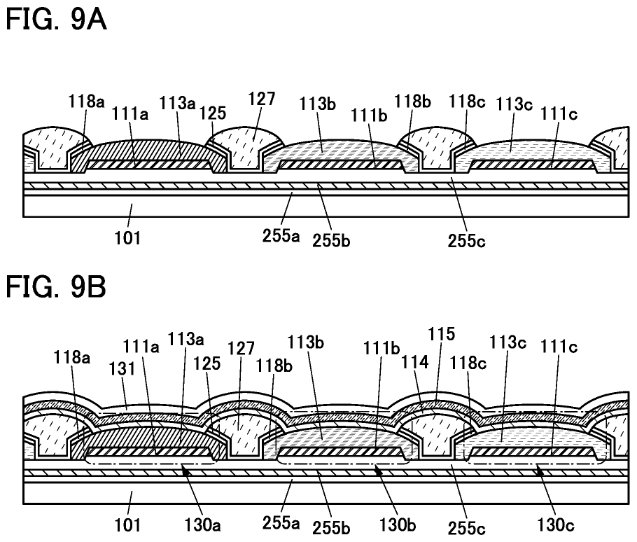

FIG. 8A to FIG. 9B illustrate an example of a manufacturing method of the display apparatus 100 illustrated in FIG. 2B and the like.

First, the layer 113a over the pixel electrode 111a, the layer 113b over the pixel electrode 111b, and the layer 113c over the pixel electrode 111c are formed using the steps illustrated in FIG. 6A to FIG. 7B. Then, a first mask layer 118A is formed over the layer 113a, the layer 113b, and the layer 113c, and a second mask layer 119A is formed over the first mask layer 118A. Next, a resist mask 190 is formed over the second mask layer 119A (FIG. 8A). The resist mask 190 is provided in regions overlapping with the pixel electrodes 111a, 111b, and 111c.

In FIG. 8A, the layer 116, the layer 117a, the layer 117b, and the layer 117c are not illustrated for simplicity.

As the first mask layer 118A and the second mask layer 119A, a film that is highly resistant to the process conditions for the layer 113a, the layer 113b, the layer 113c, and the like, specifically, a film having high etching selectivity with EL layers is used.

The first mask layer 118A and the second mask layer 119A can be formed by a sputtering method, an ALD method (a thermal ALD method and a PEALD method), a CVD method, or a vacuum evaporation method, for example. The first mask layer 118A, which is formed over and in contact with the EL layers, is preferably formed by a formation method that causes less damage to the EL layers than a formation method for the second mask layer 119A. For example, the first mask layer 118A is preferably formed by an ALD method or a vacuum evaporation method rather than a sputtering method. The first mask layer 118A and the second mask layer 119A are formed at a temperature lower than the heat resistance temperature of the EL layer. The substrate temperature at the time of forming the first mask layer 118A and the second mask layer 119A is typically lower than or equal to 200° C., preferably lower than or equal to 150° C., further preferably lower than or equal to 120° C., still further preferably lower than or equal to 100° C., yet still further preferably lower than or equal to 80° C.

The first mask layer 118A and the second mask layer 119A are preferably films that can be removed by a wet etching method. Using a wet etching method can reduce damage to the layer 113a in processing of the first mask layer 118A and the second mask layer 119A, compared to the case of using a dry etching method.

The first mask layer 118A is preferably a film having high etching selectivity with the second mask layer 119A.

In the manufacturing method of the display apparatus of this embodiment, it is desirable that the layers (e.g., the hole-injection layer, the hole-transport layer, the light-emitting layer, and the electron-transport layer) included in the EL layers not be easily processed in the step of processing the mask layers, and that the mask layers not be easily processed in the steps of processing the layers included in the EL layers. In consideration of the above, the materials and a processing method for the mask layers and processing methods for the EL layers are preferably selected.

Although this embodiment describes an example in which the mask layer is formed to have a two-layer structure of the first mask layer and the second mask layer, the mask layer may have a single-layer structure or a stacked-layer structure of three or more layers.

As the first mask layer 118A and the second mask layer 119A, it is preferable to use an inorganic film such as a metal film, an alloy film, a metal oxide film, a semiconductor film, or an inorganic insulating film, for example.

For each of the first mask layer 118A and the second mask layer 119A, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet light for one or both of the first mask layer 118A and the second mask layer 119A is preferable, in which case the EL layers can be inhibited from being irradiated with ultraviolet light and deteriorating.

For each of the first mask layer 118A and the second mask layer 119A, a metal oxide such as In—Ga—Zn oxide can be used. As the first mask layer 118A or the second mask layer 119A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Alternatively, indium tin oxide containing silicon or the like can also be used.

In addition, in place of gallium described above, an element M (M is one or more kinds selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used. In particular, M is preferably one or more kinds selected from gallium, aluminum, and yttrium.

As each of the first mask layer 118A and the second mask layer 119A, any of a variety of inorganic insulating films that can be used as the protective layer 131 can be used. In particular, an oxide insulating film is preferable because its adhesion to the EL layers is higher than that of a nitride insulating film. For example, an inorganic insulating material such as aluminum oxide, hafnium oxide, or silicon oxide can be used for each of the first mask layer 118A and the second mask layer 119A. As the first mask layer 118A or the second mask layer 119A, an aluminum oxide film can be formed by an ALD method, for example. The use of an ALD method is preferable, in which case damage to a base (in particular, the EL layers or the like) can be reduced.

For example, an inorganic insulating film (e.g., an aluminum oxide film) formed by an ALD method can be used as the first mask layer 118A, and an inorganic film (e.g., an In—Ga—Zn oxide film, an aluminum film, or a tungsten film) formed by a sputtering method can be used as the second mask layer 119A.

Note that the same inorganic insulating film can be used for both the first mask layer 118A and the insulating layer 125 that is to be formed later. For example, an aluminum oxide film formed by an ALD method can be used for both the first mask layer 118A and the insulating layer 125. Here, the same film formation conditions may be used for the first mask layer 118A and the insulating layer 125. For example, when the first mask layer 118A is formed under conditions similar to those of the insulating layer 125, the first mask layer 118A can be an insulating layer having a high barrier property against at least one of water and oxygen. Note that without limitation to this, different film formation conditions may be employed for the first mask layer 118A and the insulating layer 125.

A material dissolvable in a solvent that is chemically stable with respect to at least the uppermost film of the layer 113a may be used for one or both of the first mask layer 118A and the second mask layer 119A. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, heat treatment is preferably performed in a reduced-pressure atmosphere, in which case the solvent can be removed at a low temperature in a short time and thermal damage to the EL layers can be reduced accordingly.

The first mask layer 118A and the second mask layer 119A may each be formed by a wet film formation method such as spin coating, dipping, spray coating, ink-jetting, dispensing, screen printing, offset printing, doctor blade coating, slit coating, roll coating, curtain coating, or knife coating.

Each of the first mask layer 118A and the second mask layer 119A may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

The resist mask can be formed by application of a photosensitive resin (photoresist), light exposure, and development. The resist mask may be formed using either a positive resist material or a negative resist material.

The resist mask 190 is provided at a position overlapping with each of the pixel electrodes 111a, 111b, and 111c. One island-shaped pattern is preferably provided for one subpixel 110a, 110b, or 110c or for one light-emitting device 130a, 130b, or 130c as the resist mask 190. Alternatively, one band-shaped pattern for a plurality of subpixels 110a aligned in one column (aligned in the Y direction in FIG. 1A) may be formed as the resist mask 190.

Here, when the resist mask 190 is formed so that an end portion of the resist mask 190 is positioned outside the end portions of the pixel electrodes 111a, 111b, and 111c, the end portions of the layers 113a, 113b, and 113c formed later can be provided outside the end portions of the pixel electrodes 111a, 111b, and 111c. A pixel with such a structure can have a high aperture ratio.

Then, part of the second mask layer 119A is removed using the resist mask 190, so that mask layers 119a, 119b, and 119c are formed (FIG. 8B).

In etching of the second mask layer 119A, an etching condition with high selectivity is preferably employed so that the first mask layer 118A is not removed by the etching. Since the EL layers are not exposed in processing the second mask layer 119A, the range of choices of the processing method is wider than that for processing the first mask layer 118A. Specifically, deterioration of the EL layers can be further inhibited even when a gas containing oxygen is used as an etching gas in processing the second mask layer 119A.

After that, the resist mask 190 is removed. The resist mask 190 can be removed by ashing using oxygen plasma, for example. Alternatively, an oxygen gas and any of CF₄, C₄F₈, SF₆, CHF₃, Cl₂, H₂O, BCl₃, and a noble gas (also referred to as a rare gas) such as He may be used. Alternatively, the resist mask 190 may be removed by wet etching. At this time, the first mask layer 118A is positioned on the outermost surface and the layer 113a, the layer 113b, and the layer 113c are not exposed; thus, the layer 113a, the layer 113b, and the layer 113c can be inhibited from being damaged in the step of removing the resist mask 190. In addition, the range of choices of the method for removing the resist mask 190 can be widened.

Next, part of the first mask layer 118A is removed using the mask layers 119a, 119b, and 119c as masks (also referred to as hard masks), so that mask layers 118a, 118b, and 118c are formed.

The first mask layer 118A and the second mask layer 119A can be processed by a wet etching method or a dry etching method. The first mask layer 118A and the second mask layer 119A are preferably processed by anisotropic etching.

Using a wet etching method can reduce damage to the layer 113a, the layer 113b, and the layer 113c in processing of the first mask layer 118A and the second mask layer 119A, compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, a chemical solution containing a mixed solution thereof, or the like, for example.

In the case of using a dry etching method, deterioration of the layer 113A can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the first mask layer 118A, the first mask layer 118A can be processed by a dry etching method using CHF₃ and He. In the case where an In—Ga—Zn oxide film formed by a sputtering method is used as the second mask layer 119A, the second mask layer 119A can be processed by a wet etching method using diluted phosphoric acid. Alternatively, the mask film 119A may be processed by a dry etching method using CH₄ and Ar. Alternatively, the second mask layer 119A can be processed by a wet etching method using diluted phosphoric acid. In the case where a tungsten film formed by a sputtering method is used as the second mask layer 119A, the second mask layer 119A can be processed by a dry etching method using a combination of CF₄ and O₂, a combination of CF₆ and O₂, a combination of CF₄, Cl₂, and O₂, or a combination of CF₆, Cl₂, and O₂.

Next, the layer 113a is processed. In the processing step, part of the layer 113a is removed by an etching method, a laser ablation method, or the like. Dry etching or wet etching can be used as the etching. In the laser ablation method, laser irradiation may be performed after providing a light-absorbing layer or a light-reflecting layer.

Through the processing step, a minute light-emitting device can be provided regardless of the nozzle diameter. In this manner, a high-resolution display apparatus can be provided. Through more processing steps, the material layers are divided in the adjacent light-emitting devices, and thus a display apparatus with less crosstalk can be provided.

Here, by etching treatment, part of the layer 113a is removed using the mask layer 119a and the mask layer 118a as hard masks, part of the layer 113b is removed using the mask layer 119b and the mask layer 118b as hard masks, and part of the layer 113c is removed using the mask layer 119c and the mask layer 118c as hard masks (FIG. 8C). As illustrated in FIG. 8C, in the layer 113a, a region overlapping with the layer 113b and a region overlapping with the layer 113c are each removed by the etching treatment. In the layer 113b, a region overlapping with the layer 113a and a region overlapping with the layer 113c are each removed. In the layer 113c, a region overlapping with the layer 113a and a region overlapping with the layer 113b are each removed.

The layer 113 covers the top surface and the side surface of the pixel electrode 111 and thus, the subsequent steps can be performed without exposure of the pixel electrode 111. When the end portion of the pixel electrode 111 is exposed, corrosion might occur due to the etching step or the like. A product generated by corrosion of the pixel electrode 111 might be unstable; for example, the product might be dissolved in a solution in wet etching and might be scattered in an atmosphere in dry etching. The product dissolved in a solution or scattered in an atmosphere might be attached to a surface to be processed, the side surface of the layer 113, and the like, which adversely affects the characteristics of the light-emitting device or forms a leakage path between the light-emitting devices in some cases. In a region where the end portion of the pixel electrode 111 is exposed, adhesion between layers in contact with each other might be lowered, which might easily cause film separation of the layer 113 or the pixel electrode 111.

With the structure in which the layer 113 covers the top surface and the side surface of the pixel electrode 111, for example, the yield of the light-emitting device can be improved and display quality of the light-emitting device can be improved.

Note that part of the layer 113 may be removed using the resist mask 190. Then, the resist mask 190 may be removed.

The layer 113 is preferably processed by anisotropic etching. In particular, anisotropic dry etching is preferable. Alternatively, wet etching may be employed.

In the case of using a dry etching method, deterioration of the layer 113 can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the layer 113A can be inhibited. Furthermore, a defect such as attachment of a reaction product generated in the etching can be inhibited.

In the case of using a dry etching method, it is preferable to use a gas containing one or more kinds of H₂, CF₄, C₄F₈, SF₆, CHF₃, Cl₂, H₂O, BCl₃, and a noble gas (also referred to as a rare gas) such as He and Ar as the etching gas, for example. Alternatively, a gas containing one or more kinds of the above-described gasses and oxygen is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas.

Note that the side surfaces of the layer 113a, the layer 113b, and the layer 113c are preferably perpendicular or substantially perpendicular to their formation surfaces. For example, the angle between the formation surfaces and these side surfaces is preferably greater than or equal to 60° and less than or equal to 90°.

When the EL layers are processed by a photolithography method as described above, the distance between pixels can be shortened to be less than or equal to 8 μm, less than or equal to 5 μm, less than or equal to 3 μm, less than or equal to 2 μm, or less than or equal to 1 μm. Here, the distance between pixels can be determined by, for example, the distance between opposite end portions of two adjacent layers among the layer 113a, the layer 113b, and the layer 113c. The distance between pixels is shortened in this manner, whereby a display apparatus with high resolution and a high aperture ratio can be provided.

Next, the mask layers 119a, 119b, and 119c are removed (FIG. 8C). As a result, the mask layer 118a is exposed over the pixel electrode 111a, the mask layer 118b is exposed over the pixel electrode 111b, the mask layer 118c is exposed over the pixel electrode 111c, and the mask layer 118a is exposed over the conductive layer 123.

Note that a structure in which the process proceeds to a step of forming an insulating film 125A without removal of the mask layers 119a, 119b, and 119c may be employed.

The step of removing the mask layers can be performed by a method similar to that for the step of processing the mask layers. In particular, using a wet etching method can reduce damage to the layer 113a, the layer 113b, and the layer 113c in removing the mask layers, as compared to the case of using a dry etching method.

The mask layer may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water included in the EL layer and water adsorbed on the surface of the EL layer. For example, heat treatment in an inert gas atmosphere or a reduced pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. A reduced-pressure atmosphere is preferable because drying at a lower temperature is possible.

Next, the insulating film 125A is formed to cover the layer 113a, the layer 113b, the layer 113c, and the mask layers 118a, 118b, and 118c.

The insulating film 125A is a layer to be the insulating layer 125 later. Thus, the insulating film 125A can be formed using a material that can be used for the insulating layer 125. The thickness of the insulating film 125A is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A, which is formed in contact with the side surfaces of the EL layers, is preferably formed by a formation method that causes less damage to the EL layers. In addition, the insulating film 125A is formed at a temperature lower than the heat resistance temperature of the EL layers. The typical substrate temperatures in formation of the insulating film 125A and the insulating layer 127 are each lower than or equal to 200° C., preferably lower than or equal to 180° C., further preferably lower than or equal to 160° C., still further preferably lower than or equal to 150° C., yet still further preferably lower than or equal to 140° C.

As the insulating film 125A, an aluminum oxide film is preferably formed by an ALD method, for example. The use of an ALD method is preferable, in which case damage due to film formation can be reduced and a film with good coverage can be formed. Here, the insulating film 125A can be formed using a material and method similar to those for the mask layers 118a, 118b, and 118c. In that case, a boundary between the insulating film 125A and the mask layers 118a, 118b, and 118c might be unclear.

Next, an insulating film 127A is applied onto the insulating film 125A (FIG. 8D).

The insulating film 127A is a film to be the insulating layer 127 in a later step, and the above-described organic material can be used for the insulating film 127A. As the organic material, a photosensitive organic resin is preferably used; for example, a photosensitive acrylic resin may be used. The viscosity of the insulating film 127A is greater than or equal to 1 cP and less than or equal to 1500 cP, preferably greater than or equal to 1 cP and less than or equal to 12 cP. By setting the viscosity of the material of the insulating film 127A in the above-described range, the insulating layer 127 having a tapered shape can be formed relatively easily.

There is no particular limitation on the method of forming the insulating film 127A, and, for example, the insulating film 127A can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating film 127A is preferably formed by spin coating.

Heat treatment is preferably performed after the application of the insulating film 127A. The heat treatment is performed at a temperature lower than the heat resistance temperature of the EL layers. The substrate temperature in heat treatment is higher than or equal to 50° C. and lower than or equal to 200° C., preferably higher than or equal to 60° C. and lower than or equal to 150° C., and further preferably higher than or equal to 70° C. and lower than or equal to 120° C. Accordingly, a solvent contained in the insulating film 127A can be removed.

Next, part of the insulating film 127A is exposed to visible light or ultraviolet rays. Here, in the case where a positive acrylic resin is used for the insulating film 127A, a region where the insulating layer 127 is not formed in a later step is irradiated with visible light or ultraviolet rays using a mask. In the case where visible light is used for exposure, the visible light preferably includes the i-line (wavelength: 365 nm). Furthermore, visible light including the g-line (wavelength: 436 nm), the h-line (wavelength: 405 nm), or the like may be used.

Note that a negative photosensitive organic resin may be used for the insulating film 127A. In that case, the region where the insulating layer 127 is formed is irradiated with visible light or ultraviolet rays.

Next, development is performed to remove the region of the insulating film 127A subjected to the light exposure, whereby the insulating layer 127 is formed. Here, in the case where an acrylic resin is used for the insulating film 127A, an alkaline solution is preferably used as a developer, and for example, a tetramethyl ammonium hydroxide (TMAH) solution is used.

After the development, the entire substrate may be subjected to light exposure, that is, the entire substrate may be irradiated with visible light or ultraviolet rays. Furthermore, after the development or after the development and light exposure, heat treatment may be performed.

Next, the insulating layer 125 is formed by etching treatment using the insulating layer 127 as a mask (FIG. 9A). The etching treatment can be performed by dry etching or wet etching.

Next, the common layer 114, the common electrode 115, and the protective layer 131 are formed in this order so as to cover the insulating layer 125, the insulating layer 127, the mask layer 118, the layer 113a, the layer 113b, and the layer 113c (FIG. 9B).

The common layer 114 is provided to cover the top surfaces of the layer 113a, the layer 113b, and the layer 113c and the top and side surfaces of the insulating layer 127. Here, in the case where the fourth layer 114 has high conductivity, a short circuit might be caused in the light-emitting devices when the common layer 114 is in contact with any of the side surfaces of the pixel electrodes 111a, 111b, and 111c and the layers 113a, 113b, and 113c. In the display apparatus of one embodiment of the present invention, however, the insulating layers 125 and 127 cover the side surfaces of the layer 113a, the layer 113b, and the layer 113c, and the layer 113a, the layer 113b, and the layer 113c cover the side surfaces of the corresponding pixel electrodes 111a, 111b, and 111c. Thus, the common layer 114 having high conductivity can be inhibited from being in contact with the side surfaces of these layers, and a short circuit of the light-emitting devices can be inhibited. Accordingly, the reliability of the light-emitting devices can be improved.

Since the space between the layer 113a and the layer 113b and the space between the layer 113b and the layer 113c are filled with the insulating layers 125 and 127, the formation surface of the common layer 114 has a smaller step and higher planarity than the formation surface of the case where the insulating layers 125 and 127 are not provided. Thus, the coverage with the common layer 114 can be increased.

In the manufacturing method of one embodiment of the present invention, the material layers containing the light-emitting materials are processed to be separated by patterning using a photolithography method. The patterning using a photolithography method is preferably performed once, not a plurality of times, on each light-emitting device. Although material layers formed by a wet process are difficult to be separately patterned with high resolution because of the limitation of the nozzle diameter or the like, patterning using a photolithography method makes high-resolution processing possible. Therefore, a high-resolution light-emitting apparatus (display apparatus) can be manufactured.

The material layers containing the light-emitting materials sometimes cause crosstalk due to the conductivity. Therefore, high-resolution processing by patterning using a photolithography method as described in the manufacturing method of one embodiment of the present invention can inhibit occurrence of crosstalk between adjacent light-emitting devices. End portions (side surfaces) of the material layers that contain the light-emitting materials and are processed by patterning using a photolithography method have substantially the same surface (or positioned on substantially the same plane), which is suitable for inhibiting occurrence of crosstalk.

Then, the substrate 120 is bonded to the protective layer 131 using the resin layer 122. Through the above steps, the display apparatus 100 can be manufactured.

### [Example 3 of Display Apparatus Manufacturing Method]

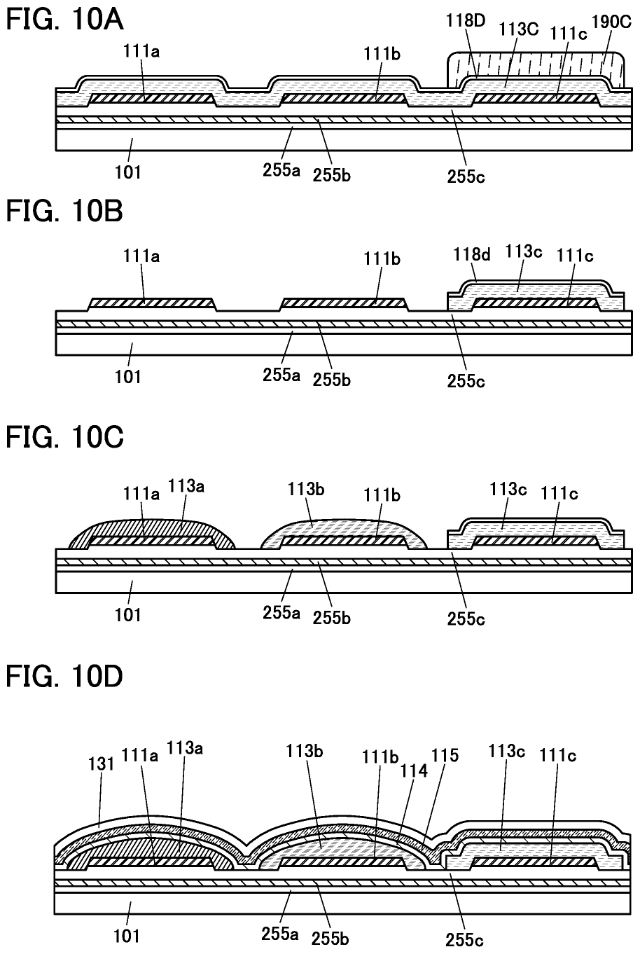

FIG. 10A to FIG. 10D illustrate an example of a manufacturing method of the display apparatus 100 illustrated in FIG. 3A or the like, in which the light-emitting layer of one of the light-emitting devices 130a, 130b, and 130c is formed by an evaporation method and the light-emitting layers of the other light-emitting devices are formed by an application method.

First, the insulating layer 255a, the insulating layer 255b, and the insulating layer 255c are formed in this order over the layer 101 including transistors. Next, the pixel electrode 111a, the pixel electrode 111b, and the pixel electrode 111c are formed over the insulating layer 255c.

Next, a film 113C is formed to cover the pixel electrode 111c. The film 113C is a film to be the layer 113c. Next, a mask layer 118D is formed over the film 113C. Next, a resist mask 190C is provided to overlap with the pixel electrode 111c (FIG. 10A).

The film 113C is preferably formed by an evaporation method. The film 113C includes one or two selected from a hole-transport layer and a hole-injection layer and a light-emitting layer containing a blue-light-emitting material. The film 113C may include an electron-transport layer.

For the mask layer 118D, any of the above-described materials, structures, and formation methods for the first mask layer 118A and the second mask layer 119A can be used. The mask layer 118D can have a stacked-layer structure of the first mask layer 118A and the second mask layer 119A described above. Alternatively, the structure of either the first mask layer 118A or the second mask layer 119A may be used for the mask layer 118D.

Next, part of the mask layer 118D is removed using the resist mask 190C, so that a mask layer 118d is formed. After that, the resist mask 190C is removed.

Next, part of the film 113C is removed by etching treatment using the mask layer 118d as a hard mask, so that the layer 113c is formed (FIG. 10B). The layer 113c illustrated in FIG. 10B includes one or two selected from a hole-transport layer and a hole-injection layer and a light-emitting layer containing a blue-light-emitting material. The layer 113c illustrated in FIG. 10B may include an electron-transport layer over the light-emitting layer containing a blue-light-emitting material. Since the surface of the layer 113c is exposed in the manufacturing process of the display apparatus, providing the electron-transport layer over the layer 113c inhibits the light-emitting layer from being exposed on the outermost surface, so that damage to the light-emitting layer can be reduced. Accordingly, the reliability of the light-emitting device can be improved.

Although FIG. 10A and FIG. 10B illustrate an example in which the film 113C is formed to cover the pixel electrode 111a, the pixel electrode 111b, and the pixel electrode 111c and the film 113C over the pixel electrode 111a and the pixel electrode 111b is removed by etching treatment, the film 113C may be formed using a metal mask so that the film 113C is not formed in a region over the pixel electrode 111a and the pixel electrode 111b. In this case, etching treatment for the film 113C is not necessarily performed.

Next, using an inkjet device, the layer 113a is formed over the pixel electrode 111a, and the layer 113b is formed over the pixel electrode 111b (FIG. 10C). FIG. 6A to FIG. 6C can be referred to for the formation of the layer 113a and the layer 113b.

Note that liquid-repellent treatment may be performed on the exposed region of the insulating layer 255c. In at least part of the region subjected to the liquid-repellent treatment, for example, a droplet discharged from the inkjet device is repelled and the layer 113a is not formed. Thus, a layer having a width smaller than the nozzle diameter of the inkjet device can be formed in some cases. Thus, even in a display apparatus with high resolution, the layer 113a and the layer 113b, the layer 113b and the layer 113c, and the layer 113c and the layer 113a can be provided apart from each other.

Next, the common layer 114, the common electrode 115, and the protective layer 131 are formed in order so as to cover the layer 113a, the layer 113b, and the layer 113c. (FIG. 10D).

The common layer 114 is one or two or more layers selected from an electron-transport layer and an electron-injection layer.

Note that in the case where the layer 113c illustrated in FIG. 10B includes an electron-transport layer and the common layer 114 includes an electron-transport layer, the light-emitting device 130c has a structure in which the electron-transport layer included in the layer 113c and the electron-transport layer included in the common layer 114 are stacked.

Then, the substrate 120 is bonded to the protective layer 131 using the resin layer 122. Through the above-described steps, the display apparatus 100 can be manufactured.

### [Example 4 of Display Apparatus Manufacturing Method]

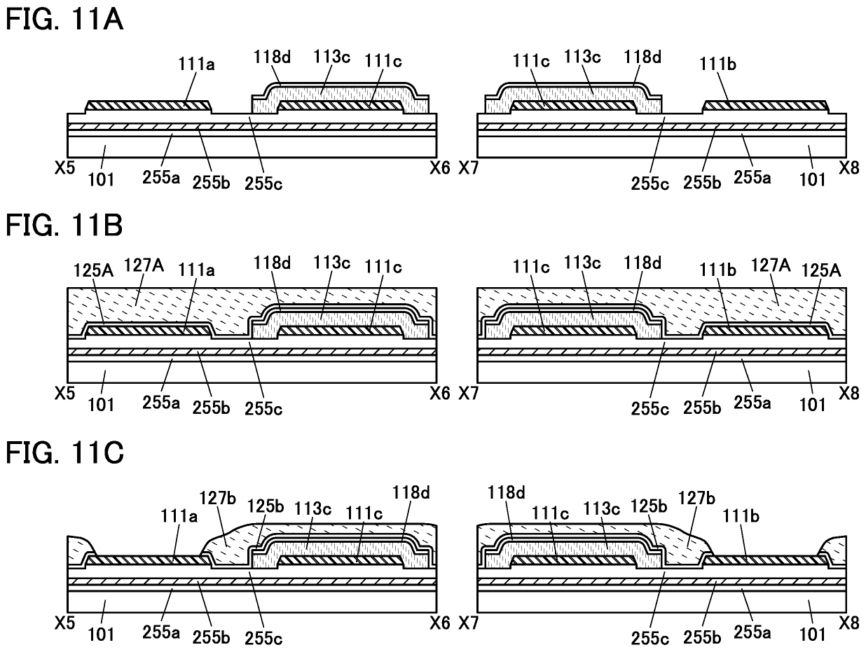

FIG. 11A to FIG. 15B illustrate an example of a manufacturing method of the display apparatus 100 illustrated in FIG. 5B and FIG. 5C.

First, the layer 113c and the mask layer 118d are formed over the pixel electrode 111c (FIG. 11A). FIG. 10A and FIG. 10B can be referred to for the formation of the layer 113c and the mask layer 118d.

Next, the insulating film 125A is formed to cover the pixel electrode 111a, the pixel electrode 111b, and the layer 113c. Then, the insulating film 127A is formed to cover the insulating film 125A (FIG. 11B).

After the insulating film 127A is formed, liquid-repellent treatment is preferably performed on a surface of the insulating film 127A. For the liquid-repellent treatment, a silane coupling material can be used, for example.

Next, part of the insulating film 127A is removed, so that an opening portion overlapping with the pixel electrode 111a and an opening portion overlapping with the pixel electrode 111b are provided and an insulating layer 127b is formed (FIG. 11C). Note that in FIG. 11C, an end portion of the opening portion over the pixel electrode is positioned over the pixel electrode; however, the end portion of the opening portion may be positioned outside the pixel electrode.

Next, etching treatment is performed on the insulating film 127A using the insulating layer 127b as a mask, so that an insulating layer 125b is formed.

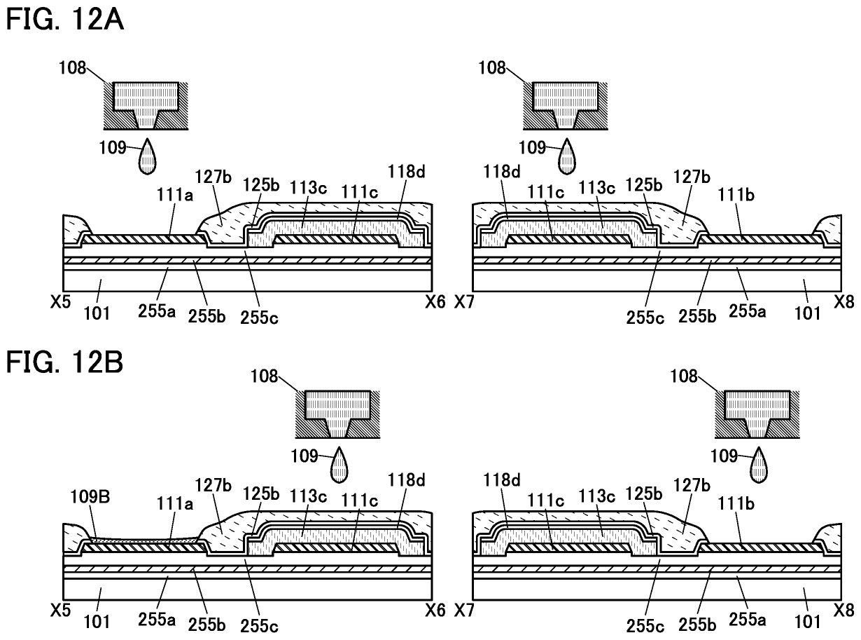

Next, in the subpixels in the column CL1, the droplets 109 are dripped from the nozzle 108 by an inkjet method (FIG. 12A). The droplets 109 include one or two or more selected from a hole-transport layer and a hole-injection layer. The subpixels 110a and the subpixels 110c are alternately arranged in the Y direction in the column CL1.

The nozzle 108 and the substrate included in the layer 101 are relatively moved so that the nozzle 108 moves in the Y direction with respect to the substrate included in the layer 101.

The dripped droplet 109 forms a layer 109B over the pixel electrode 111a. The solvent or the like is removed from the layer 109B, so that the layer 116 can be formed.

Next, in the subpixels in the column CL2, the droplets 109 are dripped from the nozzle 108 by an inkjet method (FIG. 12B). The subpixels 110c and the subpixels 110b are alternately arranged in the Y direction in the column CL2.

The nozzle 108 and the substrate included in the layer 101 are relatively moved so that the nozzle 108 moves in the Y direction with respect to the substrate included in the layer 101. Next, the solvent or the like is removed from the layer 109B, so that the layer 116 is formed.

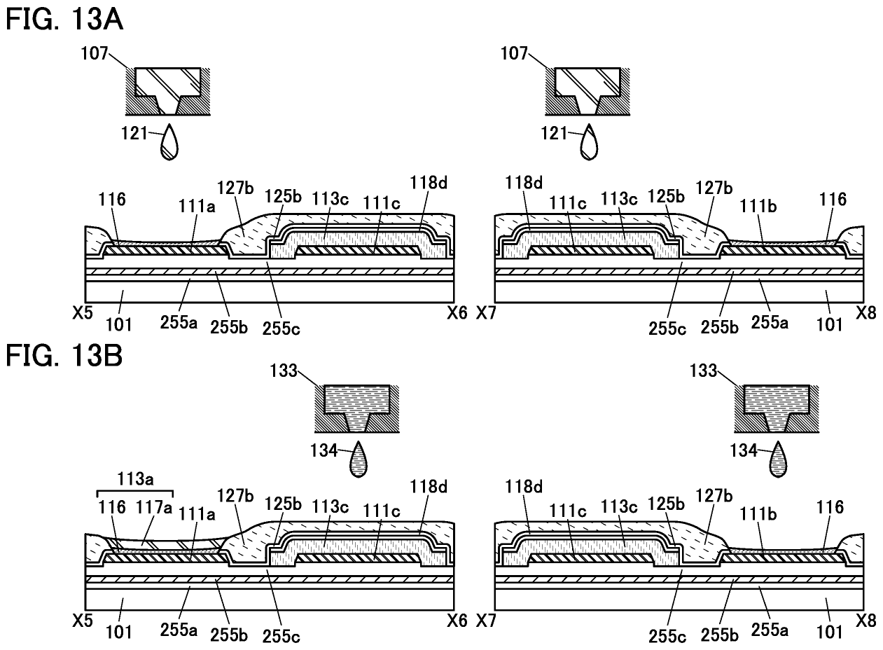

Next, in the subpixels in the column CL1, the droplets 121 are dripped from the nozzle 107 by an inkjet method (FIG. 13A). The droplets 121 contain a red-light-emitting material.

Next, the solvent or the like is removed from the dripped droplets 121, so that the layer 117a is formed.

Next, in the subpixels in the column CL2, the droplets 134 are dripped from the nozzle 133 by an inkjet method (FIG. 13B). The droplet 134 contains a green-light-emitting material. Next, the solvent or the like is removed from the dripped droplets 134, so that the layer 117b is formed.

The droplets 109, the droplets 121, and the droplets 134 can be continuously dripped in linear shapes. Alternatively, the droplets 109, the droplets 121, and the droplets 134 may be dripped intermittently. In the case of intermittent dripping, the droplets 109, the droplets 121, and the droplets 134 are not dripped and discharge thereof is stopped in a region over the subpixel 110c, for example.

In the case of continuously dripping the droplets 121 in a linear shape, the droplet 121 is also dripped onto the insulating layer 127b at the time of dripping the droplets 121 in FIG. 13A. Also in such a case, performing liquid-repellent treatment on a surface of the insulating layer 127b is preferable in order to prevent the dripped droplet 121 from forming a film over the insulating layer 127b or to make the thickness of the formed film over the insulating layer 127b smaller than that over the pixel electrode.

Furthermore, also in the case of intermittently dripping the droplets 121, when the pixel density is high, there is a concern that the droplet 121 may be dripped onto a region over the subpixel 110c. Also in such a case, performing liquid-repellent treatment on the surface of the insulating layer 127b is preferable in order to prevent the dripped droplet 121 from forming a film over the insulating layer 127b or to make the thickness of the formed film over the insulating layer 127b smaller than that over the pixel electrode.

In the case of continuously dripping the droplets 134 in a linear shape, the droplet 134 is also dripped onto the insulating layer 127b at the time of dripping the droplets 134 in FIG. 13B. Also in such a case, performing liquid-repellent treatment on the surface of the insulating layer 127b is preferable in order to prevent the dripped droplet 134 from forming a film over the insulating layer 127b or to make the thickness of the formed film over the insulating layer 127b smaller than that over the pixel electrode.

Furthermore, also in the case of intermittently dripping the droplets 134, when the pixel density is high, there is a concern that the droplet 134 may be dripped onto a region over the subpixel 110c. Also in such a case, performing liquid-repellent treatment on the surface of the insulating layer 127b is preferable in order to prevent the dripped droplet 134 from forming a film over the insulating layer 127b or to make the thickness of the formed film over the insulating layer 127b smaller than that over the pixel electrode.

The description in FIG. 6A to FIG. 7A can be referred to for the formation of the layer 116, the layer 117a, and the layer 117b.

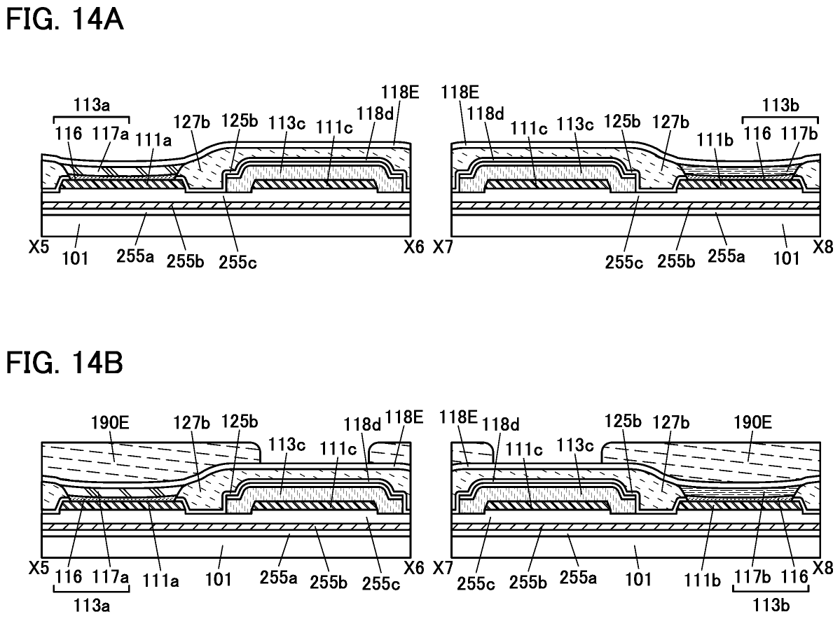

Next, a mask layer 118E is formed to cover the layer 117a, the layer 117b, and the insulating layer 127b (FIG. 14A).

For the mask layer 118E, any of the above-described materials, structures, and formation methods for the first mask layer 118A and the second mask layer 119A can be used. The mask layer 118E can have a stacked-layer structure of the first mask layer 118A and the second mask layer 119A described above. Alternatively, the structure of either the first mask layer 118A or the second mask layer 119A may be used for the mask layer 118E.

Next, a resist mask 190E is formed over the mask layer 118E (FIG. 14B).

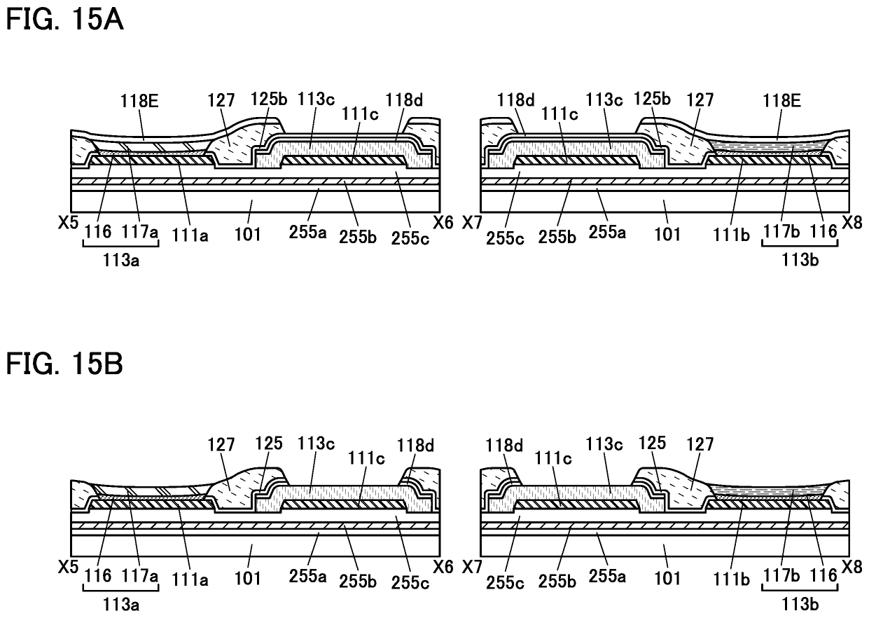

Next, part of the mask layer 118E is removed using the resist mask 190E, so that the mask layer 118d is formed. Then, the resist mask is removed. Then, part of the insulating layer 127b is removed using the mask layer 118d as a mask, so that the insulating layer 127 is formed (FIG. 15A). After the insulating layer 127b is removed, the resist mask 190E may be removed.

Next, the mask layer 118E is removed. Part of the mask layer 118d is removed using the insulating layer 127 as a mask. Next, part of the insulating layer 125b is removed using the insulating layer 127 as a mask, so that the insulating layer 125 is formed. (FIG. 15B). Note that when the same material is used for the mask layer 118E and the mask layer 118d, the mask layer 118E and the mask layer 118d can be removed at the same time in some cases.

Next, the common layer 114, the common electrode 115, and the protective layer 131 are formed in order so as to cover the layer 113a, the layer 113b, and the layer 113c.

The common layer 114 is one or two or more layers selected from an electron-transport layer and an electron-injection layer.

Note that in the case where the layer 113c illustrated in FIG. 15B includes an electron-transport layer and the common layer 114 includes an electron-transport layer, the light-emitting device 130c has a structure in which the electron-transport layer included in the layer 113c and the electron-transport layer included in the common layer 114 are stacked.

Then, the substrate 120 is bonded to the protective layer 131 using the resin layer 122. Through the above-described steps, the display apparatus 100 can be manufactured.

This embodiment can be combined with the other embodiments as appropriate.

### Embodiment 2

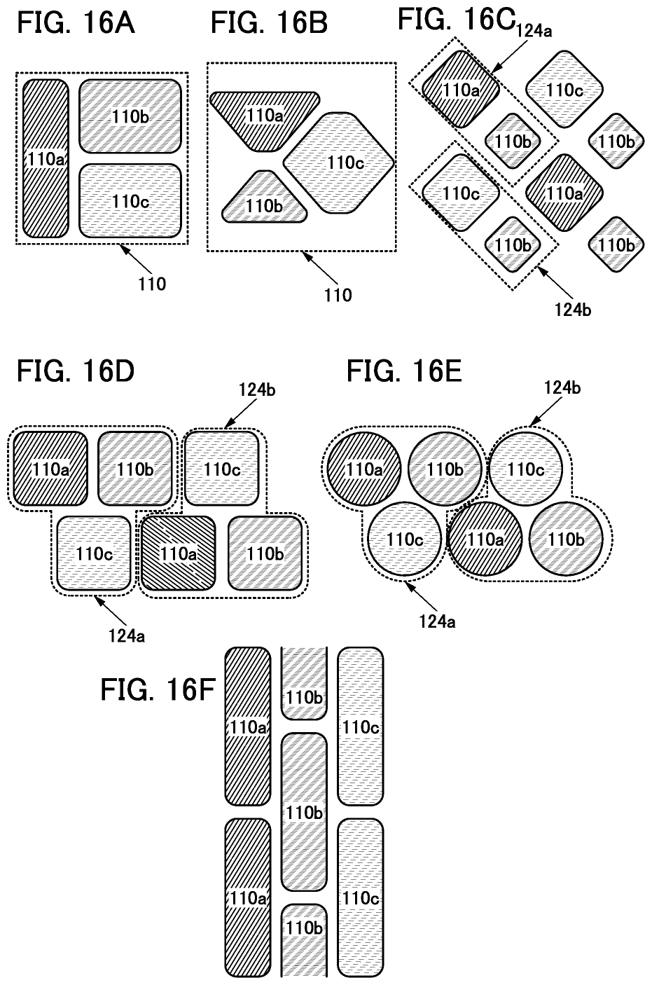

In this embodiment, the display apparatus of one embodiment of the present invention is described with reference to FIG. 16 to FIG. 19.

### [Pixel Layout]

In this embodiment, pixel layouts different from that in FIG. 1A are mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of a top surface shape of the subpixel include polygons such as a triangle, a tetragon (including a rectangle and a square), and a pentagon; polygons with rounded corners; an ellipse; and a circle. Here, a top surface shape of the subpixel corresponds to a top surface shape of a light-emitting region of the light-emitting device.

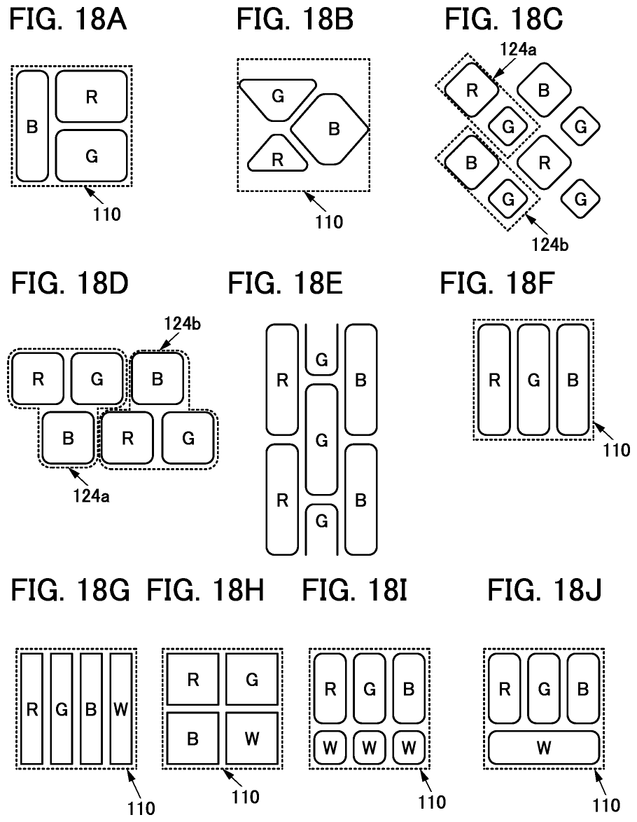

The pixel 110 illustrated in FIG. 16A employs S-stripe arrangement. The pixel 110 illustrated in FIG. 16A is made up of three subpixels 110a, 110b, and 110c. For example, as illustrated in FIG. 18A, the subpixel 110a may be a blue subpixel B, the subpixel 110b may be a red subpixel R, and the subpixel 110c may be a green subpixel G.

The pixel 110 illustrated in FIG. 16B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 18B, the subpixel 110a may be the green subpixel G, the subpixel 110b may be the red subpixel R, and the subpixel 110c may be the blue subpixel B.

Pixels 124a and 124b illustrated in FIG. 16C employ pentile arrangement. FIG. 16C illustrates an example where the pixels 124a including the subpixel 110a and the subpixel 110b and the pixels 124b including the subpixel 110b and the subpixel 110c are alternately arranged. For example, as illustrated in FIG. 18C, the subpixel 110a may be the red subpixel R, the subpixel 110b may be the green subpixel G, and the subpixel 110c may be the blue subpixel B.

The pixels 124a and 124b illustrated in FIG. 16D and FIG. 16E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 18D, the subpixel 110a may be the red subpixel R, the subpixel 110b may be the green subpixel G, and the subpixel 110c may be the blue subpixel B.

FIG. 16D is an example where each subpixel has a rough quadrangular top surface shape with rounded corners, and FIG. 16E is an example where each subpixel has a circular top surface shape.

FIG. 16F illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 18E, the subpixel 110a may be the red subpixel R, the subpixel 110b may be the green subpixel G, and the subpixel 110c may be the blue subpixel B.

Also in the pixel 110 illustrated in FIG. 1A, which employs stripe arrangement, for example, the subpixel 110a can be the red subpixel R, the subpixel 110b can be the green subpixel G, and the subpixel 110c can be the blue subpixel B as illustrated in FIG. 18F.

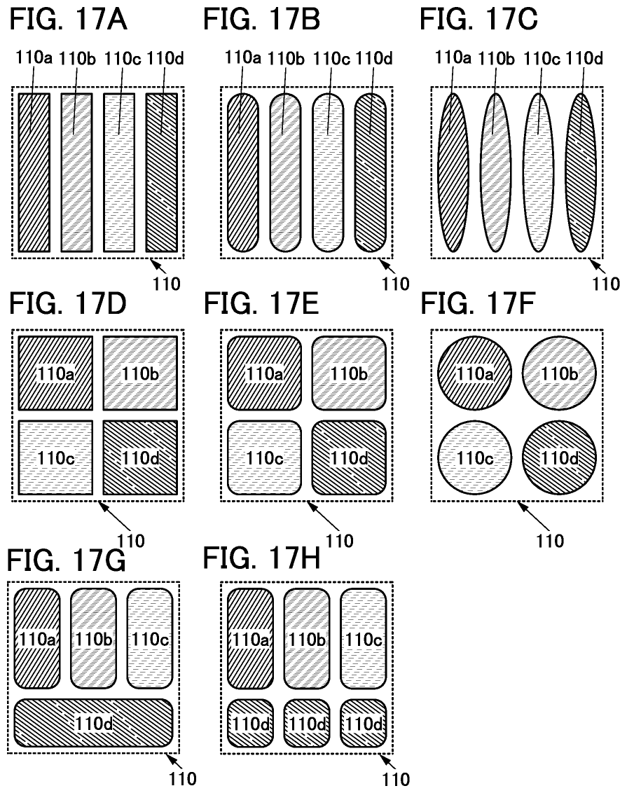

As illustrated in FIG. 17A to FIG. 17H, the pixel can include four types of subpixels.

The pixels 110 illustrated in FIG. 17A to FIG. 17C employ stripe arrangement.

FIG. 17A illustrates an example where each subpixel has a rectangular top surface shape, FIG. 17B illustrates an example where each subpixel has a top surface shape formed by combining two half circles and a rectangle, and FIG. 17C illustrates an example where each subpixel has an elliptical top surface shape.

The pixels 110 illustrated in FIG. 17D to FIG. 17F employ matrix arrangement.

FIG. 17D illustrates an example where each subpixel has a square top surface shape, FIG. 17E illustrates an example where each subpixel has a substantially square top surface shape with rounded corners, and FIG. 17F illustrates an example where each subpixel has a circular top surface shape.

FIG. 17G and FIG. 17H each illustrate an example where one pixel 110 is composed of two rows and three columns.

The pixel 110 illustrated in FIG. 17G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 17H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another the subpixel 110d in the center column (second column), and the subpixel 110c and another subpixel 110d in the right column (third column). Matching the positions of the subpixels in the upper row and the lower row as illustrated in FIG. 17H enables dust and the like that would be produced in the manufacturing process to be removed efficiently. Thus, a display apparatus with high display quality can be provided.

The pixels 110 illustrated in FIG. 17A to FIG. 17H are each composed of the four subpixels 110a, 110b, 110c, and 110d. The subpixels 110a, 110b, 110c, and 110d include light-emitting devices that emit light of different colors. The subpixels 110a, 110b, 110c, and 110d can be of four colors of R, G, B, and white (W), of four colors of R, G, B, and Y, of four colors of R, G, B, and infrared light (IR), or the like. For example, the subpixels 110a, 110b, 110c, and 110d can be, respectively, red, green, blue, and white subpixels as illustrated in FIG. 18G to FIG. 18J.

The display apparatus of one embodiment of the present invention may include a light-receiving device (also referred to as light-receiving element) in the pixel.

Three of the four subpixels included in the pixel 110 illustrated in FIG. 18G to FIG. 18J may include a light-emitting device and the other one may include a light-receiving device.

For example, the subpixels 110a, 110b, and 110c may be subpixels of three colors of R, G, and B, and the subpixel 110d may be a subpixel including the light-receiving device.

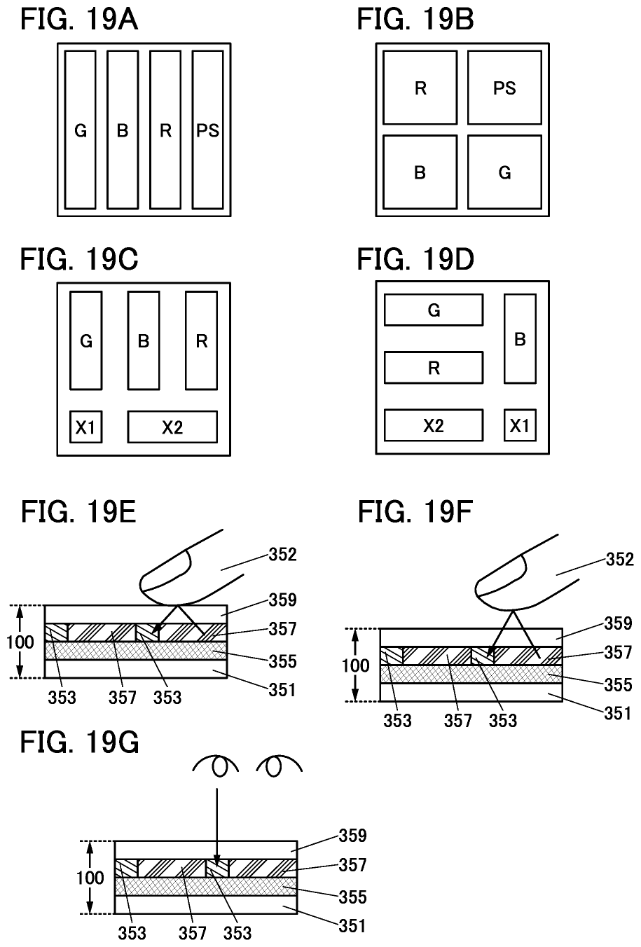

Pixels illustrated in FIG. 19A and FIG. 19B each include the subpixel G, the subpixel B, the subpixel R, and a subpixel PS. Note that the arrangement order of the subpixels is not limited to the structures illustrated in the drawings and can be determined as appropriate. For example, the positions of the subpixel G and the subpixel R may be interchanged with each other.

The pixel illustrated in FIG. 19A employs stripe arrangement. The pixel illustrated in FIG. 19B employs matrix arrangement.

The subpixel R includes a light-emitting device that emits red light. The subpixel G includes a light-emitting device that emits green light. The subpixel B includes a light-emitting device that emits blue light.

The subpixel PS includes a light-receiving device. The wavelength of light detected by the subpixel PS is not particularly limited. The subpixel PS can have a structure in which one or both of infrared light and visible light can be detected.

Pixels illustrated in FIG. 19C and FIG. 19D each include the subpixel G, the subpixel B, the subpixel R, the subpixel X1, and a subpixel X2. Note that the arrangement order of the subpixels is not limited to the structures illustrated in the drawings and can be determined as appropriate. For example, the positions of the subpixel G and the subpixel R may be interchanged with each other.

FIG. 19C illustrates an example where one pixel is provided in two rows and three columns. Three subpixels (the subpixel G, the subpixel B, and the subpixel R) are provided in the upper row (first row). In FIG. 19C, two subpixels (the subpixel X1 and the subpixel X2) are provided in the lower row (second row).

FIG. 19D illustrates an example where one pixel is composed of three rows and two columns. In FIG. 19D, the pixel includes the subpixel G in the first row, the subpixel R in the second row, and the subpixel B across these two rows. In addition, two subpixels (the subpixel X1 and the subpixel X2) are provided in the third row. In other words, the pixel illustrated in FIG. 19D includes three subpixels (the subpixel G, the subpixel R, and the subpixel X2) in the left column (first column) and two subpixels (the subpixel B and the subpixel X1) in the right column (second column).

The layout of the subpixels R, G, and B illustrated in FIG. 19C is stripe arrangement. The layout of the subpixels R, G, and B illustrated in FIG. 19D is what is called S stripe arrangement. Thus, high display quality can be achieved.

At least one of the subpixel X1 and the subpixel X2 preferably includes the light-receiving device (also referred to as subpixel PS).

Note that the layout of the pixels including the subpixel PS is not limited to the structures illustrated in FIG. 19A to FIG. 19D.

The subpixel X1 or the subpixel X2 can have a structure including a light-emitting device that emits infrared light (IR), for example. In this case, the subpixel PS preferably detects infrared light. For example, while an image is displayed using the subpixels R, G, and B, reflected light of the light emitted from one of the subpixel X1 and the subpixel X2 as a light source can be detected by the other of the subpixel X1 and the subpixel X2.

Both of the subpixel X1 and the subpixel X2 can have a structure including a light-receiving device, for example. In this case, the wavelength ranges of the light detected by the subpixel X1 and the subpixel X2 may be the same, different, or partially the same. For example, one of the subpixel X1 and the subpixel X2 may mainly detect visible light, while the other may mainly detects infrared light.

The light-receiving area of the subpixel X1 is smaller than the light-receiving area of the subpixel X2. A smaller light-receiving area leads to a narrower image-capturing range, prevents a blur in a captured image, and improves the definition. Thus, the use of the subpixel X1 enables higher-resolution or higher-definition image capturing than the use of the light-receiving device included in the subpixel X2. For example, image capturing for personal authentication with the use of a fingerprint, a palm print, the iris, the shape of a blood vessel (including the shape of a vein and the shape of an artery), a face, or the like is possible by using the subpixel X1.

The light-receiving device included in the subpixel PS preferably detects visible light, and preferably detects one or more colors of blue, violet, bluish violet, green, greenish yellow, yellow, orange, red, and the like. The light-receiving device included in the subpixel PS may detect infrared light.

In the case where the subpixel X2 has a structure including the light-receiving device, the subpixel X2 can be used in a touch sensor (also referred to as a direct touch sensor), a near touch sensor (also referred to as a hover sensor, a hover touch sensor, a contactless sensor, or a touchless sensor), or the like. The wavelength of light detected by the subpixel X2 can be determined as appropriate depending on the application purpose. For example, the subpixel X2 preferably detects infrared light. Thus, touch detection is possible even in a dark place.

Here, the touch sensor or the near touch sensor can detect an approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus can preferably detect an object when the distance between the display apparatus and the object is greater than or equal to 0.1 mm and less than or equal to 300 mm, preferably greater than or equal to 3 mm and less than or equal to 50 mm. This structure enables the display apparatus to be operated without direct contact of an object; in other words, the display apparatus can be operated in a contactless (touchless) manner. With the above structure, the display apparatus can be controlled with a reduced risk of making the display apparatus dirty or damaging the display apparatus or without the object directly touching a dirt (e.g., dust, bacteria, or a virus) attached to the display apparatus.

The refresh rate of the display apparatus of one embodiment of the present invention can be variable. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. In the case where the refresh rate of the display apparatus is 120 Hz, for example, the driving frequency of the touch sensor or the near touch sensor can be higher than 120 Hz (typically 240 Hz). With this structure, low power consumption can be achieved, and the response speed of the touch sensor or the near-touch sensor can be increased.

The display apparatus 100 illustrated in FIG. 19E to FIG. 19G includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. A switch, a transistor, a capacitor, a resistor, a wiring, a terminal, and the like can be provided in the functional layer 355. Note that in the case where the light-emitting device and the light-receiving device are driven by a passive-matrix method, a structure not provided with a switch or a transistor may be employed.

For example, after light emitted from the light-emitting device in the layer 357 including the light-emitting device is reflected by a finger 352 touching the display apparatus 100 as illustrated in FIG. 19E, the light-receiving device in the layer 353 including the light-receiving device detects the reflected light. Thus, the touch of the finger 352 on the display apparatus 100 can be detected.

Alternatively, the display apparatus may have a function of detecting an object that is approaching (not touching) the display apparatus as illustrated in FIG. 19F and FIG. 19G or capturing an image of such an object. FIG. 19F illustrates an example where a human finger is detected, and FIG. 19G illustrates an example where information on the periphery, surface, or inside of the human eye (e.g., the number of blinks, movement of an eyeball, and movement of an eyelid) is detected.

In the display apparatus of this embodiment, an image of the periphery of an eye, the surface of the eye, or the inside (fundus or the like) of the eye of a user of a wearable device can be captured with the use of the light-receiving device. Therefore, the wearable device can have a function of detecting one or more selected from a blink, movement of an iris, and movement of an eyelid of the user.

As described above, the pixel composed of the subpixels including the light-emitting devices can employ any of a variety of layouts in the display apparatus of one embodiment of the present invention. The display apparatus of one embodiment of the present invention can have a structure in which the pixel includes both a light-emitting device and a light-receiving device. Also in this case, any of a variety of layouts can be employed.

This embodiment can be combined with the other embodiments as appropriate.

### Embodiment 3

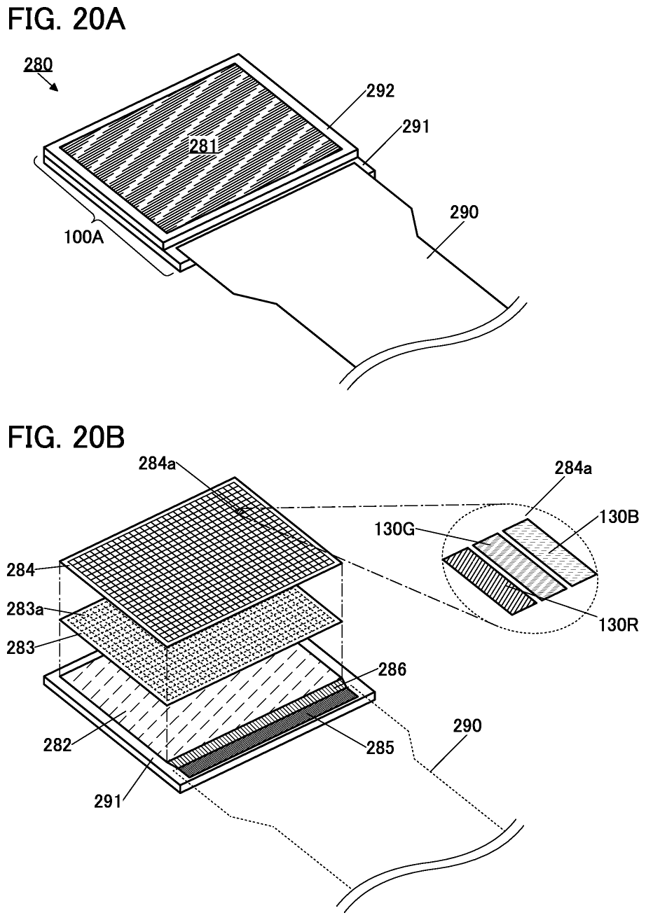

In this embodiment, the display apparatus of one embodiment of the present invention is described with reference to FIG. 20 to FIG. 30.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display and a glasses-type AR device.

The display apparatus of this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

### [Display Module]

FIG. 20A is a perspective view of a display module 280. The display module 280 includes a display apparatus 100A and an FPC 290. Note that the display apparatus included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 20B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 20B. The pixel 284a includes the light-emitting device 130R that emits red light, the light-emitting device 130G that emits green light, and the light-emitting device 130B that emits blue light.

The pixel circuit portion 283 includes a plurality of pixel circuits 283a arranged periodically.

One pixel circuit 283a is a circuit that controls light emission of three light-emitting devices included in one pixel 284a. One pixel circuit 283a may be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has an extremely high resolution, and thus can be suitably used for a VR device such as a head-mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device such as a watch.

### [Display Apparatus 100A]

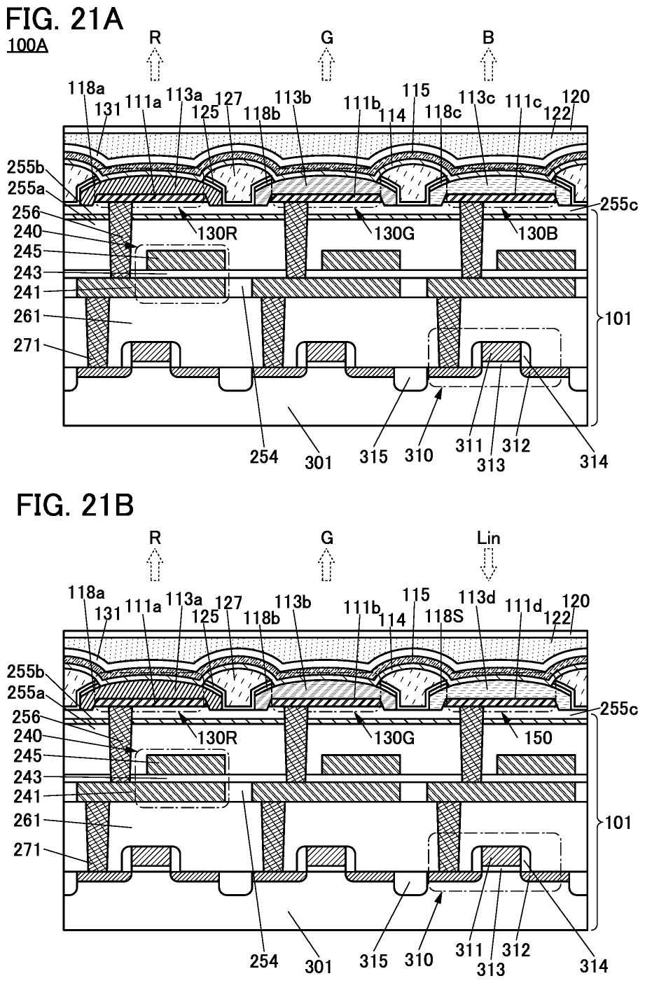

The display apparatus 100A illustrated in FIG. 21A includes a substrate 301, the light-emitting devices 130R, 130G and 130B, a capacitor 240, and a transistor 310. The light-emitting devices 130a, 130b, and 130c described in the above embodiment can be referred to for the light-emitting devices 130R, 130G, and 130B, respectively.

The substrate 301 corresponds to the substrate 291 in FIG. 20A and FIG. 20B. A stacked-layer structure including the substrate 301 and the components thereover up to the insulating layer 255c corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, the insulating layer 255b is provided over the insulating layer 255a, and the insulating layer 255c is provided over the insulating layer 255b.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and that a silicon nitride film be used as the insulating layer 255b. The insulating layer 255b preferably has a function of an etching protective film. Although this embodiment shows an example where a depressed portion is provided in the insulating layer 255c, a depressed portion is not necessarily provided in the insulating layer 255c.

The light-emitting device 130R, the light-emitting device 130G, and the light-emitting device 130B are provided over the insulating layer 255c. FIG. 21A illustrates an example where the light-emitting device 130R, the light-emitting device 130G, and the light-emitting device 130B have the stacked-layer structure illustrated in FIG. 2B.

Furthermore, since the layer 113a, the layer 113b, and the layer 113c are separated from each other in the display apparatus 100A, crosstalk generated between adjacent subpixels can be prevented while the display apparatus has high resolution. Accordingly, the display apparatus can have high resolution and high display quality.

An insulator is provided in a region between adjacent light-emitting devices. In FIG. 21A and the like, the insulating layer 125 and the insulating layer 127 over the insulating layer 125 are provided in the region.

A mask layer 118a is positioned over the layer 113a included in the light-emitting device 130R, a mask layer 118b is positioned over the layer 113b included in the light-emitting device 130G, and a mask layer 118c is positioned over the layer 113c included in the light-emitting device 130B.

The pixel electrode 111a, the pixel electrode 111b, and the pixel electrode 111c of the light-emitting device are each electrically connected to one of the source and the drain of the transistor 310 through a plug 256 embedded in the insulating layer 255a, the insulating layer 255b, and the insulating layer 255c, the conductive layer 241 embedded in the insulating layer 254, and the plug 271 embedded in the insulating layer 261. The level of the top surface of the insulating layer 255c is equal to or substantially equal to the level of the top surface of the plug 256. A variety of conductive materials can be used for the plugs.

Examples of a material that can be used for the plug 256 include metals such as aluminum, titanium, chromium, nickel, copper, yttrium, zirconium, molybdenum, gold, silver, platinum, magnesium, iron, cobalt, palladium, tantalum, or tungsten; an alloy containing any of these metal materials; and nitride of any of these metal materials. For the plug 256, a film containing any of these materials can be used in a single layer or as a stacked-layer structure. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, and a three-layer structure in which an aluminum film or a copper film is stacked over a molybdenum film or a molybdenum nitride film and a molybdenum film or a molybdenum nitride film is formed thereover can be given. Note that an oxide such as indium oxide, tin oxide, or zinc oxide may be used. Copper containing manganese is preferably used because it increases shape controllability by etching. FIG. 21A and the like illustrate an example where the pixel electrode has a two-layer structure of a reflective electrode and a transparent electrode over the reflective electrode.

The protective layer 131 is provided over the light-emitting device 130R, the light-emitting device 130G, and the light-emitting device 130B. The substrate 120 is bonded to the protective layer 131 with the resin layer 122. Embodiment 1 can be referred to for details of the light-emitting devices and the components thereover up to the substrate 120.

An insulating layer covering the end portion of the top surface of the pixel electrode 111a is not provided between the pixel electrode 111a and the layer 113a. An insulating layer covering the end portion of the top surface of the pixel electrode 111b is not provided between the pixel electrode 111b and the layer 113b. Thus, the interval between adjacent light-emitting devices can be extremely shortened. Accordingly, the display apparatus can have a high resolution or a high definition.

Although the display apparatus 100A includes the light-emitting devices 130R, 130G, and 130G in this example, the display apparatus of this embodiment may further include the light-receiving device.

The display apparatus illustrated in FIG. 21B includes the light-emitting devices 130R and 130G and a light-receiving device 150. The light-receiving device 150 has a stack of a pixel electrode 111d, a layer 113d, the common layer 114, and the common electrode 115. The layer 113d includes an active layer of the light-receiving device. Embodiment 1 can be referred to for the details of components of the light-receiving device 150. Note that when part of a mask layer 118S provided in contact with a top surface of the layer 113d for formation of the layer 113d remains over the layer 113d.

### [Display Apparatus 100B]

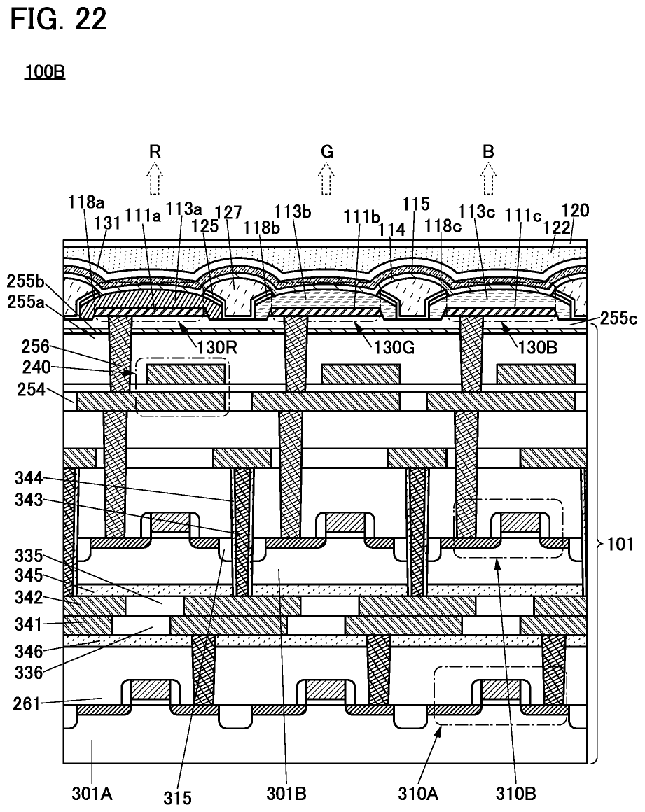

The display apparatus 100B illustrated in FIG. 22 has a structure where a transistor 310A and a transistor 310B in each of which a channel is formed in a semiconductor substrate are stacked. Note that in the description of the display apparatus below, portions similar to those of the above-mentioned display apparatus are not described in some cases.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used for the protective layer 131 or an insulating layer 332 can be used.

The substrate 301B is provided with a plug 343 that penetrates the substrate 301B and the insulating layer 345. An insulating layer 344 is preferably provided to cover a side surface of the plug 343. The insulating layer 344 functions as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Over the substrate 301A, a conductive layer 341 is provided over the insulating layer 346. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ Cu—Cu (copper-to-copper) direct bonding technique (a technique for achieving electrical continuity by connecting Cu (copper) pads).

### [Display Apparatus 100C]

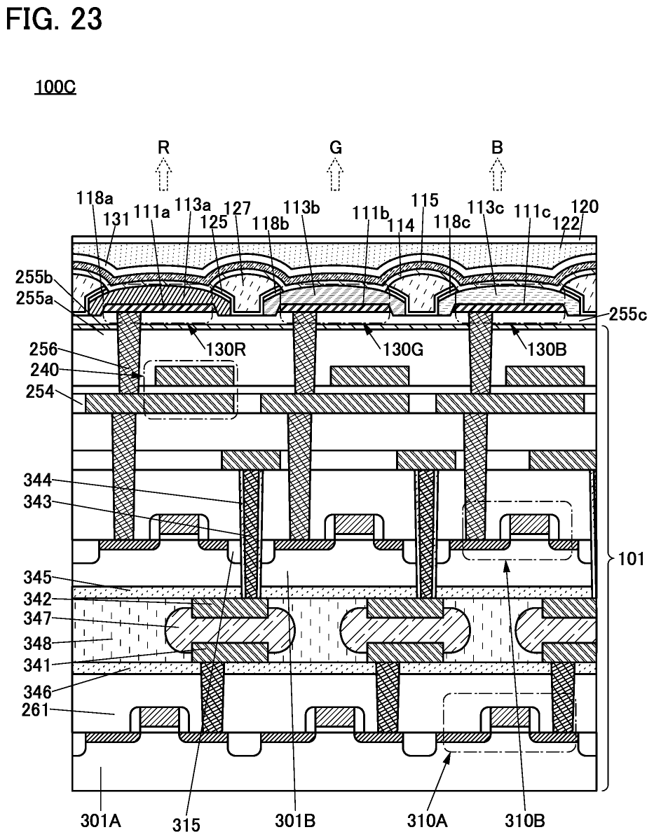

The display apparatus 100C illustrated in FIG. 23 has a structure where the conductive layer 341 and the conductive layer 342 are bonded to each other through a bump 347.

As illustrated in FIG. 23, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Apparatus 100D]

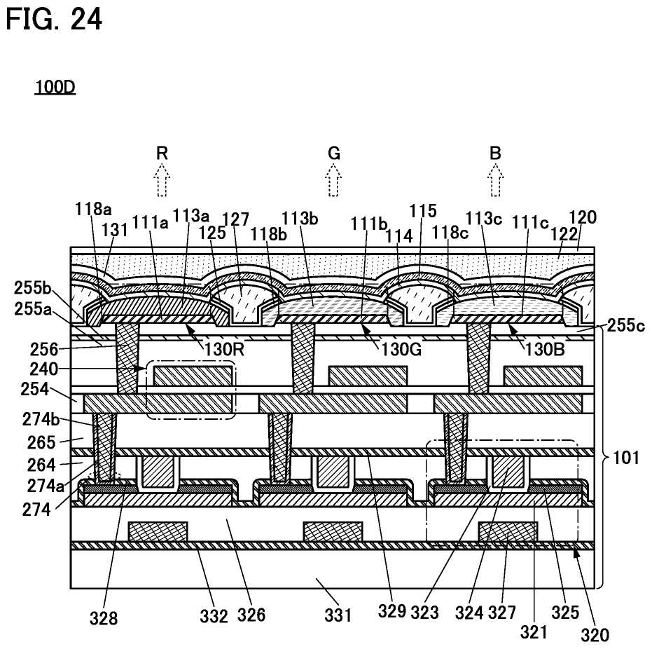

The display apparatus 100D illustrated in FIG. 24 differs from the display apparatus 100A mainly in a structure of a transistor.

A transistor 320 is a transistor that contains a metal oxide (also referred to as an oxide semiconductor) in a semiconductor layer where a channel is formed (i.e., an OS transistor). The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 20A and FIG. 20B. A stacked-layer structure including the substrate 331 and components thereover up to the insulating layer 255b corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided so as to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material through which hydrogen and oxygen are unlikely to diffuse is preferably used for the conductive layer 274a.

### [Display Apparatus 100E]

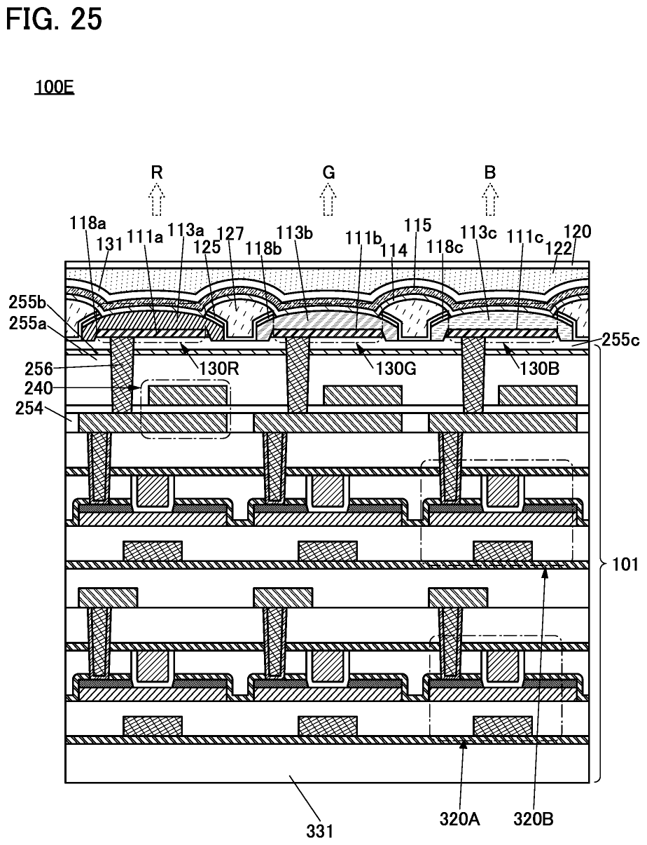

The display apparatus 100E illustrated in FIG. 25 has a structure in which a transistor 320A and a transistor 320B each including an oxide semiconductor in a semiconductor where a channel is formed are stacked.

The description of the display apparatus 100D can be referred to for the transistor 320A, the transistor 320B, and the components around them.

Although the structure where two transistors including an oxide semiconductor are stacked is described, the present invention is not limited thereto. For example, three or more transistors may be stacked.

### [Display Apparatus 100F]

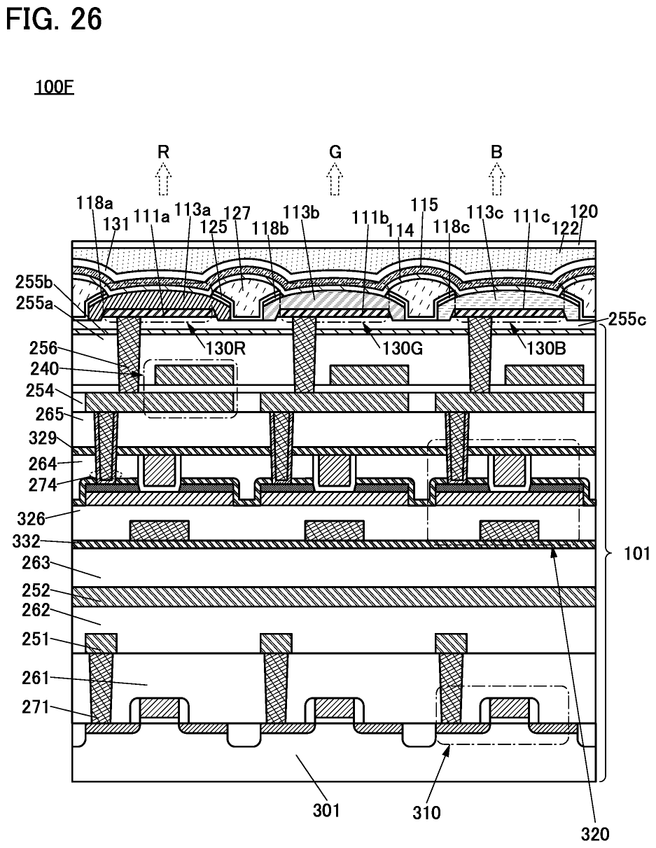

The display apparatus 100F illustrated in FIG. 26 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit (a gate line driver circuit or a source line driver circuit) for driving the pixel circuit. The transistor 310 and the transistor 320 can be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### [Display Apparatus 100G]

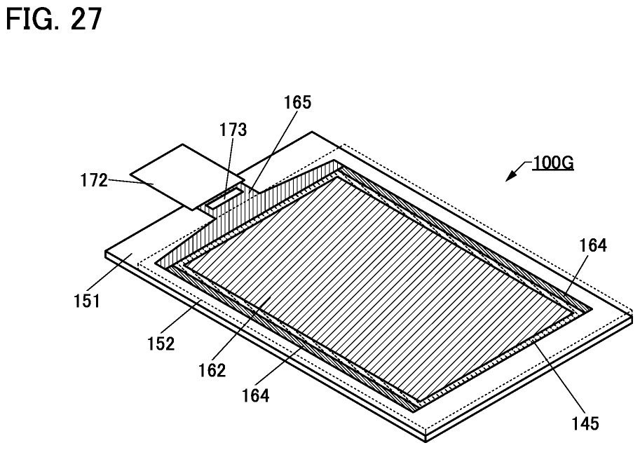

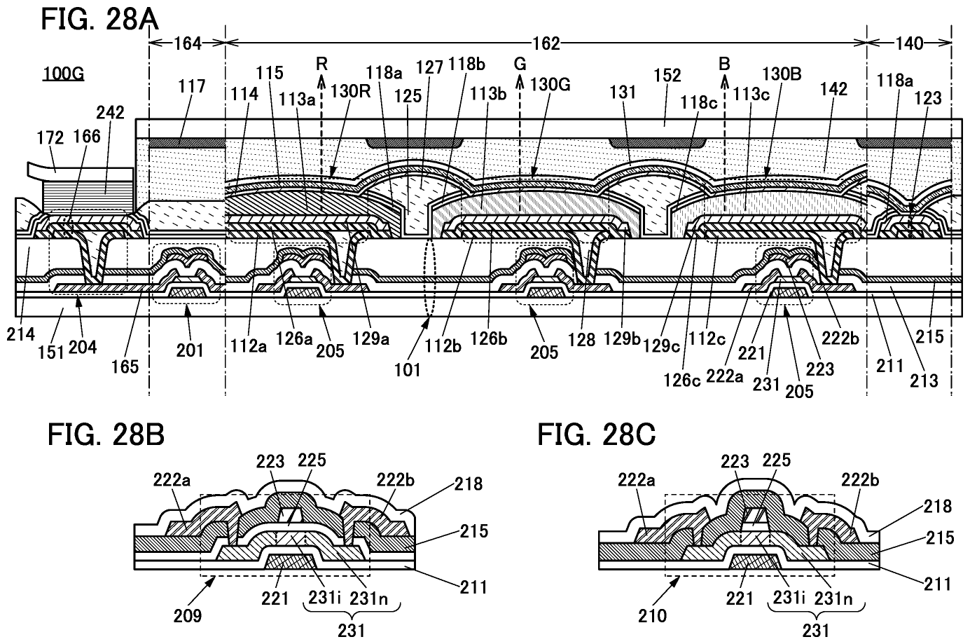

FIG. 27 is a perspective view of the display apparatus 100G, and FIG. 28A is a cross-sectional view of the display apparatus 100G.

In the display apparatus 100G, a substrate 152 and a substrate 151 are bonded to each other. In FIG. 27, the substrate 152 is denoted by a dashed line.

The display apparatus 100G includes a display portion 162, the connection portion 145, a circuit 164, a wiring 165, and the like. FIG. 27 illustrates an example where an IC 173 and an FPC 172 are mounted on the display apparatus 100G. Thus, the structure illustrated in FIG. 27 can be regarded as a display module including the display apparatus 100G, the IC (integrated circuit), and the FPC.

The connection portion 145 is provided outside the display portion 162. The connection portion 145 can be provided along one or more sides of the display portion 162. The number of connection portions 145 can be one or more. FIG. 27 illustrates an example where the connection portion 145 is provided to surround the four sides of the display portion. A common electrode of a light-emitting device is electrically connected to a conductive layer in the connection portion 145, so that a potential can be supplied to the common electrode.

As the circuit 164, a scan line driver circuit can be used, for example.

The wiring 165 has a function of supplying a signal and power to the display portion 162 and the circuits 164. The signal and power are input to the wiring 165 from the outside through the FPC 172 or from the IC 173.

FIG. 27 illustrates an example where the IC 173 is provided over the substrate 151 by a COG (Chip on Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 28A illustrates an example of cross sections of part of a region including the FPC 172, part of the circuit 164, part of the display portion 162, part of the connection portion 145, and part of a region including an end portion of the display apparatus 100G.

The display apparatus 100G illustrated in FIG. 28A includes a transistor 201, a transistor 205, the light-emitting device 130R that emits red light, the light-emitting device 130G that emits green light, the light-emitting device 130B that emits blue light, and the like between the substrate 151 and the substrate 152. The light-emitting devices 130a, 130b, and 130c described in the above embodiment can be referred to for the light-emitting devices 130R, 130G, and 130B, respectively.

The light-emitting devices 130R, 130G, and 130B each have the same structure as the stacked-layer structure illustrated in FIG. 2B except the structure of the pixel electrode. Embodiment 1 can be referred to for the details of the light-emitting devices.

Since the layer 113a, the layer 113b, and the layer 113c are separated from each other in the display apparatus 100G, crosstalk generated between adjacent subpixels can be prevented while the display apparatus 100G has high resolution. Accordingly, the display apparatus can have high resolution and high display quality.

The light-emitting device 130R includes a conductive layer 112a, a conductive layer 126a over the conductive layer 112a, and a conductive layer 129a over the conductive layer 126a. All of the conductive layers 112a, 126a, and 129a can be referred to as pixel electrodes, or one or two of them can be referred to as pixel electrode(s).

The light-emitting device 130G includes the conductive layer 112b, the conductive layer 126b over the conductive layer 112b, and the conductive layer 129b over the conductive layer 126b.

The light-emitting device 130B includes a conductive layer 112c, a conductive layer 126c over the conductive layer 112c, and a conductive layer 129c over the conductive layer 126c.

The conductive layer 112a is connected to the conductive layer 222b included in the transistor 205 through an opening provided in the insulating layer 214. The end portion of the conductive layer 126a is positioned outward from the end portion of the conductive layer 112a. The end portion of the conductive layer 126a and the end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

Detailed description of the conductive layers 112b, 126b, and 129b of the light-emitting device 130G and the conductive layers 112c, 126c, and 129c of the light-emitting device 130B is omitted because these conductive layers are similar to the conductive layers 112a, 126a, and 129a of the light-emitting device 130R.

Depressed portions are formed in the conductive layers 112a, 112b, and 112c to cover the openings provided in the insulating layer 214. A layer 128 is embedded in each of the depressed portions.

The layer 128 has a function of filling the depressed portions of the conductive layers 112a, 112b, and 112c. The conductive layers 126a, 126b, and 126c electrically connected to the conductive layers 112a, 112b, and 112c, respectively, are provided over the conductive layers 112a, 112b, and 112c and the layer 128. Thus, regions overlapping with the depressed portions of the conductive layers 112a, 112b, and 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surfaces of the conductive layers 112a, 112b, and 112c. When the layer 128 is formed using a negative photosensitive resin, the layer 128 can sometimes be formed using the same photomask (light-exposure mask) as the photomask used for forming the opening in the insulating layer 214.

The top and side surfaces of the conductive layer 126a and the top and side surfaces of the conductive layer 129a are covered with the layer 113a. Similarly, the top surface and side surfaces of the conductive layer 126b and the top and side surfaces of the conductive layer 129b are covered with the layer 113b. Moreover, the top and side surfaces of the conductive layer 126c and the top and side surfaces of the conductive layer 129c are covered with the layer 113c. Accordingly, regions provided with the conductive layers 126a, 126b, and 126c can be entirely used as the light-emitting regions of the light-emitting devices 130R, 130G, and 130B, increasing the aperture ratio of the pixels.

The side surfaces of the layer 113a, the layer 113b, and the layer 113c are covered with the insulating layers 125 and 127. The mask layer 118a is positioned between the layer 113a and the insulating layer 125. The mask layer 118b is positioned between the layer 113b and the insulating layer 125, and the mask layer 118c is positioned between the layer 113c and the insulating layer 125. The common layer 114 is provided over the layer 113a, the layer 113b, the layer 113c, and the insulating layers 125 and 127. The common electrode 115 is provided over the common layer 114. The common layer 114 and the common electrode 115 are each a continuous film shared by a plurality of light-emitting devices.

The protective layer 131 is provided over each of the light-emitting devices 130R, 130G, and 130B. The protective layer 131 covering the light-emitting devices can inhibit an impurity such as water from entering the light-emitting devices, and increase the reliability of the light-emitting devices.

The protective layer 131 and the substrate 152 are bonded to each other with an adhesive layer 142. A solid sealing structure, a hollow sealing structure, or the like can be employed to seal the light-emitting devices. In FIG. 28A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting devices. The space may be filled with a resin other than the frame-shaped adhesive layer 142.

The conductive layer 123 is provided over the insulating layer 214 in the connection portion 145. An example is described in which the conductive layer 123 has a stacked-layer structure of a conductive film obtained by processing the same conductive film as the conductive layers 112a, 112b, and 112c; a conductive film obtained by processing the same conductive film as the conductive layers 126a, 126b, and 126c; and a conductive film obtained by processing the same conductive film as the conductive layers 129a, 129b, and 129c. The end portion of the conductive layer 123 is covered with the mask layer 118a, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 145. In this case, the conductive layer 123 and the common electrode 115 are in direct contact with each other to be electrically connected to each other.

The display apparatus 100G has a top-emission structure. Light emitted from the light-emitting device is emitted toward the substrate 152. For the substrate 152, a material having a high visible-light-transmitting property is preferably used. The pixel electrode contains a material that reflects visible light, and a counter electrode (the common electrode 115) contains a material that transmits visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be prevented from being formed in the insulating layer 214 at the time of processing the conductive layer 112a, the conductive layer 126a, the conductive layer 129a, or the like. Alternatively, a depressed portion may be formed in the insulating layer 214 at the time of processing the conductive layer 112a, the conductive layer 126a, the conductive layer 129a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably includes a metal oxide (also referred to as an oxide semiconductor).

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, and component cost and mounting cost can be reduced.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black level degradation”, “increase in emission luminance”, “increase in the number of gray levels”, “inhibition of variation in light-emitting devices”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used.

When an In-M-Zn oxide is used for the semiconductor layer, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. The plurality of transistors included in the circuit 164 may have the same structure or two or more kinds of structures. Similarly, the plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure where an LTPS transistor and an OS transistor are used in combination is referred to as LTPO in some cases. Note that in a further suitable example, it is preferable that an OS transistor be used as, for example, a transistor functioning as a switch for controlling conduction and that non-conduction between wirings and an LTPS transistor be used as, for example, a transistor for controlling current.

For example, one of the transistors included in the display portion 162 functions as a transistor for controlling a current flowing through the light-emitting device and can also be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the display portion 162 functions as a switch for controlling selection and non-selection of the pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display can be achieved.

FIG. 28B and FIG. 28C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 28B illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 28C, the insulating layer 225 overlaps with the channel formation region 231i of the semiconductor layer 231 and does not overlap with the low-resistance regions 231n. The structure illustrated in FIG. 28C can be formed by processing the insulating layer 225 with the conductive layer 223 as a mask, for example. In FIG. 28C, the insulating layer 215 is provided to cover the insulating layer 225 and the conductive layer 223, and the conductive layer 222a and the conductive layer 222b are connected to the low-resistance regions 23 In through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layers 112a, 112b, and 112c, a conductive film obtained by processing the same conductive film as the conductive layers 126a, 126b, and 126c, and a conductive film obtained by processing the same conductive film as the conductive layers 129a, 129b, and 129c. The conductive layer 166 is exposed on the top surface of the connection portion 204. Thus, the connection portion 204 and the FPC 172 can be electrically connected to each other through the connection layer 242.

A light-blocking layer 117 is preferably provided on a surface of the substrate 152 that faces the substrate 151. The light-blocking layer 117 can be provided between adjacent light-emitting devices, in the connection portion 145, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

This embodiment can be combined with the other embodiments as appropriate.

### Embodiment 4

In this embodiment, a structure example of a transistor that can be used in the display apparatus of one embodiment of the present invention will be described. Specifically, the case of using a transistor including silicon as a semiconductor where a channel is formed will be described.

One embodiment of the present invention is a display apparatus including a light-emitting device and a pixel circuit. For example, the display apparatus includes three kinds of light-emitting devices emitting light of red (R), green (G), and blue (B), whereby a full-color display apparatus can be achieved.

Transistors containing silicon in their semiconductor layers where channels are formed are preferably used as all transistors included in the pixel circuit for driving the light-emitting device. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, such as LTPS transistors, a circuit required to be driven at a high frequency (e.g., a source driver circuit) can be formed on the same substrate as the display portion. Thus, external circuits mounted on the display apparatus can be simplified, and component cost and mounting cost can be reduced.

It is preferable to use transistors including a metal oxide (hereinafter also referred to as an oxide semiconductor) in the semiconductor where channels are formed (such transistors are hereinafter also referred to as OS transistors) as at least one of the transistors included in the pixel circuit. An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

When an LTPS transistor is used as one or more of the transistors included in the pixel circuit and an OS transistor is used as the rest of the transistors, a display apparatus with low power consumption and high driving capability can be achieved. As a more preferable example, it is preferable to use an OS transistor as, for example, a transistor functioning as a switch for controlling electrical continuity between wirings and an LTPS transistor as, for example, a transistor for controlling current.

For example, one of the transistors included in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the pixel circuit functions as a switch for controlling selection and non-selection of the pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

More specific structure examples are described below with reference to drawings.

### [Structure Example of Display Apparatus]

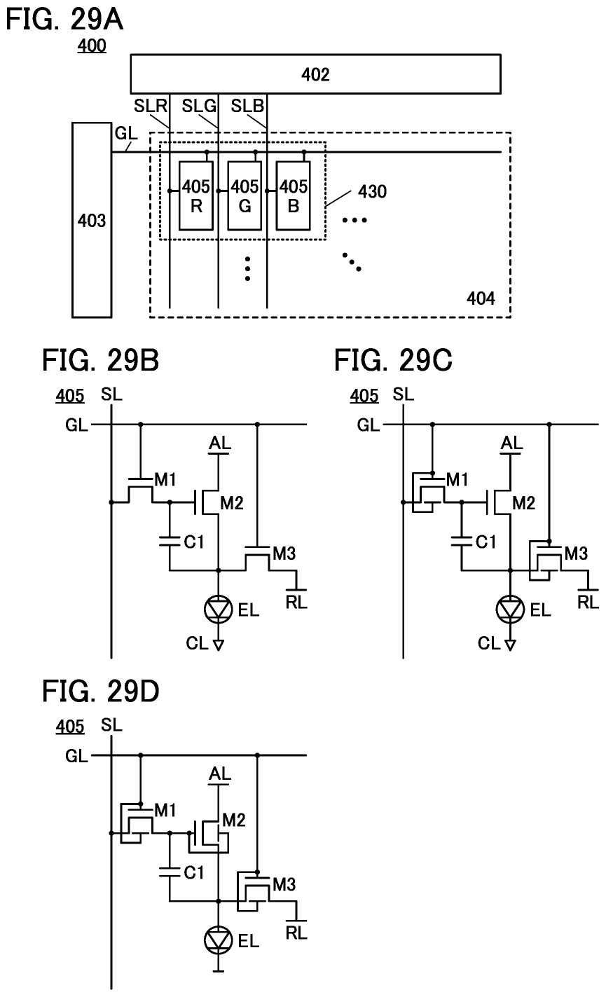

FIG. 29A illustrates a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting device functioning as a display device.

The pixel 430 is electrically connected to a wiring GL, a wiring SLR, a wiring SLG, and a wiring SLB. The wiring SLR, the wiring SLG, and the wiring SLB are electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting device emitting red light. The subpixel 405G includes a light-emitting device emitting green light. The subpixel 405B includes a light-emitting device emitting blue light. Thus, the display apparatus 400 can perform full-color display. Note that the pixel 430 may include a subpixel including a light-emitting device emitting light of another color. For example, the pixel 430 may include, in addition to the three subpixels, a subpixel including a light-emitting device emitting white light, a subpixel including a light-emitting device emitting yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 29B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting device EL. The wiring GL and a wiring SL are electrically connected to the pixel 405. The wiring SL corresponds to any of the wiring SLR, the wiring SLG, and the wiring SLB illustrated in FIG. 29A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. For example, the transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor including an oxide semiconductor in its semiconductor layer where a channel is formed can be used. The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and a lower carrier density than silicon can achieve an extremely low off-state current. Thus, such a low off-state current enables long-term retention of electric charge accumulated in a capacitor that is connected to the transistor in series. Therefore, it is particularly preferable to use a transistor including an oxide semiconductor as the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 405.

Note that although the transistor is illustrated as an n-channel transistor in FIG. 29B, a p-channel transistor can also be used.

The transistors included in the pixel 405 are preferably formed to be arranged over the same substrate.

Note that transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 29C is an example where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 29D is an example where a transistor including a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

### [Structure Example of Transistor]

Cross-sectional structure examples of a transistor that can be used in the display apparatus described above are described below.

### Structure Example 1

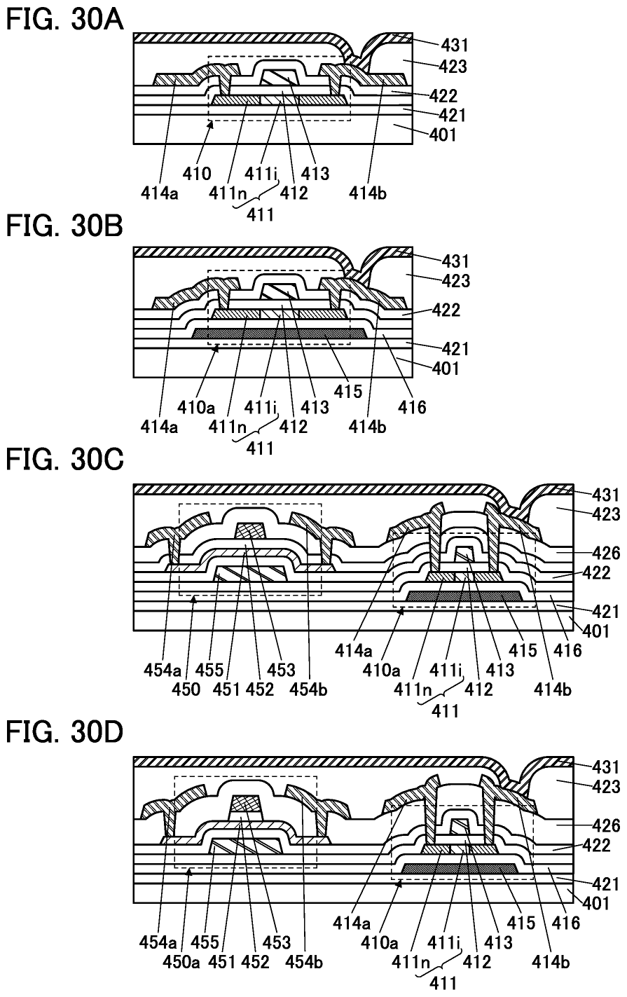

FIG. 30A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 30A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance region 41 In in the opening portion provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, and the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### Structure Example 2

FIG. 30B illustrates a transistor 410a including a pair of gate electrodes. The transistor 410a illustrated in FIG. 30B is different from FIG. 30A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 30B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 exemplified in FIG. 30A or the transistor 410a exemplified in FIG. 30B can be used. In this case, the transistors 410a may be used as all of the transistors included in the pixels 405, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 30C is a schematic cross-sectional view including the transistor 410a and a transistor 450.

Structure example 1 described above can be referred to for the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor including metal oxide in its semiconductor layer. The structure in FIG. 30C illustrates an example in which the transistor 450 corresponds to the transistor M1 and the transistor 410a corresponds to the transistor M2 in the pixel 405. That is, FIG. 30C illustrates an example in which one of a source and a drain of the transistor 410a is electrically connected to the conductive layer 431.

Moreover, FIG. 30C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in openings provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 30C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 41 In through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 30C illustrates a structure where the conductive layer 413 and the conductive layer 455 are formed on the same plane (i.e., in contact with the top surface of the insulating layer 412) and contain the same metal element. This is preferable because the manufacturing process can be simplified.

In the structure in FIG. 30C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in the transistor 450a illustrated in FIG. 30D.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 5

In this embodiment, a light-emitting device that can be used in the display apparatus of one embodiment of the present invention will be described.

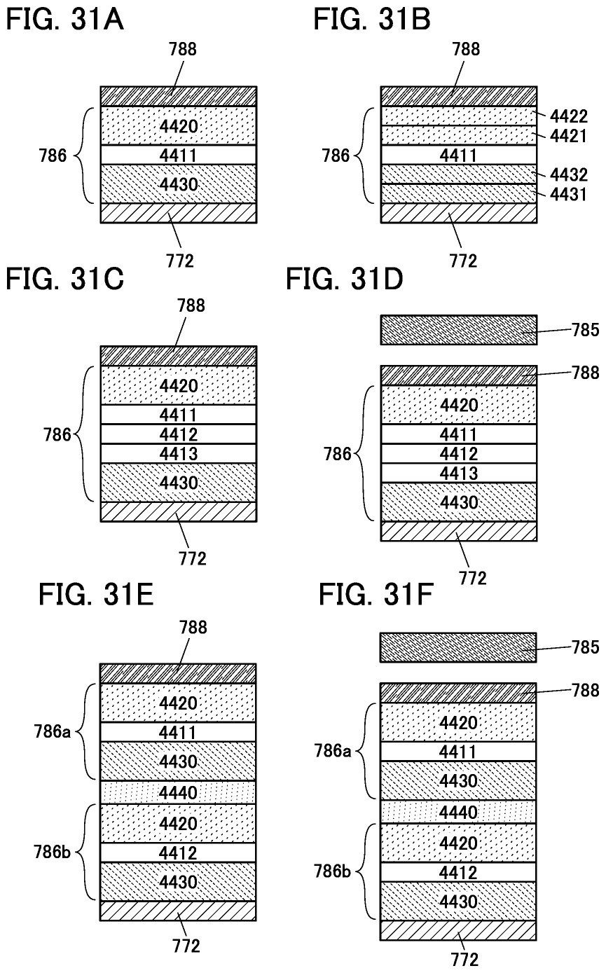

As illustrated in FIG. 31A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can function as a single light-emitting unit, and the structure in FIG. 31A is referred to as a single structure in this specification.

FIG. 31B is a variation example of the EL layer 786 included in the light-emitting device illustrated in FIG. 31A. Specifically, the light-emitting device illustrated in FIG. 31B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. When the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layer structure, carriers can be efficiently injected to the light-emitting layer 4411, and the efficiency of the recombination of carriers in the light-emitting layer 4411 can be enhanced.

Note that the structure where a plurality of light-emitting layers (light-emitting layers 4411, 4412, and 4413) are provided between the layer 4420 and the layer 4430 as illustrated in FIG. 31C and FIG. 31D is also a variation of the single structure.

A structure in which a plurality of light-emitting units (an EL layer 786a and an EL layer 786b) are connected in series with a charge-generation layer 4440 therebetween as illustrated in FIG. 31E or FIG. 31F is referred to as a tandem structure in this specification. Note that a tandem structure may be referred to as a stack structure. The tandem structure enables a light-emitting device capable of high-luminance light emission.

In FIG. 31C and FIG. 31D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 31D.

Alternatively, light-emitting materials that emit light of different colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 31D. When white light passes through a color filter, light of a desired color can be obtained.

In FIG. 31E and FIG. 31F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when the light-emitting layer 4411 and the light-emitting layer 4412 emit light of complementary colors. FIG. 31F illustrates an example where the layer 785 is further provided. One or both of a color conversion layer and a color filter (coloring layer) can be used as the layer 785.

Note that also in FIG. 31C, FIG. 31D, FIG. 31E, and FIG. 31F, the layer 4420 and the layer 4430 may each have a stacked-layer structure of two or more layers as illustrated in FIG. 31B.

A structure in which light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, white, or the like depending on the material that constitutes the EL layer 786. Furthermore, the color purity can be further increased when the light-emitting device has a microcavity structure.

The light-emitting device that emits white light preferably contains two or more kinds of light-emitting substances in the light-emitting layer. To obtain white light emission, two or more light-emitting substances may be selected such that their emission colors are complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

The light-emitting layer preferably contains two or more selected from light-emitting substances that emit light of red (R), green (G), blue (B), yellow (Y), orange (O), and the like. Alternatively, the light-emitting layer preferably contains two or more light-emitting substances that emit light containing two or more of spectral components of R, G, and B.

This embodiment can be combined with the other embodiments as appropriate.

### Embodiment 6

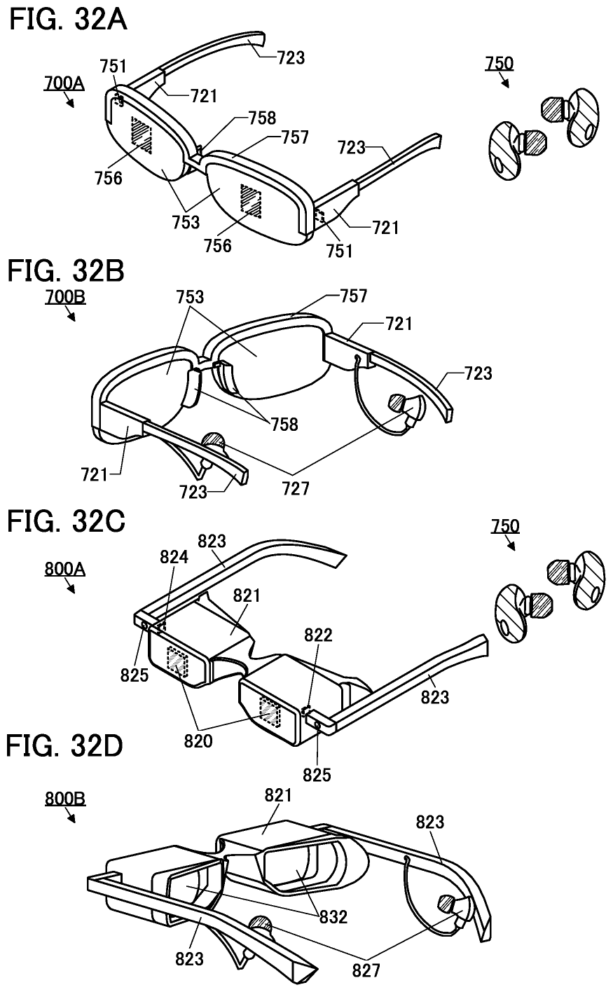

In this embodiment, electronic devices of one embodiment of the present invention are described with reference to FIG. 32 to FIG. 34.

Electronic devices of this embodiment each include the display apparatus of one embodiment of the present invention in a display portion. The display apparatus according to one embodiment of the present invention can easily achieve higher resolution and higher definition and can achieve high display quality. Thus, the display apparatus of one embodiment of the present invention can be used for a display portion of a variety of electronic devices.

Examples of electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, the display apparatus of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 32A to FIG. 32D. These wearable devices have one or both of a function of displaying AR contents and a function of displaying VR contents. Note that these wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 32A and an electronic device 700B illustrated in FIG. 32B each include a pair of display apparatuses 751, a pair of housings 721, a communication portion (not illustrated), a pair of mounting portions 723, a control portion (not illustrated), an image capturing portion (not illustrated), a pair of optical members 753, a frame 757, and a pair of nose pads 758.

The display apparatus of one embodiment of the present invention can be used for the display apparatuses 751. Thus, the electronic device can perform ultrahigh-resolution display.

The electronic device 700A and the electronic device 700B can each project images displayed on the display apparatuses 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 32C and an electronic device 800B illustrated in FIG. 32D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic device can perform ultrahigh-resolution display. Such an electronic device provides an enhanced sense of immersion to the user.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for laterally adjusting the positions of the lenses 832 and the display portions 820 so that the lenses 832 and the display portions 820 can be positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the mounting portions 823. FIG. 32C or the like illustrates an example where the mounting portions 823 have a shape like a temple (also referred to as a joint or the like) of glasses; however, one embodiment of the present invention is not limited thereto. The mounting portions 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor capable of measuring a distance between the user and an object (hereinafter also referred to as a sensing portion) just needs to be provided. In other words, the image capturing portion 825 is one embodiment of the sensing portion. As the sensing portion, an image sensor or a distance image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, any one or more of the display portion 820, the housing 821, and the mounting portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 32A has a function of transmitting information to the earphones 750 with the wireless communication function. As another example, the electronic device 800A illustrated in FIG. 32C has a function of transmitting information to the earphones 750 with the wireless communication function.

The electronic device may include an earphone portion. The electronic device 700B in FIG. 32B includes earphone portions 727. For example, the earphone portion 727 and the control portion can be connected to each other by wire. Part of a wiring that connects the earphone portion 727 and the control portion may be positioned inside the housing 721 or the mounting portion 723.

Similarly, the electronic device 800B illustrated in FIG. 32D includes earphone portions 827. For example, the earphone portion 827 and the control portion 824 can be connected to each other by wire. Part of a wiring that connects the earphone portion 827 and the control portion 824 may be positioned inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

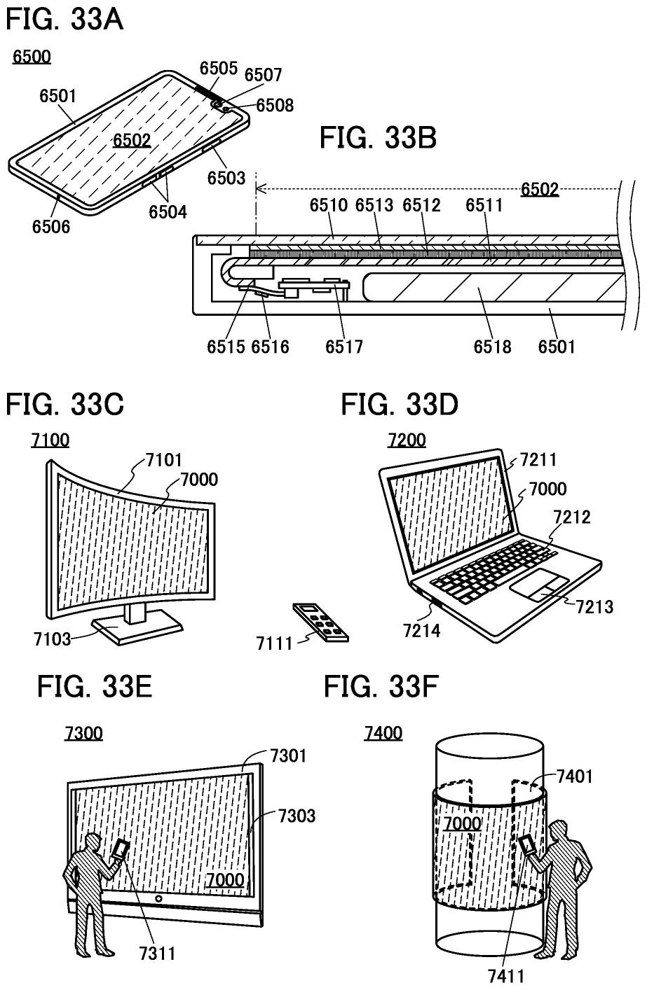

An electronic device 6500 illustrated in FIG. 33A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 33B is a schematic cross-sectional view including an end portion of the housing 6501 on the microphone 6506 side.

A protection member 6510 having a light-transmitting property is provided on a display surface side of the housing 6501, and a display apparatus 6511, an optical member 6512, a touch sensor panel 6513, a printed circuit board 6517, a battery 6518, and the like are provided in a space surrounded by the housing 6501 and the protection member 6510.

The display apparatus 6511, the optical member 6512, and the touch sensor panel 6513 are fixed to the protection member 6510 with an adhesive layer (not illustrated).

Part of the display apparatus 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be achieved. Since the display apparatus 6511 is extremely thin, the battery 6518 with high capacity can be mounted with an increase in the thickness of the electronic device suppressed. Moreover, part of the display apparatus 6511 is folded back and a connection portion with the FPC 6515 is positioned on the back side of a pixel portion, whereby an electronic device with a narrow bezel can be achieved.

FIG. 33C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 33C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 33D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 33E and FIG. 33F illustrate examples of digital signage.

Digital signage 7300 illustrated in FIG. 33E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 33F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 33E and FIG. 33F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 33E and FIG. 33F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

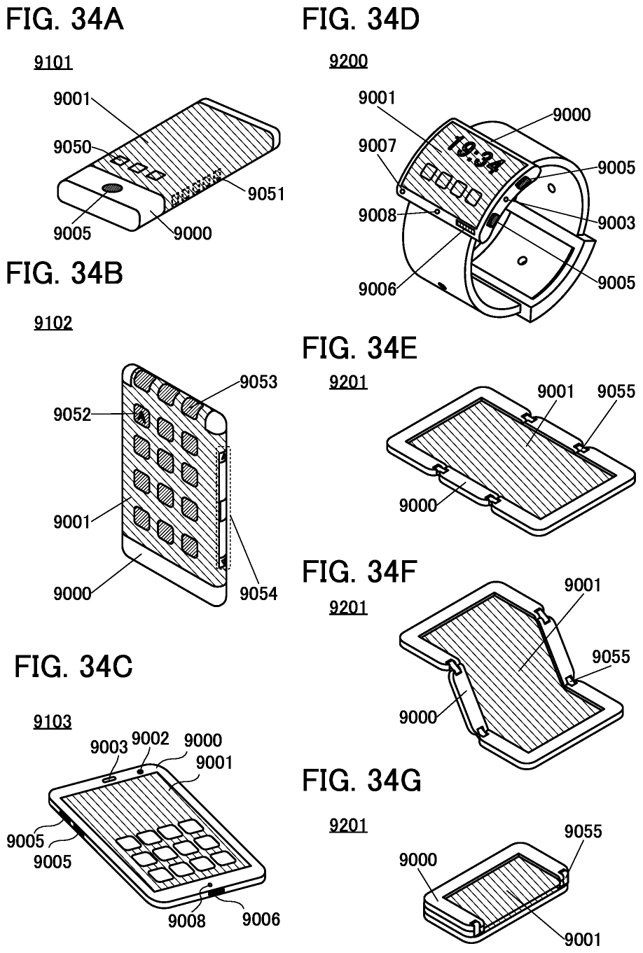

Electronic devices illustrated in FIG. 34A to FIG. 34G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 34A to FIG. 34G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 34A to FIG. 34G are described below.

FIG. 34A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 34A illustrates an example where three icons 9050 are displayed. Furthermore, information 9051 indicated by dashed rectangles can also be displayed on the other surfaces of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 34B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 34C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 34D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 34E to FIG. 34G are perspective views illustrating a foldable portable information terminal 9201. FIG. 34E is a perspective view of an opened state of the portable information terminal 9201, FIG. 34G is a perspective view of a folded state thereof, and FIG. 34F is a perspective view of a state in the middle of change from one of FIG. 34E and FIG. 34G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate.

### REFERENCE NUMERALS

AL: wiring, CL: wiring, GL: wiring, PS: subpixel, RL: wiring, SL: wiring, SLB: wiring, SLG: wiring, SLR: wiring, 100A: display apparatus, 100B: display apparatus, 100C: display apparatus, 100D: display apparatus, 100E: display apparatus, 100F: display apparatus, 100G: display apparatus, 100: display apparatus, 101: layer, 107: nozzle, 108: nozzle, 109B: layer, 109: droplet, 110a: subpixel, 110b: subpixel, 110c: subpixel, 110d: subpixel, 110: pixel, 111a: pixel electrode, 111b: pixel electrode, 111c: pixel electrode, 111d: pixel electrode, 111: pixel electrode, 112a: conductive layer, 112b: conductive layer, 112c: conductive layer, 113A: layer, 113a: layer, 113b: layer, 113c: layer, 113C: film, 113d: layer, 113: layer, 114: common layer, 115: common electrode, 116: layer, 116B: layer, 117a: layer, 117b: layer, 117c: layer, 117: light-blocking layer, 118a: mask layer, 118A: first mask layer, 118b: mask layer, 118c: mask layer, 118D: mask layer, 118d: mask layer, 118E: mask layer, 118S: mask layer, 118: mask layer, 119a: mask layer, 119A: second mask layer, 119b: mask layer, 119c: mask layer, 120: substrate, 121: droplet, 122: resin layer, 123: conductive layer, 124a: pixel, 124b: pixel, 125A: insulating film, 125b: insulating layer, 125: insulating layer, 126a: conductive layer, 126b: conductive layer, 126c: conductive layer, 127A: insulating film, 127b: insulating layer, 127: insulating layer, 128: layer, 129a: conductive layer, 129b: conductive layer, 129c: conductive layer, 130a: light-emitting device, 130B: light-emitting device, 130b: light-emitting device, 130c: light-emitting device, 130G: light-emitting device, 130R: light-emitting device, 130: light-emitting device, 131: protective layer, 133: nozzle, 134: droplet, 140: nozzle, 141: droplet, 142: adhesive layer, 145: connection portion, 150: light-receiving device, 151: substrate, 152: substrate, 162: display portion, 164: circuit, 165: wiring, 166: conductive layer, 172: FPC, 173: IC, 190C: resist mask, 190E: resist mask, 190: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 23 In: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 351: substrate, 352: finger, 353: layer, 355: functional layer, 357: layer, 359: substrate, 400: display apparatus, 401: substrate, 402: driver circuit portion, 403: driver circuit portion, 404: display portion, 405B: subpixel, 405G: subpixel, 405R: subpixel, 405: pixel, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 431: conductive layer, 450a: transistor, 450: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: mounting portion, 727: earphone portion, 750: earphone, 751: display apparatus, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: mounting portion, 824: control portion, 825: image capturing portion, 827: earphone portion, 832: lens, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display apparatus, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device;
a second light-emitting device; and
a third light-emitting device,
wherein the first light-emitting device comprises a first pixel electrode, a first layer over the first pixel electrode, and a common electrode over the first layer,
wherein the second light-emitting device comprises a second pixel electrode, a second layer over the second pixel electrode, and the common electrode over the second layer,
wherein the third light-emitting device comprises a third pixel electrode, a third layer over the third pixel electrode, and the common electrode over the third layer,
wherein the first layer comprises a first light-emitting layer,
wherein the second layer comprises a second light-emitting layer,
wherein the third layer comprises a third light-emitting layer,
wherein the second layer comprises a first region overlapping with the first layer and a second region overlapping with the third layer,
wherein the first region is over the first layer,
wherein the second region is under the third layer,
wherein the first light-emitting device and the second light-emitting device are adjacent to each other,
wherein the first region is between the first pixel electrode and the second pixel electrode in a top view,
wherein the second light-emitting device and the third light-emitting device are adjacent to each other, and
wherein the second region is between the second pixel electrode and the third pixel electrode in a top view.

2. The display apparatus according to claim 1, wherein the first layer comprises one or both of a hole-injection layer and a hole-transport layer.

3. The display apparatus according to claim 1, wherein the first layer comprises an electron-transport layer.

4. A display apparatus comprising:
a first light-emitting device;
a second light-emitting device; and
an insulating layer,
wherein the first light-emitting device comprises a first pixel electrode, a first layer over the first pixel electrode, and a common electrode over the first layer,
wherein the second light-emitting device comprises a second pixel electrode, a second layer over the second pixel electrode, and the common electrode over the second layer,
wherein the first layer comprises a first light-emitting layer,
wherein the second layer comprises a second light-emitting layer,
wherein the insulating layer is in contact with a side surface of the first layer and a side surface of the second layer,
wherein the insulating layer comprises a region overlapping with a top surface of the first layer,
wherein the first layer covers an end portion of the first pixel electrode, and
wherein the insulating layer covers an end portion of the second pixel electrode.

5. The display apparatus according to claim 4, wherein the second layer does not overlap with a top surface of the insulating layer.

6. The display apparatus according to claim 4, wherein the first layer comprises one or both of a hole-injection layer and a hole-transport layer.

7. The display apparatus according to claim 4, wherein the first layer comprises an electron-transport layer.

8-11. (canceled)

12. A display apparatus comprising a display portion,
wherein the display portion comprises a plurality of first light-emitting devices, a plurality of second light-emitting devices, and a plurality of third light-emitting devices,
wherein each of the plurality of first light-emitting devices exhibits light emission of a first color,
wherein each of the plurality of second light-emitting devices exhibits light emission of a second color,
wherein each of the plurality of third light-emitting devices exhibits light emission of a third color,
wherein the display portion comprises a first column where the plurality of first light-emitting devices and the plurality of third light-emitting devices are alternately arranged and a second column where the plurality of second light-emitting devices and the plurality of third light-emitting devices are alternately arranged,
wherein in the display portion, a first light-emitting device of the plurality of first light-emitting devices is adjacent to four of the plurality of third light-emitting devices and a second light-emitting device of the plurality of second light-emitting devices is adjacent to four of the plurality of third light-emitting devices,
wherein a first layer containing a light-emitting material included in each of the plurality of third light-emitting devices comprises a low molecular weight compound, and
wherein a second layer containing a light-emitting material included in each of the plurality of second light-emitting devices comprises a high molecular weight compound.

13. The display apparatus according to claim 12,
wherein each of the plurality of third light-emitting devices exhibits blue light emission,
wherein each of the plurality of second light-emitting devices exhibits red light emission, and
wherein each of the plurality of first light-emitting devices exhibits green light emission.

14. The display apparatus according to claim 12, wherein a third layer containing a light-emitting material included in each of the plurality of first light-emitting devices comprises a high molecular weight compound.
